(19) United States
(12) Patent Application Publication
(10) Pub. No.: US 2012/0056268 A1
(43) Pub. Date: Mar. 8, 2012

(54) SEMICONDUCTOR DEVICE AND MANUFACTURING METHOD THEREOF

(75) Inventors: Masaharu MIZUTANI, Kanagawa (JP); Masaru KADOSHIMA, Kanagawa (JP); Takaaki KAWAHARA, Kanagawa (JP); Masao INOUE, Kanagawa (JP); Hiroshi UMEDA, Kanagawa (JP)

(73) Assignee: Renesas Electronics Corporation

(21) Appl. No.: 13/191,050

(22) Filed: Jul. 26, 2011

(30) Foreign Application Priority Data
Sep. 8, 2010 (JP) 2010-201049

(51) Int. Cl. H01L 21/8238; H01L 27/092

(52) U.S. Cl. 257/369; 438/216; 257/E27.062; 257/E21.625

(57) ABSTRACT

There is provided a technology capable of achieving, in a semiconductor device having a MISFET using an insulating film containing hafnium as a gate insulating film, an improvement in the reliability of a MISFET. In the present invention, the gate insulating film of an n-channel core transistor is provided with a structure different from that of the gate insulating film of a p-channel core transistor. Specifically, in the n-channel core transistor, as the gate insulating film thereof, a laminate film of a silicon oxide film and a HfZrSiON film is used. On the other hand, in the p-channel core transistor, as the gate insulating film thereof, a laminate film of a silicon oxide film and a HfSiON film is used.

### CROSS-REFERENCE TO RELATED APPLICATIONS

The disclosure of Japanese Patent Application No. 2010-201049 filed on Sep. 8, 2010 including the specification, drawings and abstract is incorporated herein by reference in its entirety.

### BACKGROUND

The present invention relates to a semiconductor device and a manufacturing technique therefor, and particularly to a technology which is effective when applied to a semiconductor device having a field effect transistor using an insulating film containing hafnium as the gate insulating film and a manufacturing technique therefor.

In Japanese Unexamined Patent Publications Nos. 2009-302260 (Patent Document 1) and 2010-21200 (Patent Document 2), it is described that, for the gate insulating film of a field effect transistor, an oxide of zirconium, an oxynitride thereof, a silicate thereof, or a nitrogen-containing silicate thereof may be used.

### RELATED ART DOCUMENTS

### Patent Documents

### [Patent Document 1]

Japanese Unexamined Patent Publication No. 2009-302260

### [Patent Document 2]

Japanese Unexamined Patent Publication No. 2010-21200

### SUMMARY

Conventionally, in an n-channel MISFET (Metal Insulator Semiconductor Field Effect Transistor) and a p-channel MISFET, as the gate insulating films, a silicon oxide film and a silicon oxynitride film are used.

However, in recent years, with the scaling down of a MISEET forming a semiconductor device, the thinning of the gate insulating film has been in rapid progress. When the thickness of the gate insulating film is reduced, due to a tunnel effect, a phenomenon occurs in which electrons pass through the inside of the gate insulating film. The phenomenon allows a tunnel current to flow in the gate insulating film. Accordingly, a leakage current in the MISFET increases. On the other hand, when the thickness of the gate insulating film is increased to reduce the leakage current in the MISFET, the gate capacitance decreases to reduce the current driving capability.

In view of the foregoing, research has been promoted to use, as a gate insulating film, instead of a silicon oxide film or a silicon oxynitride film, a high-dielectric-constant film having a dielectric constant higher than that of the silicon oxide film as a replacement. This is because, when the gate insulating film is formed of the high-dielectric-constant film, even if the capacitance is the same as when the gate insulating film is formed of the silicon oxide film, the actual physical film thickness can be increased by (Dielectric Constant of High-Dielectric-Constant Film/Dielectric Constant of Silicon Oxide Film) times, and consequently the leakage current can be reduced. In the high-dielectric-constant film, even when the actual physical film thickness is increased, the dielectric constant is high and the electric film thickness, which is given by considering the dielectric constant, can be reduced, and therefore the gate capacitance can be ensured. As a result, even when a MISFET using a high-dielectric-constant film as the gate insulating film is scaled down, it is possible to reduce a leakage current therein, and improve the current driving capability thereof.

As a material of such a high-dielectric-constant film, an insulating film containing hafnium (Hf) is considered to be promising. However, the insulating film containing hafnium has the problem that a large number of fixed charges and trap levels are formed therein, and degrade the reliability of the MISFET. In particular, an increase in the degradation of PBTI (Positive Bias Temperature Instability) which occurs in an re-channel MISFET has become an obvious problem. PBTI is a phenomenon in which a continuous application of a positive voltage (positive bias) to the gate electrode of a MISFET causes fluctuations in the threshold voltage of the MISFET or the degradation of the current driving capability thereof. In an n-channel MISFET, when an ON operation thereof is to be performed, a positive voltage (positive bias) is applied to the gate electrode. Accordingly, PBTI is the phenomenon which mostly occurs in the n-channel MISFET. It can be considered that, when the insulating film containing hafnium is used as the gate insulating film, the degradation of PBTI is affected by the large number of fixed charges and trap levels formed in the insulating film containing hafnium.

An object of the present invention is to provide a technique capable of achieving, in a semiconductor device having a MISFET using an insulating film containing hafnium as the gate insulating film, an improvement in the reliability of the MISFET.

The above and other objects and novel features of the present invention will become apparent from a statement in the present specification and the accompanying drawings.

The following is a brief description of the outline of a representative aspect of the invention disclosed in the present application.

A semiconductor device according to a representative embodiment includes: an n-channel MISFET formed in an re-channel MISFET formation region of a semiconductor substrate; and a p-channel MISFET formed in a p-channel MISFET formation region of the semiconductor substrate. At this time, the re-channel MISFET has: (a) a first insulating film formed over the semiconductor substrate, and containing hafnium and zirconium; (b) a first gate electrode formed over the first insulating film; (c) a first source region formed in the semiconductor substrate; and (d) a first drain region formed in the semiconductor substrate. On the other hand, the p-channel MISFET has: (e) a second insulating film formed over the semiconductor substrate, and containing hafnium; (f) a second gate electrode formed over the second insulating film; (g) a second source region formed in the semiconductor substrate; and (h) a second drain region formed in the semiconductor substrate. In the semiconductor device, a physical film thickness of the first insulating film is larger than a physical film thickness of the second insulating film, and a concentration of the zirconium contained in the first insulating film is higher than a concentration of the zirconium contained in the second insulating film.

A method of manufacturing a semiconductor device according to a representative embodiment pertains to a method of manufacturing a semiconductor device including an n-channel MISFET formed in an n-channel MISFET formation region of a semiconductor substrate, and a p-channel MISFET formed in a p-channel MISFET formation region of the semiconductor substrate. The method includes the steps of: (a) forming a second insulating film containing hafnium over the semiconductor substrate; (b) after the step (a), forming a hard mask film over the second insulating film; (c) after the step (b), patterning the hard mask film to remove the hard mask film formed in the n-channel MISFET formation region; (d) after the step (c), forming a first cap film containing zirconium over the second insulating film formed in the n-channel MISFET formation region and over the hard mask film formed in the p-channel MISFET formation region; (e) after the step (d), performing a heating treatment to the semiconductor substrate to diffuse the zirconium contained in the first cap film into the second insulating film in the n-channel MISFET formation region, and thereby form a first insulating film containing hafnium and zirconium in the n-channel MISFET formation region; (f) after the step (e), removing the first cap film and the hard mask film which are formed in the p-channel MISFET formation region; (g) after the step (f), forming a conductor film over the first insulating film formed in the re-channel MISFET formation region and over the second insulating film formed in the p-channel MISFET formation region; (h) after the step (g), patterning the conductor film to form a first gate electrode in the n-channel MISFET formation region, and form a second gate electrode in the p-channel MISFET formation region; and

(i) after the step (h), introducing an n-type impurity into the semiconductor substrate in the n-channel MISFET formation region to form a first source region and a first drain region, while introducing a p-type impurity into the semiconductor substrate in the p-channel MISFET formation region to form a second source region and second drain region. In the method, a physical film thickness of the first insulating film is larger than a physical film thickness of the second insulating film, and a concentration of the zirconium contained in the first insulating film is higher than a concentration of the zirconium contained in the second insulating film.

A method of manufacturing a semiconductor device according to another representative embodiment pertains to a method of manufacturing a semiconductor device including an re-channel MISFET formed in an n-channel MISFET formation region of a semiconductor substrate, and a p-channel MISFET formed in a p-channel MISFET formation region of the semiconductor substrate. The method includes the steps of: (a) forming a second insulating film containing hafnium over the semiconductor substrate; (b) after the step (a), forming a hard mask film over the second insulating film; (c) after the step (b), patterning the hard mask film to remove the hard mask film formed in the n-channel MISFET formation region; (d) after the step (c), forming a first cap film containing zirconium over the second insulating film formed in the re-channel MISFET formation region and over the hard mask film formed in the p-channel MISFET formation region; (e) after the step (d), performing a heating treatment to the semiconductor substrate to diffuse the zirconium contained in the first cap film into the second insulating film in the n-channel MISFET formation region, and thereby form a first insulating film containing hafnium and zirconium in the n-channel MISFET formation region; (f) after the step (e), removing the first cap film and the hard mask film which are formed in the p-channel MISFET formation region; (g) after the step (f), forming a first conductor film containing a metal over the first insulating film formed in the n-channel MISFET formation region and over the second insulating film formed in the p-channel MISFET formation region; (h) after the step (g), patterning the first conductor film to remove the first conductor film formed in the p-channel MISFET formation region; (i) after the step (h), forming a second conductor film over the first conductor film formed in the n-channel MISFET formation region and over the second insulating film formed in the p-channel MISFET formation region; (j) after the step (i), patterning the first conductor film and the second conductor film to form a first dummy gate electrode in the re-channel MISFET formation region, and form a second dummy gate electrode in the p-channel MISFET formation region; (k) after the step (j), introducing an n-type impurity into the semiconductor substrate in the n-channel MISFET formation region to form a first source region and a first drain region, while introducing a p-type impurity into the semiconductor substrate in the p-channel MISFET formation region to form a second source region and a second drain region; (l) after the step (k), forming, over the semiconductor substrate, an interlayer insulating film covering the first dummy gate electrode and the second dummy gate electrode; (m) after the step (l), polishing a surface of the interlayer insulating film to expose an upper surface of the first dummy gate electrode and an upper surface of the second dummy gate electrode; (n) after the step (m), removing the second conductor film forming a part of the first dummy gate electrode to form a first trench in the interlayer insulating film, while removing the second conductor film forming the second dummy gate electrode to form a second trench in the interlayer insulating film; (o) after the step (n), forming a third conductor film containing a metal over the interlayer insulating film including an inside of the first trench and an inside of the second trench, and forming a fourth conductor film containing a metal over the third conductor film to fill the inside of the first trench and the inside of the second trench with the third conductor film and the fourth conductor film; and (p) after the step (o), removing the unneeded third conductor film and the unneeded fourth conductor film which are formed over the interlayer insulating film to form a first gate electrode in the first trench, and form a second gate electrode in the second trench. In the method, a physical film thickness of the first insulating film is larger than a physical film thickness of the second insulating film, and a concentration of the zirconium contained in the first insulating film is higher than a concentration of the zirconium contained in the second insulating film.

A method of manufacturing a semiconductor device according to still another representative embodiment pertains to a method of manufacturing a semiconductor device including an n-channel MISFET formed in an n-channel MISFET formation region of a semiconductor substrate, and a p-channel MISFET formed in a p-channel MISFET formation region of the semiconductor substrate. The method includes the steps of: (a) forming a second insulating film containing hafnium over the semiconductor substrate; (b) after the step (a), forming a first cap film containing zirconium over the second insulating film; (c) after the step (b), forming a first conductor film containing a metal over the first cap film; (d) after the step (c), removing the first conductor film and the first cap film which are formed in the p-channel MISFET formation region; (e) after the step (d), performing a heating treatment to the semiconductor substrate to diffuse the zirconium contained in the first cap film into the second insulating film in the re-channel MISFET formation region, and thereby form a first insulating film containing hafnium and zirconium in the re-channel MISFET formation region; (f) after the step (e), forming a second conductor film over the first conductor film formed in the n-channel MISFET formation region and over the second insulating film formed in the p-channel MISFET formation region; (g) after the step (f), patterning the first conductor film and the second conductor film to form a first dummy gate electrode in the n-channel MISFET formation region, and form a second dummy gate electrode in the p-channel MISFET formation region; (h) after the step (g), introducing an n-type impurity into the semiconductor substrate in the re-channel MISFET formation region to form a first source region and a first drain region, while introducing a p-type impurity into the semiconductor substrate in the p-channel MISFET formation region to form a second source region and a second drain region; (i) after the step (h), forming, over the semiconductor substrate, an interlayer insulating film covering the first dummy gate electrode and the second dummy gate electrode; (j) after the step (i), polishing a surface of the interlayer insulating film to expose an upper surface of the first dummy gate electrode and an upper surface of the second dummy gate electrode; (k) after the step (j), removing the second conductor film forming a part of the first dummy gate electrode to form a first trench in the interlayer insulating film, while removing the second conductor film forming the second dummy gate electrode to form a second trench in the interlayer insulating film; (l) after the step (k), forming a third conductor film containing a metal over the interlayer insulating film including an inside of the first trench and an inside of the second trench, and forming a fourth conductor film containing a metal over the third conductor film to fill the inside of the first trench and the inside of the second trench with the third conductor film and the fourth conductor film; and (m) after the step (l), removing the unneeded third conductor film and the unneeded fourth conductor film which are formed over the interlayer insulating film to form a first gate electrode in the first trench, and form a second gate electrode in the second trench. In the method, a physical film thickness of the first insulating film is larger than a physical film thickness of the second insulating film, and a concentration of the zirconium contained in the first insulating film is higher than a concentration of the zirconium contained in the second insulating film.

The following is a brief description of effects achievable by the representative aspect of the invention disclosed in the present application.

In a semiconductor device having a MISFET using an insulating film containing hafnium as the gate insulating film, an improvement in the reliability of the MISFET can be achieved.

### BRIEF DESCRIPTION OF THE DRAWINGS

FIG. 1 is a view showing a layout configuration of a semiconductor chip in a first embodiment of the present invention;

FIG. 2 is a cross-sectional view showing a structure of a semiconductor device in the first embodiment;

FIG. 3 is a cross-sectional view showing a step of manufacturing the semiconductor device in the first embodiment;

FIG. 4 is a cross-sectional view showing a step of manufacturing the semiconductor device, which is subsequent to FIG. 3;

FIG. 5 is a cross-sectional view showing a step of manufacturing the semiconductor device, which is subsequent to FIG. 4;

FIG. 6 is a cross-sectional view showing a step of manufacturing the semiconductor device, which is subsequent to FIG. 5;

FIG. 7 is a cross-sectional view showing a step of manufacturing the semiconductor device, which is subsequent to FIG. 6;

FIG. 8 is a cross-sectional view showing a step of manufacturing the semiconductor device, which is subsequent to FIG. 7;

FIG. 9 is a cross-sectional view showing a step of manufacturing the semiconductor device, which is subsequent to FIG. 8;

FIG. 10 is a cross-sectional view showing a step of manufacturing the semiconductor device, which is subsequent to FIG. 9;

FIG. 11 is a cross-sectional view showing a step of manufacturing the semiconductor device, which is subsequent to FIG. 10;

FIG. 12 is a cross-sectional view showing a step of manufacturing the semiconductor device, which is subsequent to FIG. 11;

FIG. 13 is a cross-sectional view showing a step of manufacturing the semiconductor device, which is subsequent to FIG. 12;

FIG. 14 is a cross-sectional view showing a step of manufacturing the semiconductor device, which is subsequent to FIG. 13;

FIG. 15 is a cross-sectional view showing a step of manufacturing the semiconductor device, which is subsequent to FIG. 14;

FIG. 16 is a cross-sectional view showing a step of manufacturing the semiconductor device, which is subsequent to FIG. 15;

FIG. 17 is a cross-sectional view showing a step of manufacturing the semiconductor device, which is subsequent to FIG. 16;

FIG. 18 is a cross-sectional view showing a step of manufacturing the semiconductor device, which is subsequent to FIG. 17;

FIG. 19 is a cross-sectional view showing a step of manufacturing a semiconductor device in a second embodiment;

FIG. 20 is a cross-sectional view showing a step of manufacturing the semiconductor device, which is subsequent to FIG. 19;

FIG. 21 is a cross-sectional view showing a step of manufacturing the semiconductor device, which is subsequent to FIG. 20;

FIG. 22 is a cross-sectional view showing a step of manufacturing a semiconductor device in a fourth embodiment;

FIG. 23 is a cross-sectional view showing a step of manufacturing the semiconductor device, which is subsequent to FIG. 22;

FIG. 24 is a cross-sectional view showing a step of manufacturing the semiconductor device, which is subsequent to FIG. 23;

FIG. 25 is a cross-sectional view showing a step of manufacturing the semiconductor device, which is subsequent to FIG. 24;

FIG. 26 is a cross-sectional view showing a step of manufacturing the semiconductor device, which is subsequent to FIG. 25;

FIG. 27 is a cross-sectional view showing a step of manufacturing a semiconductor device in a fifth embodiment;

FIG. 28 is a cross-sectional view showing a step of manufacturing the semiconductor device, which is subsequent to FIG. 27;

FIG. 29 is a cross-sectional view showing a step of manufacturing the semiconductor device, which is subsequent to FIG. 28;

FIG. 30 is a cross-sectional view showing a step of manufacturing a semiconductor device in a sixth embodiment;

FIG. 31 is a cross-sectional view showing a step of manufacturing the semiconductor device, which is subsequent to FIG. 30;

FIG. 32 is a cross-sectional view showing a step of manufacturing the semiconductor device, which is subsequent to FIG. 31;

FIG. 33 is a cross-sectional view showing a step of manufacturing the semiconductor device, which is subsequent to FIG. 32;

FIG. 34 is a cross-sectional view showing a step of manufacturing the semiconductor device, which is subsequent to FIG. 33;

FIG. 35 is a cross-sectional view showing a step of manufacturing the semiconductor device, which is subsequent to FIG. 34;

FIG. 36 is a cross-sectional view showing a step of manufacturing the semiconductor device, which is subsequent to FIG. 35;

FIG. 37 is a cross-sectional view showing a step of manufacturing the semiconductor device, which is subsequent to FIG. 36;

FIG. 38 is a cross-sectional view showing a step of manufacturing the semiconductor device, which is subsequent to FIG. 37;

FIG. 39 is a cross-sectional view showing a step of manufacturing the semiconductor device, which is subsequent to FIG. 38;

FIG. 40 is a cross-sectional view showing a step of manufacturing the semiconductor device, which is subsequent to FIG. 39;

FIG. 41 is a cross-sectional view showing a step of manufacturing the semiconductor device, which is subsequent to FIG. 40;

FIG. 42 is a cross-sectional view showing a step of manufacturing the semiconductor device, which is subsequent to FIG. 41;

FIG. 43 is a cross-sectional view showing a step of manufacturing a semiconductor device in an eleventh embodiment;

FIG. 44 is a cross-sectional view showing a step of manufacturing the semiconductor device, which is subsequent to FIG. 43;

FIG. 45 is a cross-sectional view showing a step of manufacturing the semiconductor device, which is subsequent to FIG. 44;

FIG. 46 is a cross-sectional view showing a step of manufacturing the semiconductor device, which is subsequent to FIG. 45; and

FIG. 47 is a cross-sectional view showing a step of manufacturing the semiconductor device, which is subsequent to FIG. 46.

### DETAILED DESCRIPTION

In each of the following embodiments, if necessary for the sake of convenience, the embodiment will be described by being divided into a plurality of sections or embodiments. However, they are by no means irrelevant to each other unless particularly explicitly described otherwise, and one of the sections or embodiments is variations, details, supplementary explanation, and so forth of part or the whole of the others.

When the number and the like (including the number, numerical value, amount, range, and the like) of elements are mentioned in the following embodiments, they are not limited to specific numbers unless particularly explicitly described otherwise or unless they are obviously limited to specific numbers in principle. The number and the like of the elements may be not less than or not more than specific numbers.

It will be appreciated that, in the following embodiments, the components thereof (including also elements, steps, and the like) are not necessarily indispensable unless particularly explicitly described otherwise or unless the components are considered to be obviously indispensable in principle.

Likewise, if the shapes, positional relationships, and the like of the components and the like are referred to in the following embodiments, the shapes and the like are assumed to include those substantially proximate or similar thereto unless particularly explicitly described otherwise or unless it can be considered that they obviously do not in principle. The same shall apply in regard to the foregoing numerical value and range.

Throughout all the drawings for illustrating the embodiments, the same components are designated by the same reference numerals in principle, and a repeated description thereof is omitted. Note that, for clarity of illustration, even a plan view may be hatched.

### First Embodiment

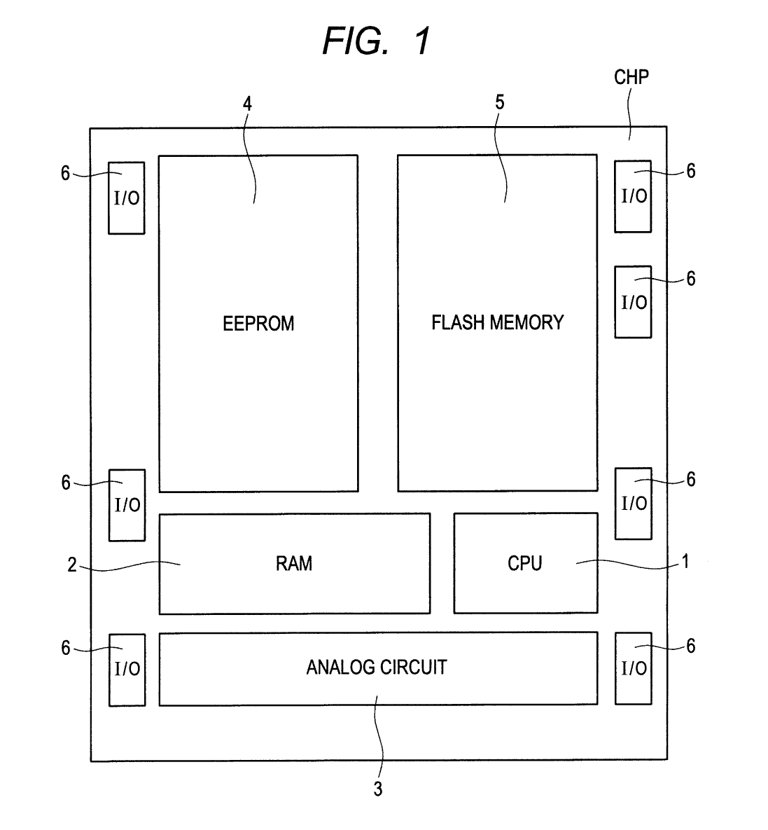

A semiconductor device in the present first embodiment will be described with reference to the drawings. First, a description will be given to a layout configuration of a semiconductor chip formed with a system including a microcomputer. FIG. 1 is a view showing the layout configuration of a semiconductor chip CHP in the present first embodiment. In FIG. 1, the semiconductor chip CHP has a CPU (Central Processing Unit) 1, a RAM (Random Access Memory) 2, an analog circuit 3, an EEPROM (Electrically Erasable Programmable Read Only Memory) 4, a flash memory 5, and an I/O (Input/Output) circuit 6.

The CPU (circuit) 1 stands for a central processing unit, and corresponds to the heart of a computer or the like. The CPU 1 reads an instruction out of a memory device, decodes the instruction, and performs various arithmetic and control operations based thereon.

The RAM (circuit) 2 is a memory from which information stored therein can be read randomly, i.e., non-sequentially or to which information to be stored can be newly written, and also called a non-sequentially writable/readable memory. A RAM as an IC memory includes two types, which are a DRAM (Dynamic RAM) using a dynamic circuit and a SRAM (Static RAM) using a static circuit. The DRAM is a non-sequential write/read memory which requires a memory retaining operation. The SRAM is a non-sequential write/read memory which does not require a memory retaining operation.

The analog circuit 3 processes a signal of a voltage or current which changes continuously with time, i.e., an analog signal, and includes, e.g., an amplification circuit, a conversion circuit, a modulation circuit, an oscillation circuit, a power source circuit, and the like.

The EEPROM 4 and the flash memory 5 are kinds of electrically rewritable nonvolatile memories in each of a write operation and an erase operation, of which the former stands for an electrically erasable programmable read only memory. The memory cells of the EEPROM 4 and the flash memory are formed of, e.g., MONOS (Metal Oxide Nitride Oxide Semiconductor) transistors or MNOS (Metal Nitride Oxide Semiconductor) transistors for storage (memory). For a write operation and an erase operation to the EEPROM 4 and the flash memory 5, for example, a Fowler-Nordheim tunnel phenomenon is utilized. Note that it is also possible to cause a write operation or an erase operation using hot electrons or hot holes. The difference between the EEPROM 4 and the flash memory 5 is that the EEPROM 4 is a nonvolatile memory which allows erasing on a per byte basis, while the flash memory 5 is a nonvolatile memory which allows erasing on a per word-line basis. In general, in the flash memory 5, a program for the execution of various processings in the CPU 1 and the like are stored while, in the EEPROM 4, various data which is high in rewriting frequency is stored.

The I/O circuit 6 is an input/output circuit for outputting data from within the semiconductor chip CHP to a device coupled externally to the semiconductor chip CHP, and inputting data from the device coupled externally to the semiconductor chip CHP into the semiconductor chip.

The foregoing is the layout configuration of the semiconductor chip CHP in the present first embodiment. Hereinbelow, a description will be given to transistors included in the CPU 1 and transistors included in the I/O circuit 6. It is assumed that the transistors included in the CPU 1 are called core transistors, and the transistors included in the I/O circuit 6 are called I/O transistors. The CPU 1 has, e.g., an n-channel core transistor, a p-channel core transistor, an n-channel resistor element, and a p-channel resistor element. On the other hand, the I/O circuit 6 has, e.g., an n-channel I/O transistor and a p-channel I/O transistor.

Each of the core transistors and each of the I/O transistors have substantially the same structures, and the difference therebetween is that the gate insulating film of the I/O transistor is formed thicker than the gate insulating film of the core transistor. This is because the I/O circuit 6 uses a power source voltage higher than that used by the CPU 1, and accordingly a higher voltage is applied to the I/O transistor than to the core transistor. That is, to the I/O transistor, a voltage higher than that applied to the core transistor is applied, and accordingly the gate insulating film thereof is formed thicker so as not to undergo dielectric breakdown even when a high voltage is applied.

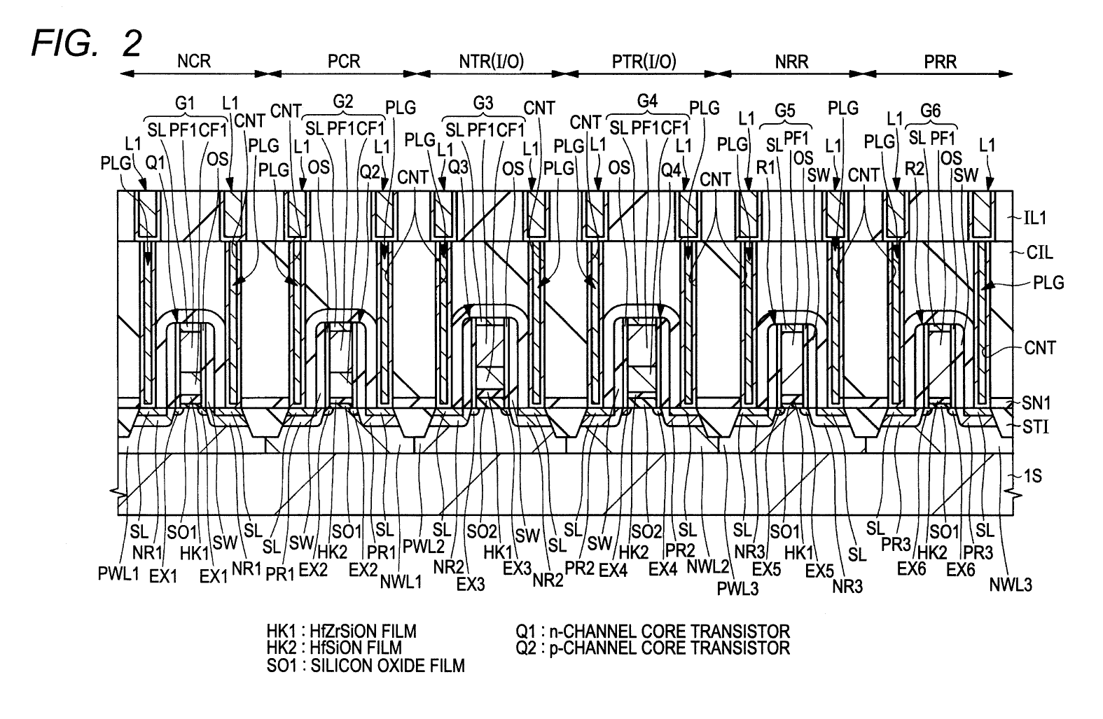

Hereinbelow, a description will be given to respective structures of the core transistors included in the CPU 1, the I/O transistors included in the I/O circuit 6, and the resistor elements included in the CPU 1. FIG. 2 is a cross-sectional view showing the structures of an n-channel core transistor Q1, a p-channel core transistor Q2, an n-channel I/O transistor Q3, a p-channel I/O transistor Q4, an n-channel resistor element R1, and a p-channel resistor element R2 in the present first embodiment. As shown in FIG. 2, in an re-channel core transistor formation region NCR, the n-channel core transistor Q1 is formed and, in a p-channel core transistor formation region PCR, the p-channel core transistor Q2 is formed. Likewise, in an n-channel I/O transistor formation region NTR(I/O), the n-channel I/O transistor Q3 is formed and, in a p-channel I/O transistor formation region PTR(I/O), the p-channel I/O transistor Q4 is formed. In addition, in an n-channel resistor element formation region NRR, the n-channel resistor element R1 is formed and, in a p-channel resistor element formation region PRR, the p-channel resistor element R2 is formed.

First, a description will be given to the structure of the n-channel core transistor Q1 formed in the n-channel core transistor formation region NCR. In FIG. 2, in the main surface of a semiconductor substrate 1S made of a silicon single crystal, a plurality of isolation regions STI are formed and, in an active region defined by the isolation regions STI, a p-type well PWL1 is formed. The p-type well PWL1 is formed of a semiconductor region into which a p-type impurity such as boron (B) has been introduced and, over the p-type well PWL1, the n-channel core transistor Q1 is formed.

Specifically, over the p-type well PWL1, a silicon oxide film SO1 is formed and, over the silicon oxide film SO1, a HfZrSiON film HK1 is formed. The silicon oxide film SO1 and the HfZrSiON film HK1 form the gate insulating film of the re-channel core transistor Q1. In addition, over the HfZrSiON film HK1, a gate electrode G1 is formed. The gate electrode G1 includes a conductor film CF1 formed over the HfZrSiON film HK1 and containing a metal, a polysilicon film PF1 formed over the conductor film CF1, and a silicide film SL formed by silicidizing the surface of the polysilicon film PF1. Examples of the conductor film CF1 containing a metal include a titanium nitride film. The silicide film SL is formed of a nickel platinum silicide film, a nickel silicide film, a titanium silicide film, a cobalt silicide film, a platinum silicide film, or the like. The silicide film SL is formed to reduce the resistance of the gate electrode G1.

Subsequently, over the both side walls of the gate electrode G1, offset spacers OS formed of, e.g., a silicon oxide film are formed. Outside the offset spacers OS, sidewalls SW are formed. Each of the sidewalls SW is formed of, e.g., a laminate film of a silicon oxide film and a silicon nitride film. However, the structure of the sidewall SW is not limited thereto. The sidewall SW can also be formed of a single-layered film of silicon oxide or a single-layered film of silicon nitride.

In the semiconductor substrate 1S under the sidewalls SW, as semiconductor regions, shallow n-type impurity diffusion regions EX1 are formed. Outside the shallow n-type impurity diffusion regions EX1, deep n-type impurity diffusion regions NR1 are formed and, over the surfaces of the deep n-type impurity diffusion regions NR1, the silicide films SL are formed.

The sidewalls SW are formed to impart a LDD structure to each of a source region and a drain region, which are the semiconductor regions of the n-channel core transistor Q1. That is, the source region and the drain region of the n-channel core transistor Q1 are formed of the shallow n-type impurity diffusion regions EX1, the deep n-type impurity diffusion regions NR1, and the silicide films SL. At this time, the impurity concentrations of the shallow n-type impurity diffusion regions EX1 are lower than the impurity concentrations of the deep n-type impurity diffusion regions NR1. Accordingly, by forming the source region and the drain region under the sidewalls SW of the shallow n-type impurity diffusion regions EX1 having the lower impurity concentrations, electric field concentration under the end portions of the gate electrode G1 can be suppressed. Note that the region immediately under the gate insulating film interposed between the source region and the drain region serves as a channel region. Thus, over the semiconductor substrate 1S, the re-channel core transistor Q1 is formed.

Next, a description will be given to the structure of the p-channel core transistor Q2 formed in the p-channel core transistor formation region PCR. In FIG. 2, in the main surface of the semiconductor substrate 1S made of a silicon single crystal, the plural isolation regions STI are formed and, in an active region defined by the isolation regions STI, an n-type well NWL1 is formed. The n-type well NWL1 is formed of a semiconductor region into which an n-type impurity such as phosphorus (P) or arsenic (As) has been introduced and, over the n-type well NWL1, the p-channel core transistor Q2 is formed.

Specifically, over the n-type well NWL1, the silicon oxide film SO1 is formed and, over the silicon oxide film SO1, a HfSiON film HK2 is formed. The silicon oxide film SO1 and the HfSiON film HK2 form the gate insulating film of the p-channel core transistor Q2. In addition, over the HfSiON film HK2, a gate electrode G2 is formed. The gate electrode G2 includes the conductor film CFI formed over the HfSiON film HK2 and containing a metal, the polysilicon film PFI formed over the conductor film CFI, and the silicide film SL formed by silicidizing the surface of the polysilicon film PFI. Examples of the conductor film CFI containing a metal include a titanium nitride film. The silicide film SL is formed of a nickel platinum silicide film, a nickel silicide film, a titanium silicide film, a cobalt silicide film, a platinum silicide film, or the like. The silicide film SL is formed to reduce the resistance of the gate electrode G2.

Subsequently, over the both side walls of the gate electrode G2, the offset spacers OS formed of, e.g., a silicon oxide film are formed. Outside the offset spacers OS, the sidewalls SW are formed. Each of the sidewalls SW is formed of, e.g., a laminate film of a silicon oxide film and a silicon nitride film. However, the structure of the sidewall SW is not limited thereto. The sidewall SW can also be formed of a single-layered film of silicon oxide or a single-layered film of silicon nitride.

In the semiconductor substrate IS under the sidewalls SW, as semiconductor regions, shallow p-type impurity diffusion regions EX2 are formed. Outside the shallow p-type impurity diffusion regions EX2, deep p-type impurity diffusion regions PR1 are formed and, over the surfaces of the deep p-type impurity diffusion regions PR1, the silicide films SL are formed.

The sidewalls SW are formed to impart a LDD structure to each of a source region and a drain region, which are the semiconductor regions of the p-channel core transistor Q2. That is, the source region and the drain region of the p-channel core transistor Q2 are formed of the shallow p-type impurity diffusion regions EX2, the deep p-type impurity diffusion regions PR1, and the silicide films SL. At this time, the impurity concentrations of the shallow p-type impurity diffusion regions EX2 are lower than the impurity concentrations of the deep p-type impurity diffusion regions PR1. Accordingly, by forming the source region and the drain region under the sidewalls SW of the shallow p-type impurity diffusion regions EX2 having the lower impurity concentrations, electric field concentration under the end portions of the gate electrode G2 can be suppressed. Note that the region immediately under the gate insulating film interposed between the source region and the drain region serves as a channel region. Thus, over the semiconductor substrate 1S, the p-channel core transistor Q2 is formed.

Subsequently, a description will be given to the structure of the n-channel I/O transistor Q3 formed in the re-channel I/O transistor formation region NTR(I/O). In FIG. 2, in the main surface of the semiconductor substrate 1S made of a silicon single crystal, the plural isolation regions STI are formed and, in an active region defined by the isolation regions STI, a p-type well PWL2 is formed. The p-type well PWL2 is formed of a semiconductor region into which a p-type impurity such as boron (B) has been introduced and, over the p-type well PWL2, the n-channel I/O transistor Q3 is formed.

Specifically, over the p-type well PWL2, a silicon oxide film SO2 is formed and, over the silicon oxide film SO2, the HfZrSiON film HK1 is formed. The silicon oxide film SO2 and the HfZrSiON film HK1 form the gate insulating film of the re-channel I/O transistor Q3. Here, if the gate insulating film of the n-channel I/O transistor Q3 is compared with the gate insulating film of the n-channel core transistor Q1 described above, the thickness of the silicon oxide film SO2 of the re-channel I/O transistor Q3 is larger than the thickness of the silicon oxide film SO1 of the n-channel core transistor Q1. On the other hand, the thickness of the HfZrSiON film HK1 of the n-channel I/O transistor Q3 is the same as the thickness of the HfZrSiON film HK1 of the n-channel core transistor Q1. Accordingly, the gate insulating film of the n-channel I/O transistor Q3 is formed thicker than the gate insulating film of the n-channel core transistor Q1. This is because a higher voltage is applied to the n-channel I/O transistor Q3 than to the n-channel core transistor Q1. That is, to the n-channel I/O transistor Q3, a higher voltage is applied than to the re-channel core transistor Q1 so that the gate insulating film thereof is formed thick so as not to undergo dielectric breakdown.

In addition, over the HfZrSiON film HK1, a gate electrode G3 is formed. The gate electrode G3 includes the conductor film CF1 formed over the HfZrSiON film HK1 and containing a metal, the polysilicon film PF1 formed over the conductor film CF1, and the silicide film SL formed by silicidizing the surface of the polysilicon film PF1. Examples of the conductor film CF1 containing a metal include a titanium nitride film. The silicide film SL is formed of a nickel platinum silicide film, a nickel silicide film, a titanium silicide film, a cobalt silicide film, a platinum silicide film, or the like. The silicide film SL is formed to reduce the resistance of the gate electrode G3. At this time, if the gate length of the re-channel I/O transistor Q3 is compared with the gate length of the n-channel core transistor Q1 described above, the re-channel I/O transistor Q3 is formed to have the gate length larger than the gate length of the n-channel core transistor Q1.

Subsequently, over the both side walls of the gate electrode G3, the offset spacers OS formed of, e.g., a silicon oxide film are formed. Outside the offset spacers OS, the sidewalls SW are formed. Each of the sidewalls SW is formed of, e.g., a laminate film of a silicon oxide film and a silicon nitride film. However, the structure of the sidewall SW is not limited thereto. The sidewall SW can also be formed of a single-layered film of silicon oxide or a single-layered film of silicon nitride.

In the semiconductor substrate 1S under the sidewalls SW, as semiconductor regions, shallow n-type impurity diffusion regions EX3 are formed. Outside the shallow n-type impurity diffusion regions EX3, deep n-type impurity diffusion regions NR2 are formed and, over the surfaces of the deep n-type impurity diffusion regions NR2, the silicide films SL are formed.

The sidewalls SW are formed to impart a LDD structure to each of a source region and a drain region, which are the semiconductor regions of the n-channel I/O transistor Q3. That is, the source region and the drain region of the n-channel I/O transistor Q3 are formed of the shallow n-type impurity diffusion region EX3, the deep n-type impurity diffusion region NR2, and the silicide films SL. At this time, the impurity concentrations of the shallow n-type impurity diffusion regions EX3 are lower than the impurity concentrations of the deep n-type impurity diffusion regions NR2. Accordingly, by forming the source region and the drain region under the sidewalls SW of the shallow n-type impurity diffusion regions EX3 having the lower impurity concentrations, electric field concentration under the end portions of the gate electrode G3 can be suppressed. Note that the region immediately under the gate insulating film interposed between the source region and the drain region serves as a channel region. Thus, over the semiconductor substrate 1S, the re-channel I/O transistor Q3 is formed.

Next, a description will be given to the structure of the p-channel I/O transistor Q4 formed in the p-channel I/O transistor formation region PTR(I/O). In FIG. 2, in the main surface of the semiconductor substrate 1S made of a silicon single crystal, the plural isolation regions STI are formed and, in an active region defined by the isolation regions STI, an n-type well NWL2 is formed. The n-type well NWL2 is formed of a semiconductor region into which an n-type impurity such as phosphorus (P) or arsenic (As) has been introduced and, over the n-type well NWL2, the p-channel I/O transistor Q4 is formed.

Specifically, over the n-type well NWL2, the silicon oxide film SO2 is formed and, over the silicon oxide film SO2, the HfSiON film HK2 is formed. The silicon oxide film SO2 and the HfSiON film HK2 form the gate insulating film of the p-channel I/O transistor Q4. Here, if the gate insulating film of the p-channel I/O transistor Q4 is compared with the gate insulating film of the p-channel core transistor Q2 described above, the thickness of the silicon oxide film SO2 of the p-channel I/O transistor Q4 is larger than the thickness of the silicon oxide film SO1 of the p-channel core transistor Q2. On the other hand, the thickness of the HfSiON film HK2 of the p-channel I/O transistor Q4 is the same as the thickness of the HfSiON film HK2 of the p-channel core transistor Q2. Accordingly, the gate insulating film of the p-channel I/O transistor Q4 is formed thicker than the gate insulating film of the p-channel core transistor Q2. This is because a higher voltage is applied to the p-channel I/O transistor Q4 than to the p-channel core transistor Q2. That is, to the p-channel I/O transistor Q4, a higher voltage is applied than to the p-channel core transistor Q2 so that the gate insulating film thereof is formed thick so as not to undergo dielectric breakdown.

In addition, over the HfSiON film HK2, a gate electrode G4 is formed. The gate electrode G4 includes the conductor film CF1 formed over the HfSiON film HK2 and containing a metal, the polysilicon film PF1 formed over the conductor film CF1, and the silicide film SL formed by silicidizing the surface of the polysilicon film PF1. Examples of the conductor film CF1 containing a metal include a titanium nitride film. The silicide film SL is formed of a nickel platinum silicide film, a nickel silicide film, a titanium silicide film, a cobalt silicide film, a platinum silicide film, or the like. The silicide film SL is formed to reduce the resistance of the gate electrode G4. At this time, if the gate length of the p-channel I/O transistor Q4 is compared with the gate length of the p-channel core transistor Q2 described above, the p-channel I/O transistor Q4 is formed to have the gate length larger than the gate length of the p-channel core transistor Q2.

Subsequently, over the both side walls of the gate electrode G4, the offset spacers OS formed of, e.g., a silicon oxide film are formed. Outside the offset spacers OS, the sidewalls SW are formed. Each of the sidewalls SW is formed of, e.g., a laminate film of a silicon oxide film and a silicon nitride film. However, the structure of the sidewall SW is not limited thereto. The sidewall SW can also be formed of a single-layered film of silicon oxide or a single-layered film of silicon nitride.

In the semiconductor substrate 1S under the sidewalls SW, as semiconductor regions, shallow p-type impurity diffusion regions EX4 are formed. Outside the shallow p-type impurity diffusion regions EX4, deep p-type impurity diffusion regions PR2 are formed and, over the surfaces of the deep p-type impurity diffusion regions PR2, the silicide films SL are formed.

The sidewalls SW are formed to impart a LDD structure to each of a source region and a drain region, which are the semiconductor regions of the p-channel I/O transistor Q4. That is, the source region and the drain region of the p-channel I/O transistor Q4 are formed of the shallow p-type impurity diffusion regions EX4, the deep p-type impurity diffusion region PR2, and the silicide films SL. At this time, the impurity concentrations of the shallow p-type impurity diffusion regions EX4 are lower than the impurity concentrations of the deep p-type impurity diffusion regions PR2. Accordingly, by forming the source region and the drain region under the sidewalls SW of the shallow p-type impurity diffusion regions EX4 having the lower impurity concentrations, electric field concentration under the end portions of the gate electrode G4 can be suppressed. Note that the region immediately under the gate insulating film interposed between the source region and the drain region serves as a channel region. Thus, over the semiconductor substrate 1S, the p-channel I/O transistor Q4 is formed.

A description will be given further to the structure of the n-channel resistor element R1 formed in the n-channel resistor element formation region NRR. In FIG. 2, in the main surface of the semiconductor substrate 1S made of a silicon single crystal, the plural isolation regions STI are formed and, in an active region defined by the isolation regions STI, a p-type well PWL3 is formed. The p-type well PWL3 is formed of a semiconductor region into which a p-type impurity such as boron (B) has been introduced and, over the p-type well PWL3, the n-channel resistor element R1 is formed.

Specifically, over the p-type well PWL3, the silicon oxide film SO1 is formed and, over the silicon oxide film SO1, the HfZrSiON film HK1 is formed. In addition, over the HfZrSiON film HK1, a gate electrode G5 is formed. The gate electrode G5 includes the polysilicon film PF1 formed over the HfZrSiON film HK1, and the silicide film SL formed by silicidizing the surface of the polysilicon film PF1. The silicide film SL is formed of a nickel platinum silicide film, a nickel silicide film, a titanium silicide film, a cobalt silicide film, a platinum silicide film, or the like. The silicide film SL is formed to reduce the resistance of the gate electrode G5.

Subsequently, over the both side walls of the gate electrode G5, the offset spacers OS formed of, e.g., a silicon oxide film are formed. Outside the offset spacers OS, the sidewalls SW are formed. Each of the sidewalls SW is formed of, e.g., a laminate film of a silicon oxide film and a silicon nitride film. However, the structure of the sidewall SW is not limited thereto. The sidewall SW can also be formed of a single-layered film of silicon oxide or a single-layered film of silicon nitride.

In the semiconductor substrate 1S under the sidewalls SW, as semiconductor regions, shallow n-type impurity diffusion regions EX5 are formed. Outside the shallow n-type impurity diffusion regions EX5, deep n-type impurity diffusion regions NR3 are formed and, over the surfaces of the deep n-type impurity diffusion regions NR3, the silicide films SL are formed. Thus, over the semiconductor substrate 1S, the re-channel resistor element R1 is formed.

Next, a description will be given to the structure of the p-channel resistor element R2 formed in the p-channel resistor element formation region PRR. In FIG. 2, in the main surface of the semiconductor substrate 1S made of a silicon single crystal, the plural isolation regions STI are formed and, in an active region defined by the isolation regions STI, an n-type well NWL3 is formed. The n-type well NWL3 is formed of a semiconductor region into which an n-type impurity such as phosphorus (P) or arsenic (As) has been introduced and, over the n-type well NWL3, the p-channel resistor element R2 is formed.

Specifically, over the n-type well NWL3, the silicon oxide film SO1 is formed and, over the silicon oxide film SO1, the HfSiON film HK2 is formed. In addition, over the HfSiON film HK2, a gate electrode G6 is formed. The gate electrode G6 includes the polysilicon film PF1 formed over the HfSiON film HK2, and the silicide film SL formed by silicidizing the surface of the polysilicon film PF1. The silicide film SL is formed of a nickel platinum silicide film, a nickel silicide film, a titanium silicide film, a cobalt silicide film, a platinum silicide film, or the like. The silicide film SL is formed to reduce the resistance of the gate electrode G6.

Subsequently, over the both side walls of the gate electrode G6, the offset spacers OS formed of, e.g., a silicon oxide film are formed. Outside the offset spacers OS, the sidewalls SW are formed. Each of the sidewalls SW is formed of, e.g., a laminate film of a silicon oxide film and a silicon nitride film. However, the structure of the sidewall SW is not limited thereto. The sidewall SW can also be formed of a single-layered film of silicon oxide or a single-layered film of silicon nitride.

In the semiconductor substrate 1S under the sidewalls SW, as semiconductor regions, shallow p-type impurity diffusion regions EX6 are formed. Outside the shallow p-type impurity diffusion regions EX6, deep p-type impurity diffusion regions PR3 are formed and, over the surfaces of the deep p-type impurity diffusion regions PR3, the silicide films SL are formed. Thus, over the semiconductor substrate 1S, the p-channel resistor element R2 is formed.

Next, over the semiconductor substrate 1S formed with the n-channel core transistor Q1, the p-channel core transistor Q2, the n-channel I/O transistor Q3, the p-channel I/O transistor Q4, the n-channel resistor element R1, and the p-channel resistor element R2, multilayer wiring is formed. Hereinbelow, the structure of the multilayer wiring will be described. As shown in FIG. 2, over the semiconductor substrate 1S formed with the n-channel core transistor Q1, the p-channel core transistor Q2, the n-channel I/O transistor Q3, the p-channel I/O transistor Q4, the n-channel resistor element R1, and the p-channel resistor element R2, the silicon nitride film SN1 is formed so as to cover the semiconductor elements. Over the silicon nitride film SN1, a contact interlayer insulating film CIL is formed. The contact interlayer insulating film CIL is formed of a laminate film of, e.g., an ozone TEOS film formed by a thermal CVD method using ozone and TEOS (tetra ethyl ortho silicate) as raw materials and a plasma TEOS film formed by a plasma CVD method using TEOS provided over the ozone TEOS film as a raw material.

Next, plugs PLG are formed to extend through the contact interlayer insulating film CIL, and reach the source regions and the drain regions of the n-channel core transistor Q1, the p-channel core transistor Q2, the n-channel I/O transistor Q3, the p-channel I/O transistor Q4, the n-channel resistor element R1, and the p-channel resistor element R2. The plugs PLG are formed by, e.g., filling contact holes CNT with a titanium film, a titanium nitride film formed over the titanium film, and a tungsten film formed over the titanium nitride film. The titanium film and the titanium nitride film are provided for preventing tungsten forming the tungsten film from being diffused into silicon. Note that the contact interlayer insulating film CIL may also be formed of either a silicon dioxide film (SiO₂ film) or a SiOF film.

In addition, over the contact interlayer insulating film CIL, wiring lines L1 are formed as a first wiring layer. Specifically, the wiring lines L1 are formed to be buried in an interlayer insulating film IL1 formed over the contact interlayer insulating film CIL formed with the plugs PLG. That is, by filling wiring trenches extending through the interlayer insulating film IL1 and having bottom portions at which the plugs PLG are exposed with a barrier conductor film and a film (hereinafter referred to as the copper film) containing copper as a main component, the wiring lines L1 are formed. That is, the wiring lines L1 are formed of the barrier conductor film formed to cover the side and bottom surfaces of the wiring trenches and the copper film formed to fill the wiring trenches over the barrier conductor film. Furthermore, over the wiring lines L1, the multilayer wiring is formed but, in the present first embodiment, the description thereof is omitted. In this manner, over the semiconductor substrate 1S, the n-channel core transistor Q1, the p-channel core transistor Q2, the n-channel I/O transistor Q3, the p-channel I/O transistor Q4, the n-channel resistor element R1, and the p-channel resistor element R2 are formed, and the wiring lines L1 are formed over the semiconductor elements.

Subsequently, a detailed description will be given to the structures of the gate insulating films which characterize the present first embodiment. First, by focusing attention on the n-channel core transistor Q1 and the p-channel core transistor Q2 which are described above, the description will be given to the characteristic feature of the present first embodiment.

Conventionally, in, e.g., an n-channel transistor and a p-channel transistor which form an integrated circuit, as the gate insulating films, silicon oxide films or silicon oxynitride films have been used. However, in recent years, with the scaling down of a transistor forming a semiconductor device, the thinning of the gate insulating film has been in rapid progress. When the thickness of the gate insulating film is reduced, due to a tunnel effect, a phenomenon occurs in which electrons pass through the inside of the gate insulating film. The phenomenon allows a tunnel current to flow in the gate insulating film. Accordingly, a leakage current in the transistor increases. On the other hand, when the thickness of the gate insulating film is increased to reduce the leakage current in the transistor, the gate capacitance decreases to reduce the current driving capability.

In view of the foregoing, research has been promoted to use, as a gate insulating film, instead of a silicon oxide film or a silicon oxynitride film, a high-dielectric-constant film having a dielectric constant higher than that of the silicon oxide film as a replacement. This is because, when the gate insulating film is formed of the high-dielectric-constant film, even if the capacitance is the same as when the gate insulating film is formed of the silicon oxide film, the actual physical film thickness can be increased by (Dielectric Constant of High-Dielectric-Constant Film/Dielectric Constant of Silicon Oxide Film) times, and consequently the leakage current can be reduced. In the high-dielectric-constant film, even when the actual physical film thickness is increased, the dielectric constant is high and the electric film thickness, which is given by considering the dielectric constant, can be reduced, and therefore the gate capacitance can be ensured. As a result, even when a transistor using a high-dielectric-constant film as the gate insulating film is scaled down, it is possible to reduce a leakage current therein, and improve the current driving capability thereof.

As a material of such a high-dielectric-constant film, an insulating film containing hafnium (Hf) is considered to be promising. Examples of the insulating film containing hafnium include a HfSiON film, a HfSiO film, a HfON film, and a HfO film. However, the insulating film containing hafnium has the problem that a large number of fixed charges and trap levels are formed therein. That is, in the insulating film containing hafnium, the large number of fixed charges and trap levels are contained, and therefore the problem arises that fluctuations in the threshold voltage of the transistor and a reduction in the mobility of carriers are caused thereby.

For example, the fixed charges assume charges and, when electrons are trapped in the trap levels, by the charges of the trapped electrons, an insulating film (gate insulating film) containing hafnium is charged. That is, the insulating film containing hafnium in which the fixed charges and the trap levels are present is charged so that, when the insulating film containing hafnium is used as a gate insulating film, the charges produced in the film cause fluctuations in the threshold voltage of the transistor.

In addition, the fixed charges present in the insulating film containing hafnium generate an electric field, and the electrons trapped in the trap levels also generate an electric field. When the insulating film containing hafnium is used as the gate insulating film, the electric field resulting from the fixed charges or the electrons trapped in the trap levels affects the channel region formed immediately under the gate insulating film. That is, the channel region is a path for the electrons between the source region and the drain region but, if the electric field resulting from the fixed charges or the electrons trapped in the trap levels reaches the channel region, the electrons passing through the channel region are scattered by the electric field. Accordingly, the mobility of the electrons passing through the channel region undesirably decreases. As a result, the current driving capability of the transistor cannot be sufficiently improved.

Moreover, the fixed charges and the trap levels present in the insulating film containing hafnium degrade the reliability of the transistor. In particular, an increase in the degradation of PBTI (Positive Bias Temperature Instability) occurring in an n-channel transistor has become an obvious problem. PBTI is a phenomenon in which a continuous application of a positive voltage (positive bias) to the gate electrode of a transistor causes fluctuations in the threshold voltage of the transistor or a reduction in current driving capability. The phenomenon mostly occurs in an n-channel transistor since, when an ON operation of the n-channel transistor is to be performed, a positive voltage (positive bias) is applied to the gate electrode. It is considered that, when the insulating film containing hafnium is used as the gate insulating film, the large number of fixed charges and trap levels formed in the insulating film containing hafnium affect the degradation of PBTI.

Thus, to achieve a reduction in the leakage current which increases with the thinning of a gate insulating film, it is useful to use the insulating film containing hafnium, which is a high-dielectric-constant film, as the gate insulating film. However, in the insulating film containing hafnium, the large number of fixed charges and trap levels are present, and it will be understood that the fixed charges and the trap levels are an impediment to achieving improvements in the performance and reliability of the transistor.

Therefore, in the present first embodiment, measures have been taken such that, even when the insulating film containing hafnium is used as the gate insulating film, the performance and reliability of the transistor can be sufficiently improved. Hereinbelow, a description will be given to a characteristic feature of the present first embodiment for which the measures have been taken.

In FIG. 2, when attention is focused on the n-channel core transistor Q1, the gate insulating film of the n-channel core transistor Q1 is formed of the silicon oxide film SO1 and the HfZrSiON film HK1. At this time, the use of the HfZrSiON film HK1 containing hafnium and zirconium as a high-dielectric-constant film is the characteristic feature of the present first embodiment. That is, in the present first embodiment, as the high-dielectric-constant film containing hafnium, not a HfSiON film containing hafnium, but the HfZrSiON film HK1 containing hafnium and zirconium is used. The reason for this will be described below.

Examples of the insulating film containing hafnium include a HfSiON film but, in the HfSiON film, there are a large number of fixed charges and trap levels, as described above. In view of this, the present inventors have conducted a dedicated study on how to achieve reductions in the fixed charges and trap levels present in the insulating film containing hafnium, and consequently focused attention on the fact that, when the HfSiON film is caused to contain zirconium, the fixed charges and trap levels present in the film can be reduced. In other words, the present inventors have focused attention on the fact that the insulating film containing hafnium and zirconium can achieve greater reductions in fixed charges and trap levels than the insulating film containing hafnium. When the HfZrSiON film HK1 containing hafnium and zirconium is thus used as the gate insulating film, because the HfZrSiON film HK1 is intrinsically a high-dielectric-constant film, even when the transistor is scaled down, it is possible to reduce a leakage current therein and improve the current driving capability thereof.

In the HfZrSiON film HK1, the fixed charges and the trapped levels can be reduced, and therefore it is possible to suppress fluctuations in the threshold voltage of the transistor and a reduction in the mobility of carries, each resulting from the fixed charges and the trapped levels. Thus, by using the HfZrSiON film HK1 as the gate insulating film, the performance of the transistor can be improved. Additionally, in the present first embodiment, the HfZrSiON film HK1 is used as the gate insulating film of the n-channel core transistor Q1 to achieve reductions in fixed charges and trap levels. As described above, particularly in n-channel transistors (including the n-channel core transistor Q1), the degradation of PBTI resulting from the fixed charges or trap levels is obvious. Accordingly, by using the HfZrSiON film HK1 containing hafnium and zirconium as the gate insulating film of the n-channel core transistor Q1 and reducing the fixed charges and the trap levels, it is possible to greatly improve PBTI, and consequently improve the reliability of the re-channel core transistor Q1.

Note that, in the present first embodiment, as the gate insulating film, the laminate film of the silicon oxide film SO1 and the HfZrSiON film HK1 is used and, between the HfZrSiON film HK1 and the semiconductor substrate 1S, the silicon oxide film SO1 is interposed. This is because, when the HfZrSiON film HK1, which is a high-dielectric-constant film, is brought into direct contact with the semiconductor substrate 1S, the surface roughness (unevenness of the surface) of the HfZrSiON film HK1 scatters carriers flowing in the channel region immediately under the gate insulating film, and reduces the mobility of the carriers. That is, in terms of suppressing a reduction in the mobility of the carriers, the silicon oxide film SO1 having excellent surface flatness is interposed between the HfZrSiON film HK1 and the semiconductor substrate 1S. Thus, it is desirable to interpose the silicon oxide film SO1 having excellent surface flatness between the HfZrSiON film HK1 and the semiconductor substrate 1S, but the silicon oxide film SO1 need not necessarily be provided.

In the present first embodiment, as the gate insulating film of the n-channel core transistor Q1, the insulating film containing hafnium and zirconium is used and, as an example of the insulating film containing hafnium and zirconium, the HfZrSiON film HK1 is mentioned. However, the gate insulating film of the n-channel core transistor Q1 is not limited thereto. Even when a HfZrSiO film, a HfZrON film, a HfZrO film, or the like is used, the same effect can be obtained.

Next, in FIG. 2, when attention is focused on the p-channel core transistor Q2, the gate insulating film of the p-channel core transistor Q2 is formed of the silicon oxide film SO1 and the HfSiON film HK2. Here, it can be considered that, in the p-channel core transistor Q2 also, if the HfZrSiON film HK1 is used as the high-dielectric-constant film instead of the HfSiON film HK2 in the same manner as in the n-channel core transistor Q1, zirconium contained therein reduces the fixed charges and the trap levels in the film. However, in the present first embodiment, as the gate insulating film of the p-channel core transistor Q2, not the HfZrSiON film HK1, but the HfSiON film HK2 is used. The reason for this will be described below.

First of all, if the HfSiON film HK2 is caused to contain zirconium to provide the HfZrSiON film HK1, the physical film thickness of the HfZrSiON film HK1 is increased to be larger than the physical film thickness of the HfSiON film HK2 by zirconium contained therein. Accordingly, if the HfZrSiON film HK1 is used in each of the n-channel core transistor Q1 and the p-channel core transistor Q2, the physical film thickness of the gate insulating film of the n-channel core transistor Q1 becomes the same as the physical film thickness of the gate insulating film of the p-channel core transistor Q2.

Here, it is known that, if the physical film thickness of the gate insulating film of the n-channel core transistor Q1 is set the same as the physical film thickness of the gate insulating film of the p-channel core transistor Q2, the electric film thickness of the gate insulating film of the p-channel core transistor Q2 becomes larger than the electric film thickness of the gate insulating film of the n-channel core transistor Q1. That is, in the case where the gate insulating films having the same physical film thicknesses are used in the n-channel core transistor Q1 and the p-channel core transistor Q2, the electric film thickness of the p-channel core transistor Q2 becomes larger than the electric film thickness of the n-channel core transistor Q1. The electric film thickness is a film thickness given by focusing attention on a gate capacitance, and also considering a dielectric constant.

This means that, if the gate insulating films made of the same material and having the same physical film thicknesses are used in the n-channel core transistor Q1 and the p-channel core transistor Q2, the electric film thickness of the p-channel core transistor Q2 becomes larger than the electric film thickness of the n-channel core transistor Q1, and consequently the gate capacitance of the p-channel core transistor Q2 becomes smaller than the gate capacitance of the n-channel core transistor Q1. In this case, the current driving capability of the n-channel core transistor Q1 and the current driving capability of the p-channel core transistor Q2 are unbalanced so that circuit design is difficult.

Thus, when the HfZrSiON film HK1 similar to the gate insulating film of the n-channel core transistor Q1 is used as the gate insulating film of the p-channel core transistor Q2, the disadvantage arises that the electric film thickness of the p-channel core transistor Q2 becomes larger than the electric film thickness of the n-channel core transistor Q1.

On the other hand, the advantage of using the HfZrSiON film HK1 is that the fixed charges and trap levels present in the film can be reduced. In particular, in the n-channel core transistor Q1, reductions in fixed charges and trap levels result in a significant improvement in PBTI, and therefore the advantage of using the HfZrSiON film HK1 in the n-channel core transistor Q1 increases. By contrast, in the p-channel core transistor Q2, even when the HfZrSiON film HK1 is used as the gate insulating film, the effect of improving NBTI (Negative Bias Temperature Instability) is rather small, and the advantage of using the HfZrSiON film HK1 in the p-channel core transistor Q2 is small. Here, NBTI is a phenomenon in which a continuous application of a negative voltage (negative bias) to the gate electrode of a transistor causes fluctuations in the threshold voltage of the transistor or a reduction in the current driving capability thereof. The phenomenon mostly occurs in a p-channel transistor since, when an ON operation of the p-channel transistor is to be performed, a negative voltage (negative bias) is applied to the gate electrode.

Thus, when the HfZrSiON film HK1 is used as the gate insulating film in the p-channel core transistor Q2, the advantage of improved NBTI is overridden by the disadvantage that the physical film thickness of the gate insulating film increases, and consequently the electric film thickness of the p-channel core transistor Q2 also increases to reduce the gate capacitance. Therefore, in the present first embodiment, in the p-channel core transistor Q2, not the HfZrSiON film HK1, but the HfSiON film HK2 is used.

Note that, in the present first embodiment, as the gate insulating film, the laminate film of the silicon oxide film SO1 and the HfSiON film HK2 is used and, between the HfSiON film HK2 and the semiconductor substrate 1S, the silicon oxide film SO1 is interposed. This is because, when the HfSiON film HK2, which is a high-dielectric-constant film, is brought into direct contact with the semiconductor substrate 1S, the surface roughness (unevenness of the surface) of the HfSiON film HK2 scatters carriers flowing in the channel region immediately under the gate insulating film, and reduces the mobility of the carriers. That is, in terms of suppressing a reduction in the mobility of the carriers, the silicon oxide film SO1 having excellent surface flatness is interposed between the HfSiON film HK2 and the semiconductor substrate 1S. Thus, it is desirable to interpose the silicon oxide film SO1 having excellent surface flatness between the HfSiON film HK2 and the semiconductor substrate 1S, but the silicon oxide film SO1 need not necessarily be provided.

In the present first embodiment, as the gate insulating film of the p-channel core transistor Q2, the insulating film containing hafnium is used and, as an example of the insulating film containing hafnium, the HfSiON film HK2 is mentioned. However, the gate insulating film of the p-channel core transistor Q2 is not limited thereto, and a HfSiO film, a HfON film, a HfO film, or the like may also be used.

The following is the summary of the characteristic feature of the present first embodiment described above. That is, in the present first embodiment, the gate insulating film of the n-channel core transistor Q1 and the gate insulating film of the p-channel core transistor Q2 are provided with different structures. Specifically, in the present first embodiment, as the gate insulating film of the n-channel core transistor Q1, the laminate film of the silicon oxide film SO1 and the HfZrSiON film HK1 is used. On the other hand, as the gate insulating film of the p-channel core transistor Q2, the laminate film of the silicon oxide film SO1 and the HfSiON film HK2 is used.

By thus using the HfZrSiON film HK1 containing hafnium and zirconium as the gate insulating film of the n-channel core transistor Q1 and reducing the fixed charges and the trap levels, it is possible to greatly improve PBTI, and consequently improve the reliability of the n-channel core transistor Q1. In addition, since the fixed charges and the trap levels can be reduced, fluctuations in threshold voltage and a reduction in current driving capability can also be suppressed.

Also, the HfZrSiON film HK1 containing zirconium has a physical film thickness which is accordingly larger than that of the HfSiON film HK2. Consequently, in the present first embodiment, the use of the HfSiON film HK2, not the HfZrSiON film HK1, as the gate insulating film of the p-channel core transistor Q2 allows the physical film thickness of the gate insulating film of the p-channel core transistor Q2 to be smaller than the physical film thickness of the gate insulating film of the n-channel core transistor Q1. As a result, even when a phenomenon occurs in which the electric film thickness of the p-channel core transistor Q2 becomes larger than the electric film thickness of the n-channel core transistor Q1, since the physical film thickness of the p-channel core transistor Q2 is set smaller than the physical film thickness of the n-channel core transistor Q1, it is consequently possible to allow the gate capacitance of the p-channel core transistor Q2 to be substantially the same as the gate capacitance of the n-channel core transistor Q1. Therefore, according to the present first embodiment, the advantage is obtained that the current driving capability of the n-channel core transistor Q1 and the current driving capability of p-channel core transistor Q2 are well balanced, and circuit design can be easily performed.

Note that, in the present first embodiment, as the gate insulating film of the n-channel core transistor Q1, the HfZrSiON film HK1 is used and, as the gate insulating film of the p-channel core transistor Q2, the HfSiON film HK2 is used. Accordingly, it can be said that, as the gate insulating film of the n-channel core transistor Q1, an insulating film containing hafnium and zirconium is used and, as the gate insulating film of the p-channel core transistor Q2, an insulating film containing hafnium is used. At this time, zirconium is basically not contained in the HfSiON film HK2 used as the gate insulating film of the p-channel core transistor Q2. However, it can be considered that, in an actual manufacturing process, a small amount of zirconium may be mixed as an impurity in the HfSiON film HK2. Therefore, the technical idea of the present first embodiment has given consideration to the fact that, even though zirconium is not positively caused to be contained in the HfSiON film HK2 of the p-channel core transistor Q2, in the manufacturing process, zirconium may be unintentionally contained as an impurity in the HfSiON film HK2. That is, it can be said that, in the structure of the present first embodiment, the concentration of zirconium contained in the HfZrSiON film HK1 is higher than the concentration of zirconium contained in the HfSiON film HK2. At this time, the case is naturally included where the HfSiON film HK2 does not contain zirconium.

Thus far, the description has been given to the gate insulating film of the n-channel core transistor Q1 and the gate insulating film of the p-channel core transistor Q2, but the same holds true for the gate insulating film of the re-channel I/O transistor Q3 and the gate insulating film of the p-channel I/O transistor Q4. That is, as shown in FIG. 2, the gate insulating film of the n-channel I/O transistor Q3 includes the silicon oxide film SO2 and the HfZrSiON film HK1, and the gate insulating film of the p-channel I/O transistor Q4 includes the silicon oxide film SO2 and the HfSiON film HK2. In addition, the physical film thickness of the HfZrSiON film HK1 is larger than the physical film thickness of the HfSiON film HK2.

Also, the same holds true for the gate insulating film of the n-channel resistor element R1 and the gate insulating film of the p-channel resistor element R2. That is, as shown in FIG. 2, the gate insulating film of the n-channel resistor element R1 includes the silicon oxide film SO1 and the HfZrSiON film HK1, and the gate insulating film of the p-channel resistor element R2 includes the silicon oxide film SO1 and the HfSiON film HK2. In addition, the physical film thickness of the HfZrSiON film HK1 is larger than the physical film thickness of the HfSiON film HK2.

Subsequently, a description will be given to the reason for using the laminate film of the conductor film CF1 containing a metal and the polysilicon film PF1 in each of the n-channel core transistor Q1, the p-channel core transistor Q2, the n-channel I/O transistor Q3, and the p-channel I/O transistor Q4.

For example, in the case where a silicon oxide film or a silicon oxynitride film is used as a gate insulating film, a gate electrode formed over the gate insulating film is typically formed of a polysilicon film. In an n-channel MISFET, into a polysilicon film forming the gate electrode, an n-type impurity (such as phosphorus or arsenic) is introduced. By thus setting the work function (Fermi level) of the gate electrode to a value in the vicinity of the conduction band of silicon (in the vicinity of 4.05 eV), it is possible to achieve a reduction in the threshold voltage of the n-channel MISFET. On the other hand, in a p-channel MISFET, a p-type impurity (such as boron) is introduced into a polysilicon film forming the gate electrode. By thus setting the work function of the gate electrode to a value in the vicinity of the valence band of silicon (in the vicinity of 5.17 eV), it is possible to achieve a reduction in the threshold voltage of the p-channel MISFET. Briefly, in the case where a silicon oxide film or a silicon oxynitride film is used as a gate insulating film, by introducing an n-type impurity or a p-type impurity into the gate electrode, the work function of the gate electrode can be set to a value in the vicinity of the conduction band or the valence band.

However, if a high-dielectric-constant film (HfZrSiON film HK1 or HfSiON film HK2) is used as a gate insulating film as in the present first embodiment, a phenomenon occurs in which, even when an n-type impurity or a p-type impurity is introduced into a gate electrode formed of a polysilicon film, the work function of the gate electrode does not have a value in the vicinity of the conduction band or the valence band. That is, when a high-dielectric-constant film (HfZrSiON film HK1 or HfSiON film HK2) is used as the gate insulating film of the n-channel MISFET, the work function of the gate electrode increases to a value away from the vicinity of the conduction band so that the threshold voltage of the n-channel MISFET increases. On the other hand, when a high-dielectric-constant film (HfZrSiON film HK1 or HfSiON film HK2) is used as the gate insulating film of the p-channel MISFET, the work function of the gate electrode decreases to a value away from the vicinity of the valence band so that the threshold voltage thereof increases similarly to that of the n-channel MISFET. A phenomenon in which the work function of a gate electrode thus shifts in the direction in which the threshold voltage increases is interpreted as Fermi level pinning. Therefore, it will be understood that, when a high-dielectric-constant film is used as a gate insulating film, if a gate electrode is formed of a polysilicon film, the threshold voltage cannot be properly adjusted.

Accordingly, when a high-dielectric-constant film having a dielectric constant higher than that of a silicon oxide film is used as a gate insulating film, in the present first embodiment, each of the gate electrodes G1 to G4 disposed over the gate insulating film is not formed of a single-layered film of polysilicon. Instead, the conductor film CF1 (e.g., titanium nitride film) containing a metal is formed to come in direct contact with the gate insulating film, and the polysilicon film PF1 is formed over the conductor film CF1. That is, in the present first embodiment, each of the gate electrodes G1 to G4 is formed of the laminate film of the conductor film CF1 and the polysilicon film PF1. Each of the gate electrodes G1 to G4 having such a structure is called a MIPS (Metal Inserted Poly Silicon) electrode.

In the case where each of the gate electrodes G1 to G4 is thus formed of the MIPS electrode, the conductor film CF1 is in direct contact with the gate insulating film. As a result, with the MIPS electrode, the threshold voltage can be adjusted by choosing the type of the conductor film CF1 without introducing an impurity to adjust the threshold, unlike with a polysilicon film into which an impurity is introduced for threshold adjustment. Therefore, by using the MIPS electrode as each of the gate electrodes G1 to G4, it is possible to circumvent the problem of Fermi level pinning described above.

A description will be given further to another reason for using the MIPS electrode as each of the gate electrodes G1 to G4. For example, if a polysilicon film is formed directly over the gate insulating film, a depletion region is formed in the interfacial portion of the polysilicon film with the gate insulating film. Since the depletion region functions as an insulating region, a phenomenon occurs in which the depletion region becomes a capacitor insulating film, and the gate insulating film becomes apparently thick. As a result, the gate capacitance becomes smaller than a design value to make it difficult to ensure an ON current for the MISFET, and cause the problem of a reduction in the operating speed of the MISFET. The problem of the depletion of the polysilicon film has become obvious with the scaling down of the MISFET.

To solve the problem, the present first embodiment uses the MIPS electrode as each of the gate electrodes G1 to G4. In the MIPS electrode, the conductor film CF1 is in direct contact with the gate insulating film so that the problem of depletion does not occur. That is, the conductor film CF1 is a metal and does not undergo depletion, unlike a semiconductor, so that the problem of the depletion of the gate electrodes G1 to G4 does not occur. As a result, it is possible to prevent the gate capacitance from being smaller than the design value and, even when the MISFET is scaled down, the ON current can be ensured.

Thus, in the present first embodiment, by using the MIPS electrode as each of the gate electrodes G1 to G4, it is possible to circumvent the problem of Fermi level pinning and the problem of depletion which occur when each of the gate electrodes G1 to G4 is formed of a single-layered film of polysilicon.

Here, since the problem of Fermi level pinning and the problem of depletion can be solved by forming each of the gate electrodes G1 to G4 of the conductor film CF1, it can also be considered to form each of the gate electrodes G1 to G4 of a single-layered film of the conductor film CF1. However, in the present first embodiment, each of the gate electrodes G1 to G4 is not formed of a single-layered film of metal. Instead, each of the gate electrodes G1 to G4 is formed of the MIPS electrode, which is the laminate film of the conductor film CF1 and the polysilicon film PF1. The reason for this will be described below.

With the scaling down of the MISFETs, it is also required to increase the processing accuracy of the gate electrodes G1 to G4. However, in general, the processing of the conductor film CF1 (metal film) is difficult. Accordingly, when each of the gate electrodes G1 to G4 is formed of the single-layered film of the conductor film CF1 (metal film), the thickness of the conductor film CF1 (metal film) increases to make it difficult to improve the processing accuracy of the gate electrodes G1 to G4. That is, when each of the gate electrodes G1 to G4 is formed of the single-layered film of the conductor film CF1 (metal film), it is difficult to improve the processing accuracy, and form the gate electrodes G1 to G4 each having a gate length which is exactly the same as a design value. In this case, it becomes difficult to obtain a prescribed electric characteristic. In addition, in the plural MISFETs, variations in gate length undesirably increase.

To overcome the difficulties, the present first embodiment forms each of the gate electrodes G1 to G4 not of the single-layered film of the conductor film CF1 (metal film), but of the laminate film of the conductor film CF1 (metal film) and the polysilicon film PF1. By thus forming the gate electrodes G1 to G4, it is possible to reduce the thickness of the conductor film CF1 (metal film), and therefore reduce the difficulty of processing the conductor film CF1 (metal film). Since the polysilicon film PF1 is easy to process, by forming each of the gate electrodes G1 to G4 as the MIPS electrode, even when the gate electrodes G1 to G4 are scaled down, it is possible to satisfactorily maintain the processing accuracy of the gate electrodes G1 to G4 to provide the advantage that a desired electric characteristic is easily obtainable.

Therefore, in the present first embodiment, to solve the problems of Fermi level pinning and depletion, the conductor film CF1 (metal film) is used so as to come in direct contact with the gate insulating film and, to reduce the difficulty of processing the conductor film CF1 (metal film), the laminate film of the conductor film CF1 (metal film) and the polysilicon film PF1 is used as each of the gate electrodes G1 to G4. That is, by forming the gate electrodes G1 to G4 of the MIPS electrodes as in the first embodiment, it is possible to suppress the Fermi level pinning and depletion, and also reduce the difficulty of processing.

The semiconductor device in the present first embodiment is thus structured and, hereinbelow, a description will be given to a manufacturing method thereof with reference to the drawings.

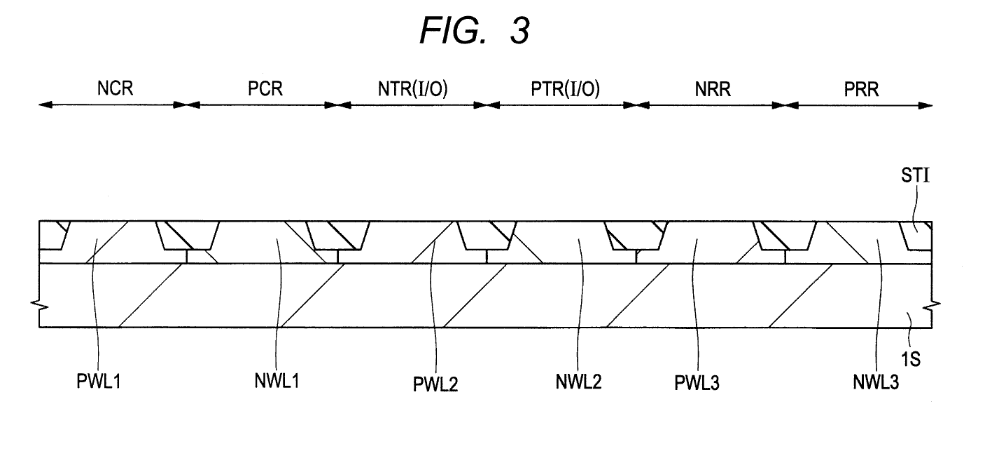

First, as shown in FIG. 3, the semiconductor substrate 1S made of a silicon single crystal into which a p-type impurity such as boron (B) has been introduced is prepared. At this time, the semiconductor substrate 1S is in the form of a semiconductor wafer having a generally disk-like shape. Then, in the semiconductor substrate 1S, the isolation regions STI for providing isolation between elements are formed. The isolation regions STI are provided to prevent mutual interference between the elements. The isolation regions STI can be formed using, e.g., a LOCOS (local Oxidation of silicon) method or a STI (shallow trench isolation) method. For example, in the STI method, the isolation regions STI are formed as follows. That is, in the semiconductor substrate 1S, using a photolithographic technique and an etching technique, isolation trenches are formed. Then, over the semiconductor substrate, a silicon oxide film is formed so as to be buried in the isolation trenches. Thereafter, by a chemical mechanical polishing (CMP) method, the unneeded silicon oxide film formed over the semiconductor substrate is removed. In this manner, the isolation regions STI can be formed in which the silicon oxide film is buried only in the isolation trenches.

Next, into the active regions isolated by the isolation regions STI, an impurity is introduced to form the p-type wells PWL1 to PWL3. Specifically, in the active region of the n-channel core transistor formation region NCR, the p-type well PWL1 is formed and, in the active region of the n-channel I/O transistor formation region NTR(I/O), the p-type well PWL2 is formed. Then, in the active region of the n-channel resistor element formation region NRR, the p-type well PWL3 is formed. The p-type wells PWL1 to PWL3 are formed by introducing a p-type impurity such as, e.g., boron into the semiconductor region 1S by an ion implantation method.

Meanwhile, into the active regions isolated by the isolation regions STI, an impurity is introduced to form the n-type wells NWL1 to NWL3. Specifically, in the active region of the p-channel core transistor formation region PCR, the n-type well NWL1 is formed and, in the active region of the p-channel I/O transistor formation region PTR(I/O), the n-type well NWL2 is formed. Then, in the active region of the p-channel resistor element formation region PRR, the n-type well NWL3 is formed. The n-type wells NWL1 to NWL3 are formed by introducing an n-type impurity such as, e.g., phosphorus or arsenic into the semiconductor region 1S by an ion implantation method.

Subsequently, in the surface regions of the p-type wells PWL1 to PWL3, semiconductor regions (not shown) for forming channels are formed. The semiconductor regions for forming the channels are formed to adjust the threshold voltages of the transistors including the channels to be formed. Likewise, in the surface regions of the n-type wells NWL1 to NWL3, semiconductor regions (not shown) for forming channels are formed. The semiconductor regions for forming the channels are formed to adjust the threshold voltages of the transistors including the channels to be formed.

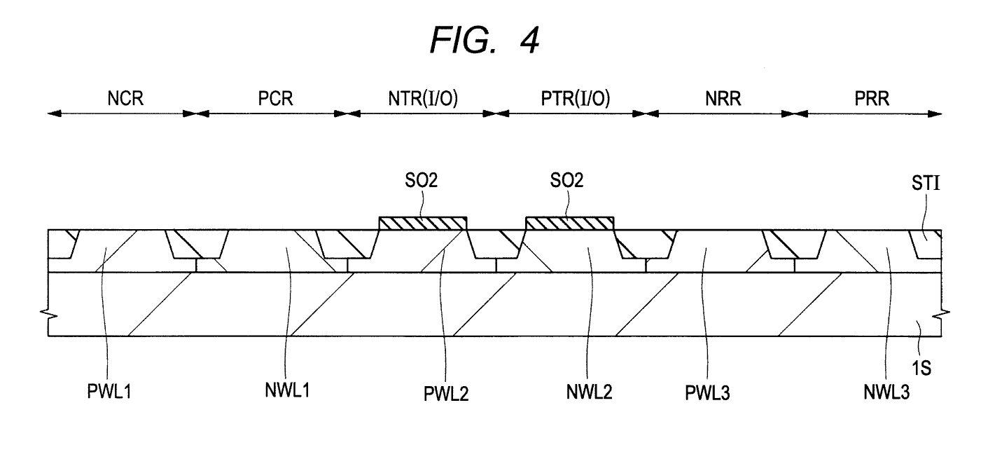

Next, as shown in FIG. 4, over the main surface of the semiconductor substrate 1S, by using, e.g., a thermal oxidation method, the silicon oxide film SO2 is formed. Then, by using a photolithographic technique and an etching technique, the silicon oxide film SO2 formed in the n-channel core transistor formation region NCR, the p-channel core transistor formation region PCR, the n-channel resistor element formation region NRR, and the p-channel resistor element formation region PRR is removed. As a result, only in the n-channel I/O transistor formation region NTR(I/O) and the p-channel I/O transistor formation region PTR(I/O), the silicon oxide film SO2 remains.

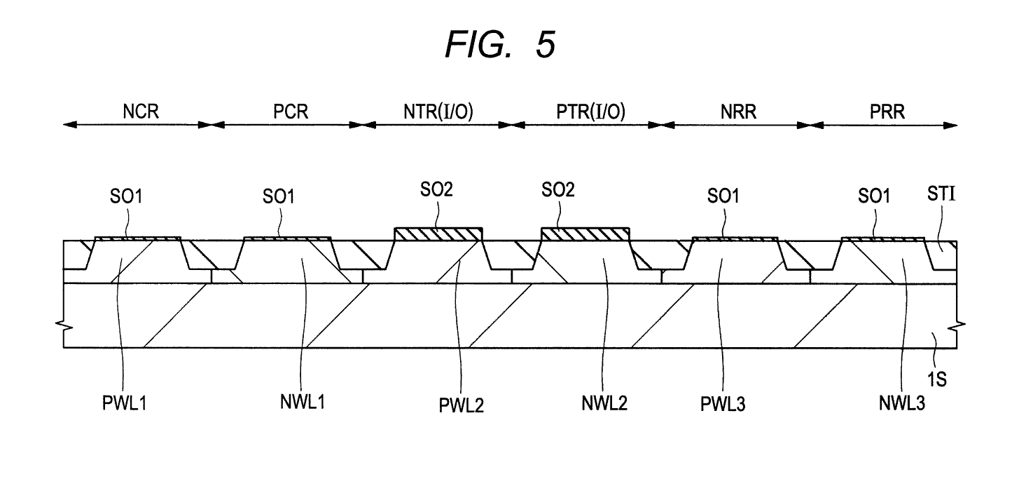

Subsequently, as shown in FIG. 5, over the main surface of the semiconductor substrate 1S, by using, e.g., a thermal oxidation method, the silicon oxide film SO1 is formed. As a result, the silicon oxide film SO1 is formed in each of the re-channel core transistor formation region NCR, the p-channel core transistor formation region PCR, the n-channel resistor element formation region NRR, and the p-channel resistor element formation region PRR. At this time, the silicon oxide film SO1 is formed such that the physical film thickness thereof is larger than the physical film thickness of the silicon oxide film SO2.

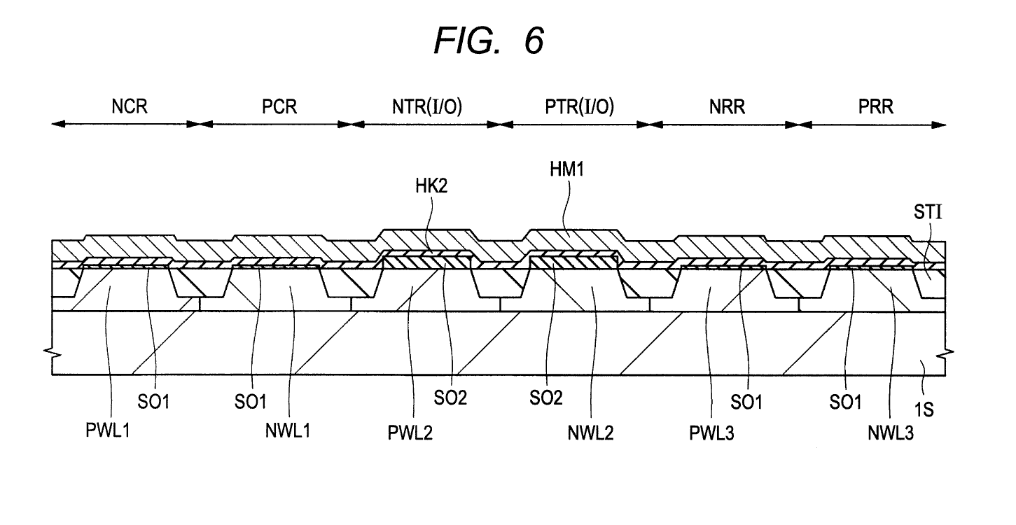

Thereafter, as shown in FIG. 6, over the semiconductor substrate 1S formed with the silicon oxide films SO1 and SO2, the HfSiON film HK2 is formed and, over the HfSiON film HK2, a hard mask film HM1 is formed. The HfSiON film HK2 can be formed by using, e.g., a sputtering method, a CVD (Chemical Vapor Deposition) method, or an ALD (Atomic Layer Deposition) method. Note that, instead of the HfSiON film HK2, another hafnium-based insulating film such as a HfSiO film, a HfON film, or a HfO film can also be used. The hard mask film HM1 is formed of, e.g., a titanium nitride film, and can be formed by using, e.g., a sputtering method.

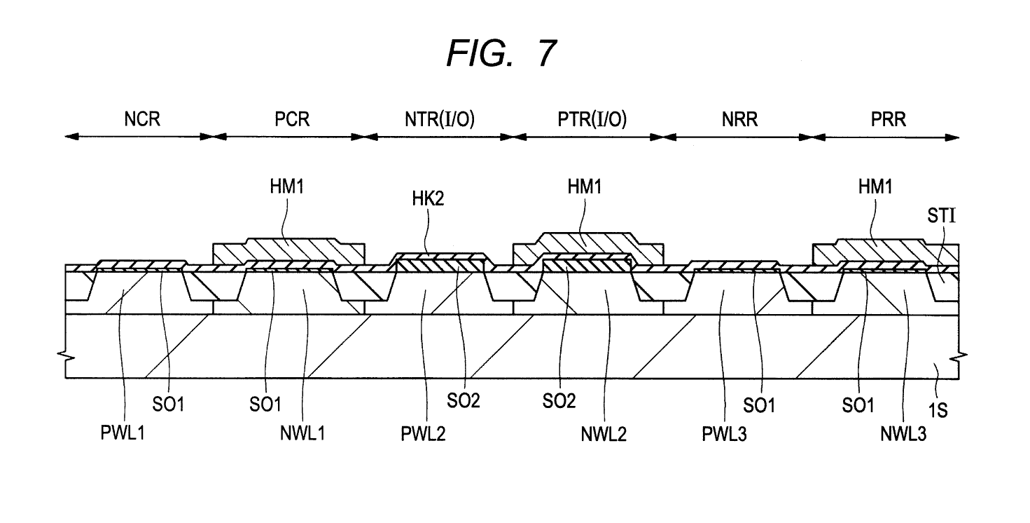

Then, as shown in FIG. 7, by using a photolithographic technique and an etching technique, the hard mask film HM1 is patterned. The patterning of the hard mask film HM1 is performed so as to remove the hard mask film HM1 formed in the n-channel core transistor formation region NCR, the n-channel I/O transistor formation region NTR(I/O), and the n-channel resistor element formation region NRR. As a result, the hard mask film HM1 formed in the p-channel core transistor formation region PCR, the p-channel I/O transistor formation region PTR(I/O), and the p-channel resistor element formation region PRR remains.

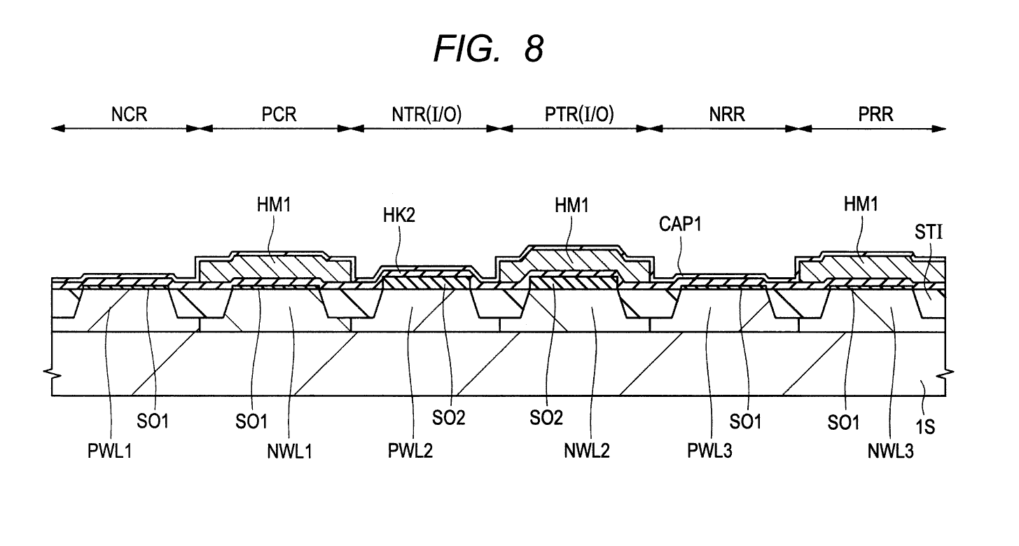

Next, as shown in FIG. 8, over the patterned hard mask film HM1, a cap film CAP1 is formed. The cap film CAP1 is formed of, e.g., a Zr (zirconium) film or a ZrO (zirconium oxide) film, and can be formed by using, e.g., a sputtering method. In this manner, in the n-channel core transistor formation region NCR, the n-channel I/O transistor formation region NTR(I/O), and the n-channel resistor element formation region NRR, the cap film CAP1 is formed directly over the HfSiON film HK2. On the other hand, in the p-channel core transistor formation region PCR, the p-channel I/O transistor formation region PTR(I/O), and the p-channel resistor element formation region PRR, the cap film CAP1 is formed over the hard mask film HM1.

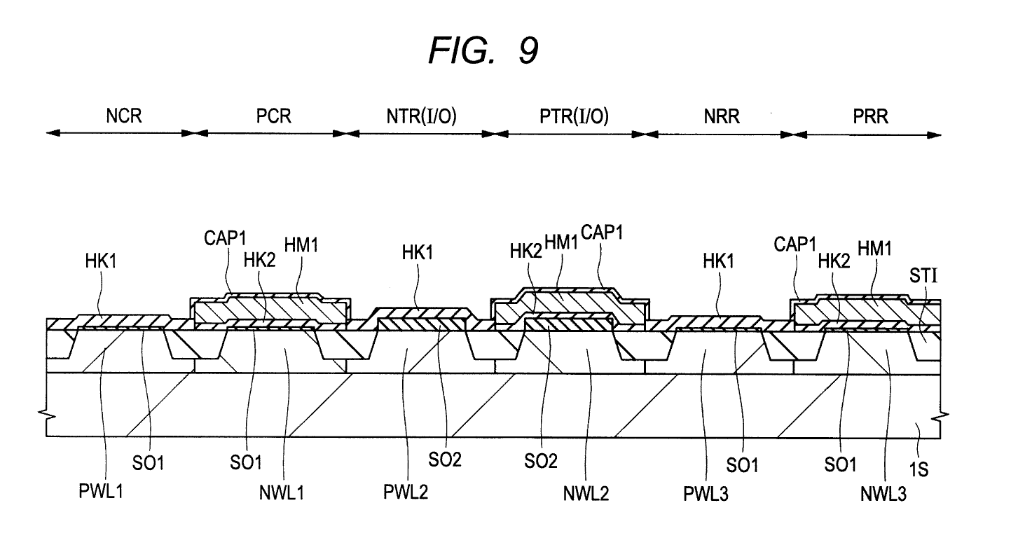

Subsequently, as shown in FIG. 9, a heat treatment is performed to the semiconductor substrate 1S. In the n-channel core transistor formation region NCR, the n-channel I/O transistor formation region NTR(I/O), and the n-channel resistor element formation region NRR, the cap film CAP1 is formed directly over the HfSiON film HK2 so that zirconium (Zr) contained in the cap film CAP1 is diffused into the HfSiON film HK2 by the heat treatment mentioned above. As a result, the HfZrSiON film HK1 is formed. On the other hand, in the p-channel core transistor formation region PCR, the p-channel I/O transistor formation region PTR(I/O), and the p-channel resistor element formation region PRR, the cap film CAP1 is formed over the hard mask film HM1 so that zirconium contained in the cap film CAP1 is not diffused into the HfSiON film HK2. In this manner, in the n-channel core transistor formation region NCR, the n-channel I/O transistor formation region NTR(I/O), and the n-channel resistor element formation region NRR, the HfZrSiON film HK1 is formed. On the other hand, in the p-channel core transistor formation region PCR, the p-channel I/O transistor formation region PTR(I/O), and the p-channel resistor element formation region PRR, the HfSiON film HK2 remains without any alteration. Here, the HfZrSiON film HK1 contains zirconium, and accordingly has a physical film thickness larger than that of the HfSiON film HK2 which does not contain zirconium.

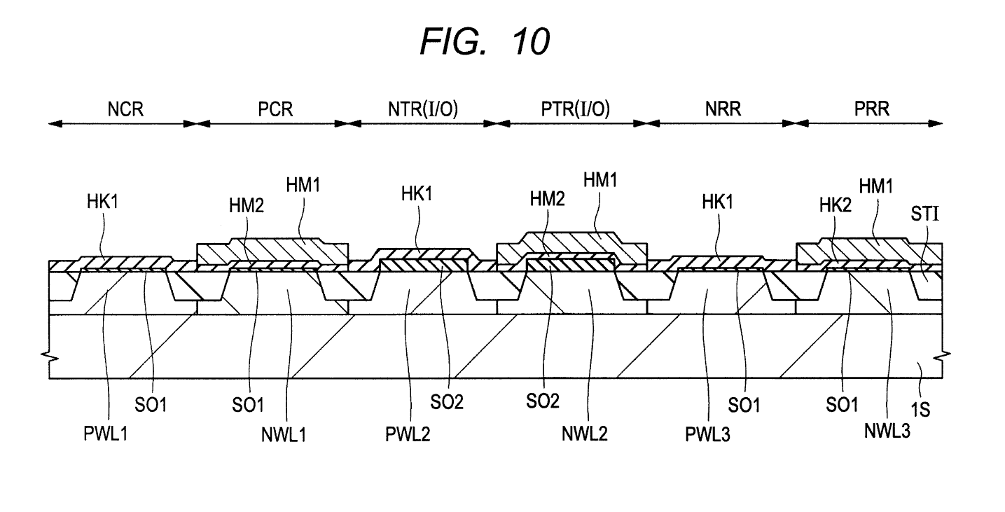

Thereafter, a resist film (not shown) is coated over the semiconductor substrate 1S, and the coated resist film is subjected to an exposure/development treatment so as to be patterned. The patterning of the resist film is performed such that the resist film remains in the n-channel core transistor formation region NCR, the n-channel I/O transistor formation region NTR(I/O), and the n-channel resistor element formation region NRR. In other words, the patterning of the resist film is performed such that the resist film does not remain in the p-channel core transistor formation region PCR, the p-channel I/O transistor formation region PTR(I/O), and the p-channel resistor element formation region PRR. Then, as shown in FIG. 10, by etching using the patterned resist film as a mask, the cap film CAP1 formed over the hard mask film HM1 is removed.

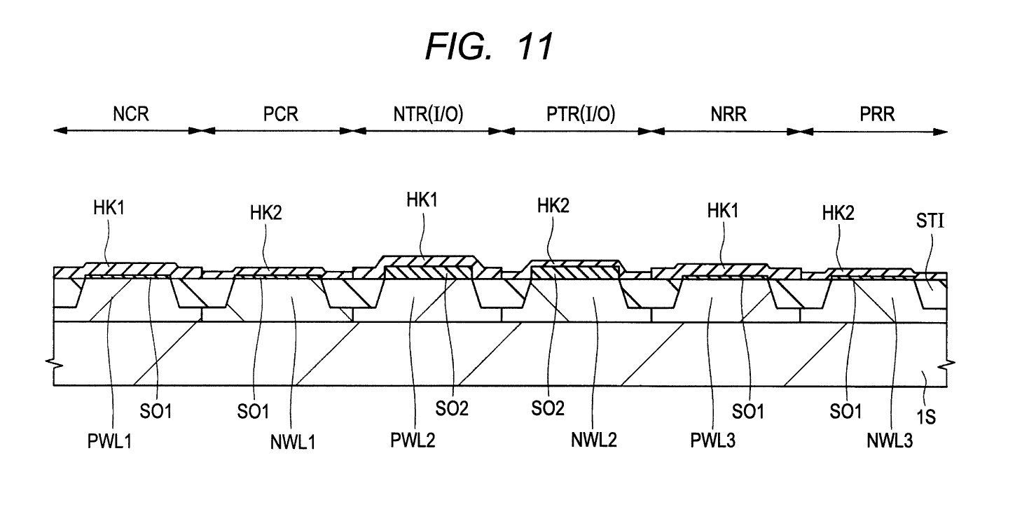

Next, as shown in FIG. 11, the remaining hard mask film HM1 is removed using, e.g., an etching technique. In this manner, in the n-channel core transistor formation region NCR, the n-channel I/O transistor formation region NTR(I/O), and the n-channel resistor element formation region NRR, the HfZrSiON film HK1 can be formed and, in the p-channel core transistor formation region PCR, the p-channel I/O transistor formation region PTR(I/O), and the p-channel resistor element formation region PRR, the HfSiON film HK2 can be formed.

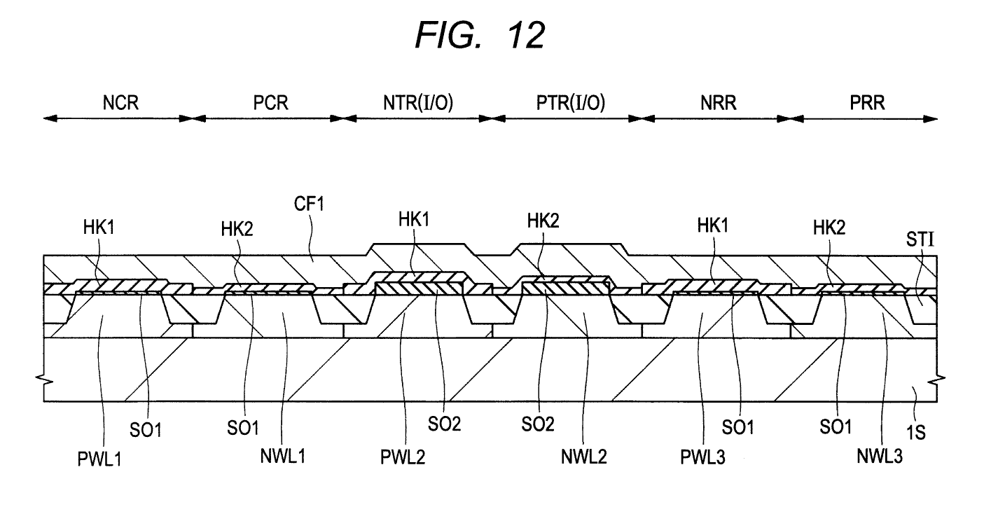

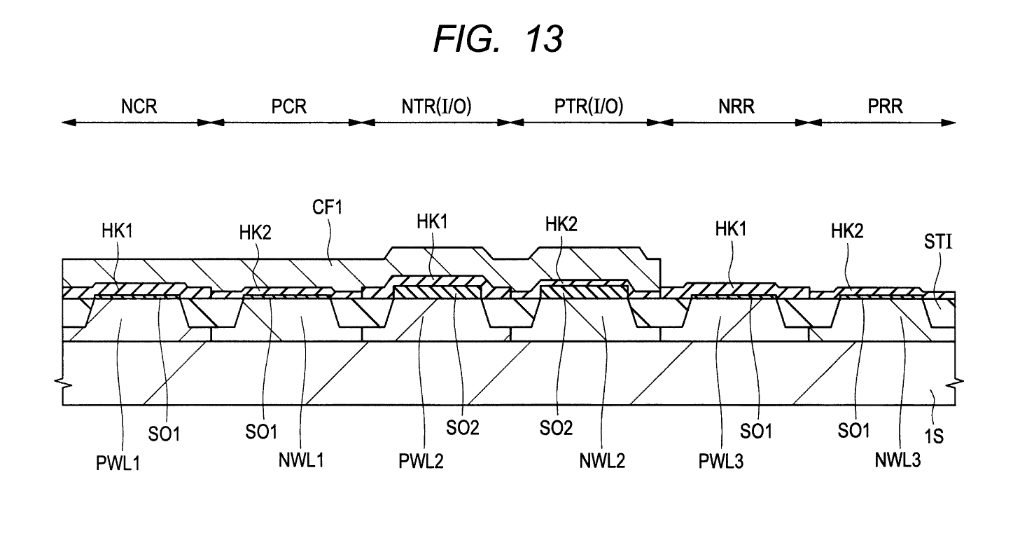

Subsequently, as shown in FIG. 12, over the semiconductor substrate 1S formed with the HfZrSiON film HK1 or the HfSiON film HK2, the conductor film CF1 containing a metal is formed. The conductor film CF1 is formed of, e.g., a titanium nitride film, and can be formed by using, e.g., a sputtering method. Then, as shown in FIG. 13, by using a photolithographic technique and an etching technique, the conductor film CF1 is patterned. The patterning of the conductor film CF1 is performed such that the conductor film CF1 remains in the re-channel core transistor formation region NCR, the p-channel core transistor formation region PCR, the n-channel I/O transistor formation region NTR(I/O), and the p-channel I/O transistor formation region PTR(I/O). In other words, the patterning of the conductor film CF1 is performed so as to remove the conductor film CF1 formed in the n-channel resistor element formation region NRR and the p-channel resistor element formation region PRR.

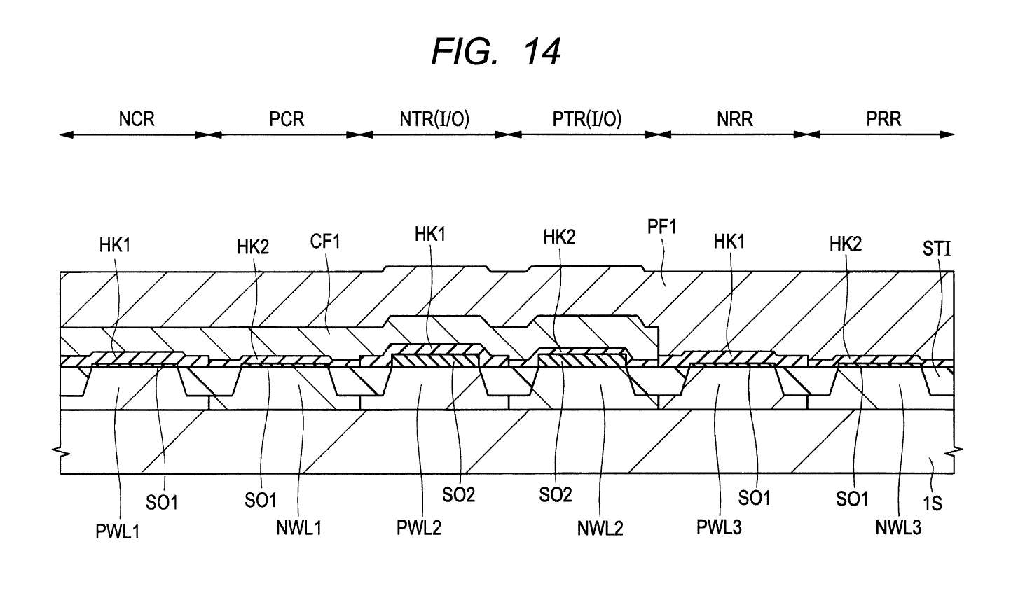

Next, as shown in FIG. 14, over the semiconductor substrate 1S, the polysilicon film PF1 is formed. As a result, in the n-channel core transistor formation region NCR, the p-channel core transistor formation region PCR, the n-channel I/O transistor formation region NTR(I/O), and the p-channel I/O transistor formation region PTR(I/O), the polysilicon film PF1 is formed over the conductor film CF1. On the other hand, in the n-channel resistor element formation region NRR and the p-channel resistor element formation region PRR, the polysilicon PF1 is formed over the HfZrSiON film HK1 or the HfSiON film HK2.

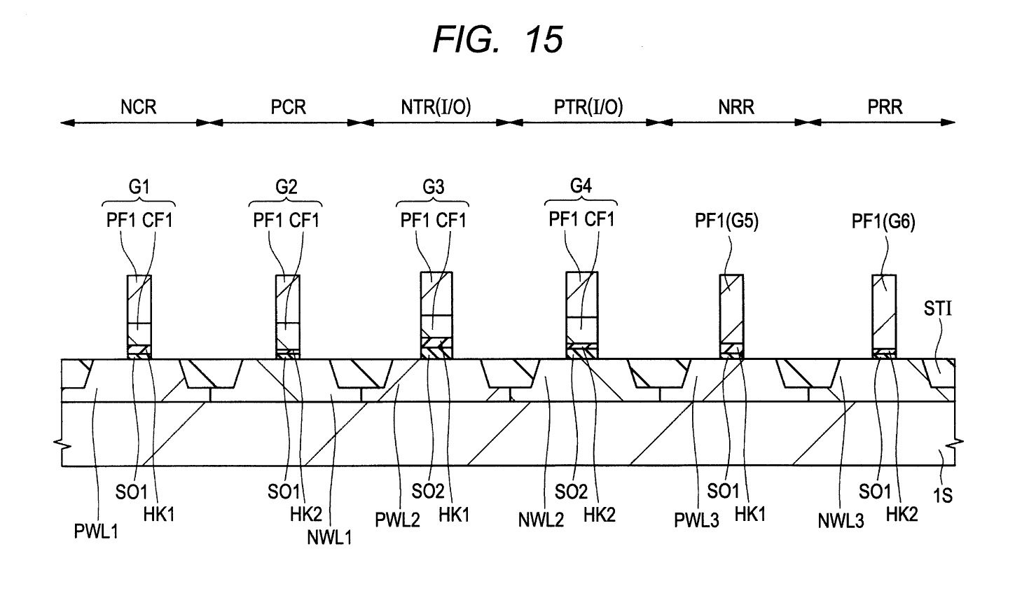

Subsequently, as shown in FIG. 15, by using a photolithographic technique and an etching technique, the polysilicon film PF1 and the conductor film CF1 are patterned to form the gate electrodes G1 to G6. Specifically, in the re-channel core transistor formation region NCR and the p-channel core transistor formation region PCR, the polysilicon film PF1 and the conductor film CF1 are patterned to form the gate electrodes G1 and G2 each formed of the laminate film of the conductor film CF1 and the polysilicon film PF1. Likewise, in the n-channel I/O transistor formation region NTR(I/O) and the p-channel I/O transistor formation region PTR(I/O) also, the polysilicon film PF1 and the conductor film CF1 are patterned to form the gate electrodes G3 and G4 each formed of the laminate film of the conductor film CF1 and the polysilicon film PF1. Also, in the n-channel resistor element formation region NRR and the p-channel resistor element formation region PRR, the polysilicon film PF1 is patterned to form the gate electrodes G5 and G6 each formed of the polysilicon film PF1.

Thereafter, in the n-channel core transistor formation region NCR, using the gate electrode G1 as a mask, the HfZrSiON film HK1 and the silicon oxide film SO1 are processed to form the gate insulating film including the silicon oxide film SO1 and the HfZrSiON film HK1. Likewise, in the p-channel core transistor formation region PCR, using the gate electrode G2 as a mask, the HfSiON film HK2 and the silicon oxide film SO1 are processed to form the gate insulating film including the silicon oxide film SO1 and the HfSiON film HK2. Also in the n-channel I/O transistor formation region NTR(I/O), using the gate electrode G3 as a mask, the HfZrSiON film HK1 and the silicon oxide film SO2 are processed to form the gate insulating film including the silicon oxide film SO2 and the HfZrSiON film HK1. Likewise, in the p-channel I/O transistor formation region PTR(I/O), using the gate electrode G4 as a mask, the HfSiON film HK2 and the silicon oxide film SO2 are processed to form the gate insulating film including the silicon oxide film SO2 and the HfSiON film HK2. Also, in the n-channel resistor element formation region NRR, using the gate electrode G5 as a mask, the HfZrSiON film HK1 and the silicon oxide film SO1 are processed to form the gate insulating film including the silicon oxide film SO1 and the HfZrSiON film HK1. Likewise, in the p-channel resistor element formation region PRR, using the gate electrode G6 as a mask, the HfSiON film HK2 and the silicon oxide film SO1 are processed to form the gate insulating film including the silicon oxide film SO1 and the HfSiON film HK2.

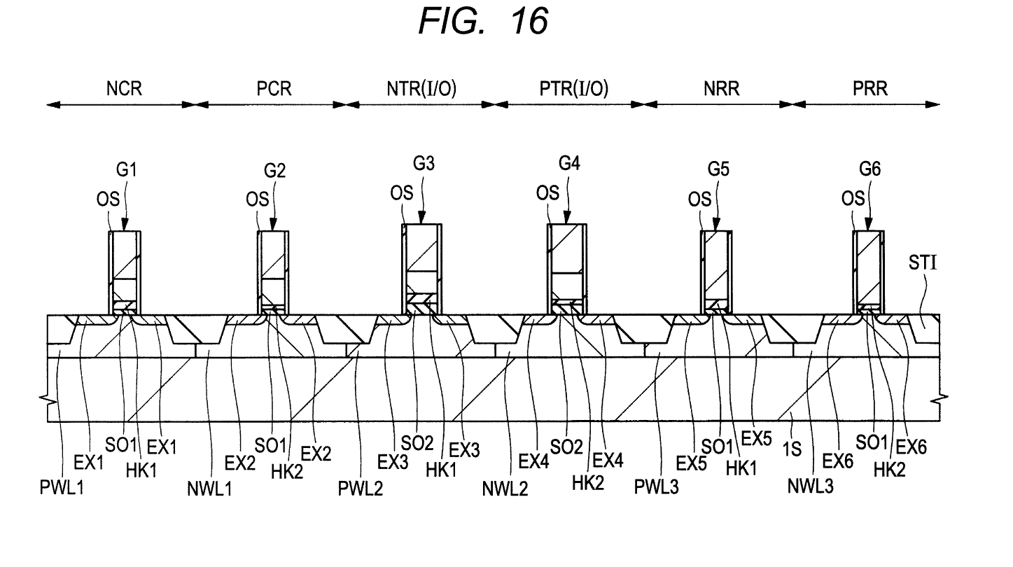

Next, as shown in FIG. 16, over the side walls of the gate electrodes G1 to G6, the offset spacers OS are formed. The offset spacers OS are formed of, e.g., a silicon oxide film, and can be formed by, e.g., forming a silicon oxide film over the semiconductor substrate 1S by a CVD method, and then anisotropically etching the silicon oxide film.

Then, by using a photolithographic technique and an ion implantation method, the shallow n-type impurity diffusion regions EX1, EX3, and EX5 are formed in alignment with respect to the gate electrodes G1, G3, and G5. The shallow n-type impurity diffusion regions EX1, EX3, and EX5 are semiconductor regions into which an n-type impurity such as phosphorus or arsenic has been introduced. Likewise, by using a photolithographic technique and an ion implantation method, the shallow p-type impurity diffusion regions EX2, EX4, and EX6 are formed in alignment with respect to the gate electrodes G2, G4, and G6. The shallow p-type impurity diffusion regions EX2, EX4, and EX6 are semiconductor regions into which a p-type impurity such as boron has been introduced.

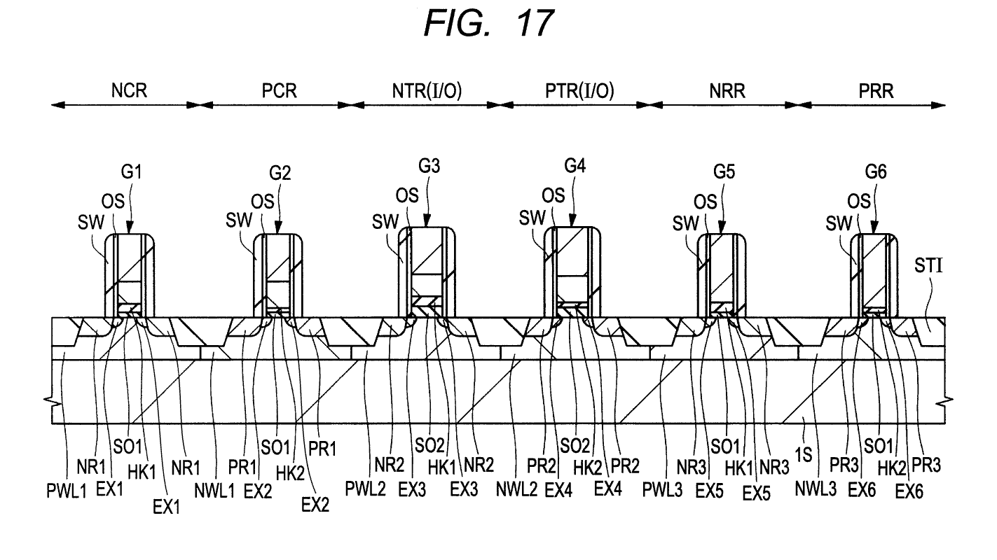

Next, as shown in FIG. 17, over the semiconductor substrate 1S, a silicon oxide film is formed. The silicon oxide film can be formed using, e.g., a CVD method. Then, by anisotropically etching the silicon oxide film, the sidewalls SW are formed over the side walls of the gate electrodes G1 to G6. The sidewalls SW are formed of the single-layered film of silicon oxide, but it is not limited thereto. For example, the sidewalls SW formed of a laminate film of a silicon nitride film and a silicon oxide film may also be formed.

Subsequently, by using a photolithographic technique and an ion implantation method, the deep n-type impurity diffusion regions NR1, NR2, and NR3 in alignment with the sidewalls SW are respectively formed in the n-channel core transistor formation region NCR, the n-channel I/O transistor formation region NTR(I/O), and the n-channel resistor element formation region NRR. The deep n-type impurity diffusion regions NR1, NR2, and NR3 are semiconductor regions into which an n-type impurity such as phosphorus or arsenic has been introduced. Likewise, by using a photolithographic technique and an ion implantation method, the deep p-type impurity diffusion regions PR1, PR2, and PR3 in alignment with the sidewalls SW are respectively formed in the p-channel core transistor formation region PCR, the p-channel I/O transistor formation region PTR(I/O), and the p-channel resistor element formation region PRR. The deep p-type impurity diffusion regions PR1, PR2, and PR3 are semiconductor regions into which a p-type impurity such as boron has been introduced.

In this manner, the deep n-type impurity diffusion regions NR1, NR2, and NR3 and the deep p-type impurity diffusion regions PR1, PR2, and PR3 are formed, and then a heat treatment at about 1000° C. is performed, thereby activating the introduced impurities.

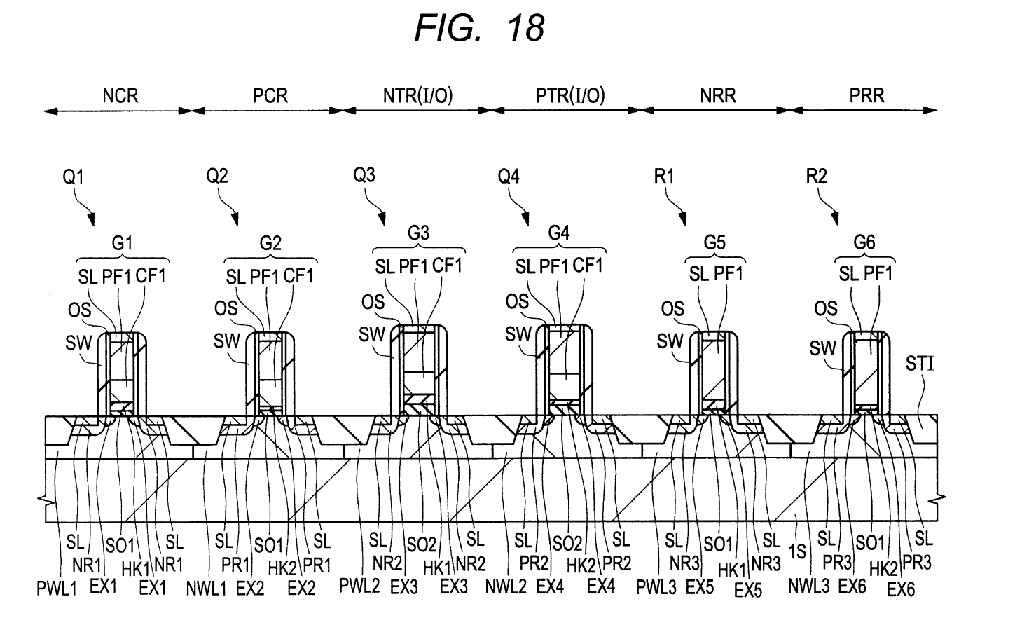

Thereafter, as shown in FIG. 18, over the semiconductor substrate 1S, a nickel platinum film (not shown) is formed. At this time, the nickel platinum film is formed so as to come in direct contact with the upper surfaces of the gate electrodes G1 to G6. Likewise, the nickel platinum film also comes in direct contact with the deep n-type impurity diffusion regions NR1, NR2, and NR3 and the deep p-type impurity diffusion regions PR1, PR2, and PR3.

The nickel platinum film can be formed using, e.g., a sputtering method. Then, after the nickel platinum film is formed, a heat treatment is performed to cause a reaction between the polysilicon film PF1 forming the gate electrodes G1 to G6 and the nickel platinum film, and form the silicide films SL formed of a nickel platinum silicide film. As a result, each of the gate electrodes G1 to G4 has a stacked structure of the conductor film CF1, the polysilicon film PF1, and the silicide film SL, while each of the gate electrodes G5 and G6 has a stacked structure of the polysilicon film PF1 and the silicide film SL. The silicide films SL are formed to reduce the resistances of the gate electrodes G1 to G6. Likewise, by the heat treatment mentioned above, at the surfaces of the deep n-type impurity diffusion regions NR1, NR2, and NR3 also, a reaction occurs between silicon and the nickel platinum film to form the silicide films SL formed of the nickel platinum silicide film. This also allows reductions in the resistances of the deep n-type impurity diffusion regions NR1, NR2, and NR3. Also, by the heat treatment mentioned above, at the surfaces of the deep p-type impurity diffusion regions PR1, PR2, and PR3 also, a reaction occurs between silicon and the nickel platinum film to form the silicide films SL formed of a nickel platinum silicide film. This also allows reductions in the resistances of the deep p-type impurity diffusion regions PR1, PR2, and PR3.

Then, the unreacted nickel platinum film is removed from over the semiconductor substrate 1S. Note that, in the present first embodiment, the silicide films SL formed of the nickel platinum silicide film are formed but, instead of the nickel platinum silicide film, for example, a nickel silicide film, a titanium silicide film, a cobalt silicide film, a platinum silicide film, or the like may also be used to form the silicide films SL. Thus, it is possible to, e.g., form, over the semiconductor substrate 1S, the n-channel core transistor Q1, the p-channel core transistor Q2, the n-channel I/O transistor Q3, the p-channel I/O transistor Q4, the n-channel resistor element R1, and the p-channel resistor element R2.

Next, a wiring step will be described with reference to FIG. 2. As shown in FIG. 2, over the main surface of the semiconductor substrate 1S, the silicon nitride film SN1 is formed and, over the silicon nitride film SN1, the contact interlayer insulating film CIL is formed. The contact interlayer insulating film CIL1 is formed of a laminate film of, e.g., an ozone TEOS film formed by a thermal CVD method using ozone and TEOS (tetra ethyl ortho silicate) as raw materials and a plasma TEOS film formed by a plasma CVD method using TEOS provided over the ozone TEOS film as a raw material. Thereafter, the surface of the contact interlayer insulating film CIL is planarized using, e.g., a CMP (Chemical Mechanical Polishing) method.

Subsequently, using a photolithographic technique and an etching technique, the contact holes CNT are formed in the contact interlayer insulating film CIL.

Thereafter, over the contact interlayer insulating film CIL including the bottom surfaces and inner walls of the contact holes CNT, a titanium/titanium nitride film is formed. The titanium/titanium nitride film is formed of a laminate film of a titanium film and a titanium nitride film, and can be formed by using, e.g., a sputtering method. The titanium/titanium nitride film has a so-called barrier property which prevents, e.g., tungsten as the material of a film to be buried in the subsequent step from being diffused into silicon.

Then, over the entire main surface of the semiconductor substrate 1S, a tungsten film is formed so as to be buried in the contact holes CNT. The tungsten film can be formed using, e.g., a CVD method. Then, by removing the unneeded titanium/titanium nitride film and the unneeded tungsten film which are formed over the contact interlayer insulating film CIL by, e.g., a CMP method, the plugs PLG can be formed.

Next, as shown in FIG. 2, over the contact interlayer insulating film CIL formed with the plugs PLG, the interlayer insulating film IL1 is formed. Then, by using a photolithographic technique and an etching technique, trenches are formed in the interlayer insulating film IL1. Thereafter, over the interlayer insulating film IL1 including the insides of the trenches, a tantalum/tantalum nitride film is formed. The tantalum/tantalum nitride film can be formed by, e.g., a sputtering method. Subsequently, over the tantalum/tantalum nitride film, a seed film formed of a thin copper film is formed by, e.g., a sputtering method. Then, by an electrolytic plating method using the seed film as an electrode, a copper film is formed over the interlayer insulating film IL1 formed with the trenches. Thereafter, by polishing and removing the copper film exposed over the interlayer insulating film IL1 except for that in the trenches by, e.g., a CMP method, the copper film is left only in the trenches formed in the interlayer insulating film IL1. In this manner, the wiring lines L1 can be formed. Furthermore, in the layer over the wiring lines L1, wiring is formed, but the description thereof is omitted here. Thus, the semiconductor device in the present first embodiment can be eventually formed.

In the present first embodiment, the description has been given to the example in which the wiring lines L1 are formed of the copper film. However, the wiring lines L1 may also be formed of an aluminum film. In this case, over the contact interlayer insulating film CIL and the plugs PLG, a titanium/titanium nitride film, an aluminum film, and a titanium/titanium nitride film are successively formed. These films can be formed by using, e.g., a sputtering method. Subsequently, by using a photolithographic technique and an etching technique, these films are patterned to form the wiring lines L1. In this manner, the wiring lines L1 formed of the aluminum film can be formed.

### Second Embodiment

In the foregoing first embodiment, the description has been given to the example in which, as the gate insulating film of each of the n-channel core transistor Q1, the re-channel I/O transistor Q3, and the n-channel resistor element R1, the HfZrSiON film which is an insulating film containing hafnium and zirconium is used. In the present second embodiment, a description will be given to an example in which, as the gate insulating film of each of the n-channel core transistor Q1, the n-channel I/O transistor Q3, and the re-channel resistor element R1, a HfZrLaSiON film which is an insulating film containing hafnium, zirconium, and lanthanum (La) is used.

The structure of the semiconductor device in the present second embodiment is substantially the same as in FIG. 2 showing the structure of the semiconductor device in the foregoing first embodiment, and therefore the depiction thereof is omitted. What is different is that, as the gate insulating film of each of the n-channel core transistor Q1, the n-channel I/O transistor Q3, and the n-channel resistor element R1, instead of the HfZrSiON film HK1, the HfZrLaSiON film is used. Thus, according to the present second embodiment, by causing the HfSiON film to contain Zr (zirconium), in the same manner as in the foregoing first embodiment, the fixed charges and the trap levels in the film can be reduced. This allows a significant improvement in PBTI, and consequently allows an improvement in the reliability of each of the re-channel core transistor Q1, the n-channel I/O transistor Q3, and the n-channel resistor element R1. In addition, since the fixed charges and the trap levels can be reduced, it is also possible to suppress fluctuations in threshold voltage and a reduction in current driving capability.

Moreover, in the present second embodiment, the HfSiON film is caused to contain not only Zr (zirconium), but also lanthanum (La). When contained in an insulating film containing hafnium, lanthanum (La) achieves the effect of reducing the threshold voltages of the n-channel MISFETs (which are the n-channel core transistor Q1, the n-channel I/O transistor Q3, and the n-channel resistor element R1 herein). Therefore, in the present second embodiment, by forming the gate insulating film such that the HfSiON film contains not only Zr (zirconium), but also lanthanum (La), not only the above-mentioned effect achieved by zirconium (Zr), but also the effect of reducing the threshold voltage of the transistor, which is achieved by lanthanum (La), can be obtained.

The semiconductor device in the present second embodiment is thus structured and, hereinbelow, a manufacturing method thereof will be described with reference to the drawings. Initially, in the manufacturing steps in FIGS. 3 to 8, the manufacturing method is the same as in the foregoing first embodiment.

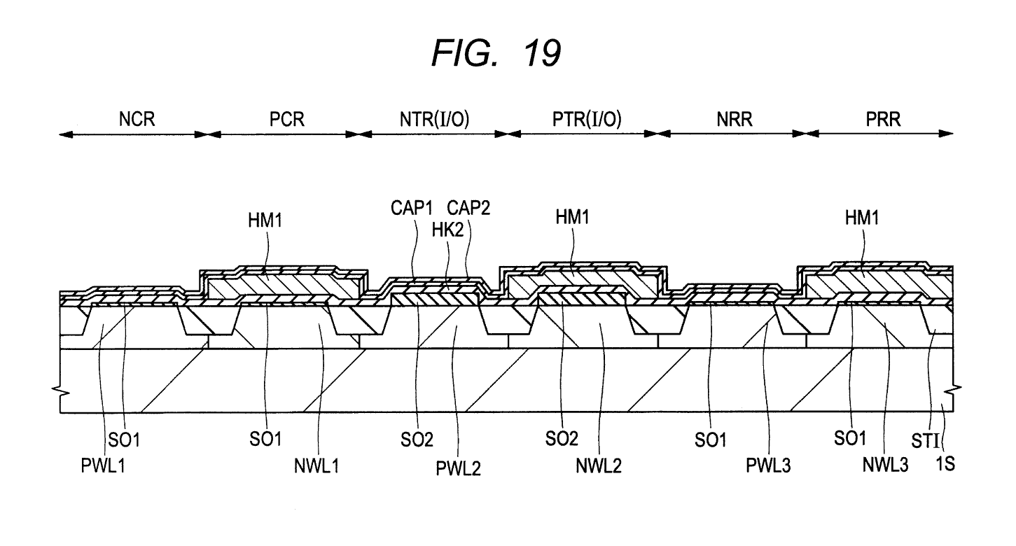

Subsequently, as shown in FIG. 19, over the semiconductor substrate 1S, a cap film CAP2 is formed. Specifically, over the cap film CAP1 formed over the semiconductor substrate 1S, the cap film CAP2 is formed. The cap film CAP2 is formed of a lanthanum (La) film or a lanthanum oxide film, and can be formed by, e.g., a sputtering method.

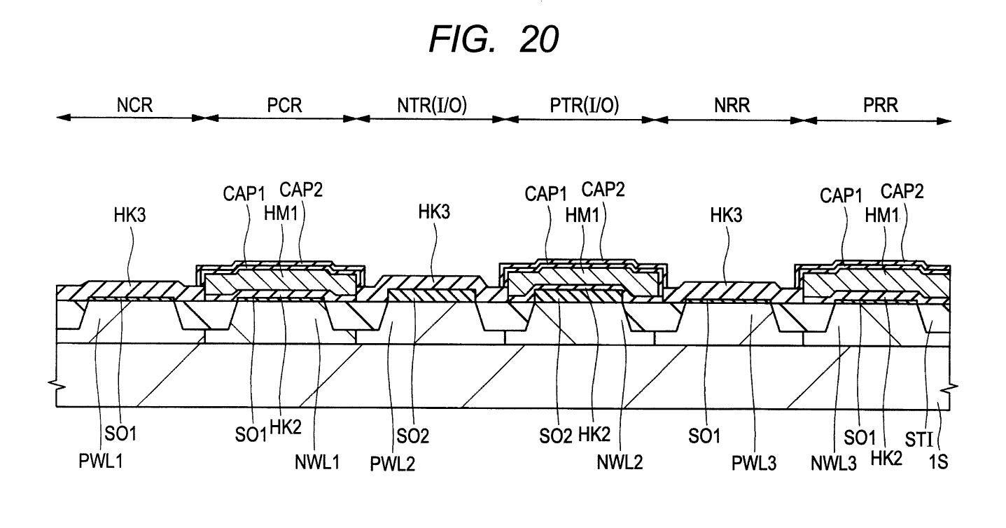

Thereafter, as shown in FIG. 20, a heat treatment is performed to the semiconductor substrate 1S. In the n-channel core transistor formation region NCR, the n-channel I/O transistor formation region NTR(I/O), and the n-channel resistor element formation region NRR, the cap films CAP1 and CAP2 are formed directly over the HfSiON film HK2 so that, by the heat treatment mentioned above, zirconium (Zr) contained in the cap film CAP1 is diffused into the HfSiON film HK2, and lanthanum (La) contained in the cap film CAP2 is diffused into the HfSiON film HK2. As a result, a HfZrLaSiON film HK3 is formed. On the other hand, in the p-channel core transistor formation region PCR, the p-channel I/O transistor formation region PTR(I/O), and the p-channel resistor element formation region PRR, the cap films CAP1 and CAP2 are formed over the hard mask film HM1 so that zirconium (Zr) contained in the cap film CAP1 and lanthanum (La) contained in the cap film CAP2 are not diffused into the HfSiON film HK2. Thus, in the re-channel core transistor formation region NCR, the n-channel I/O transistor formation region NTR(I/O), and the n-channel resistor element formation region NRR, the HfZrLaSiON film HK3 is formed. On the other hand, in the p-channel core transistor formation region PCR, the p-channel I/O transistor formation region PTR(I/O), and the p-channel resistor element formation region PRR, the HfSiON film HK2 remains without any alteration. Here, the HfZrLaSiON film HK3 contains zirconium and lanthanum so that the physical film thickness thereof is larger than that of the HfSiON film HK2 which does not contain zirconium and lanthanum.

Thereafter, a resist film (not shown) is coated over the semiconductor substrate 1S, and the coated resist film is subjected to an exposure/development treatment so as to be patterned. The patterning of the resist film is performed such that the resist film remains in the n-channel core transistor formation region NCR, the n-channel I/O transistor formation region NTR(I/O), and the n-channel resistor element formation region NRR. In other words, the patterning of the resist film is performed such that the resist film does not remain in the p-channel core transistor formation region PCR, the p-channel I/O transistor formation region PTR(I/O), and the p-channel resistor element formation region PRR. Then, by etching using the patterned resist film as a mask, the cap films CAP1 and CAP2 formed over the hard mask film HM1 are removed.

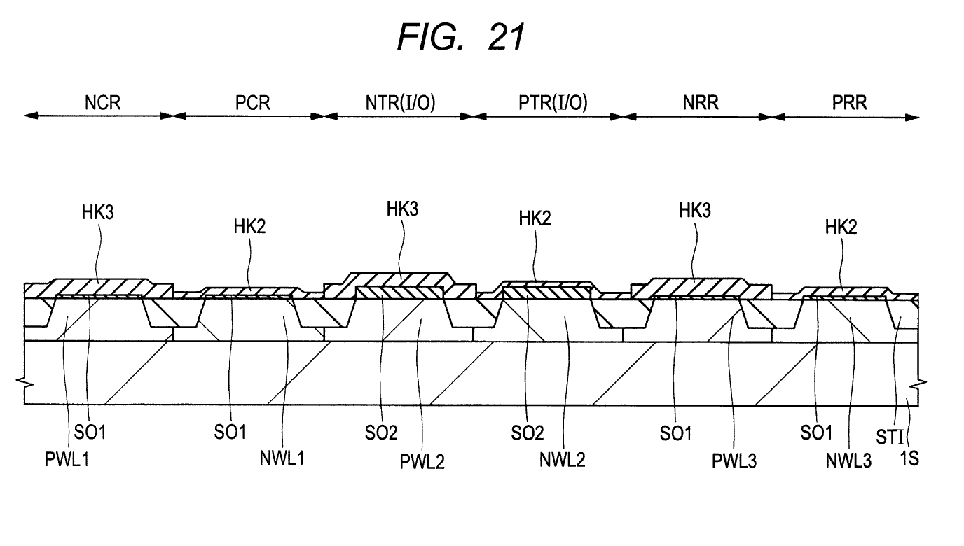

Next, as shown in FIG. 21, the remaining hard mask film HM1 is removed using, e.g., an etching technique. In this manner, in the n-channel core transistor formation region NCR, the n-channel I/O transistor formation region NTR(I/O), and the n-channel resistor element formation region NRR, the HfZrLaSiON film HK3 can be formed and, in the p-channel core transistor formation region PCR, the p-channel I/O transistor formation region PTR(I/O), and the p-channel resistor element formation region PRR, the HfSiON film HK2 can be formed.

The subsequent steps are the same as in the foregoing first embodiment so that the description thereof is omitted (see FIGS. 12 to 18). Thus, the semiconductor device in the present second embodiment can be manufactured. Note that, in the present second embodiment, the example is shown in which, over the cap film CAP1 containing zirconium, the cap film CAP2 containing lanthanum is formed, but the present second embodiment is not limited thereto. For example, it may also be possible to form the cap film CAP2 containing lanthanum first, and then form the cap film CAP1 containing zirconium over the cap film CAP2.

### Third Embodiment

In the foregoing second embodiment, the description has been given to the example in which, as the gate insulating film of each of the n-channel core transistor Q1, the re-channel I/O transistor Q3, and the n-channel resistor element R1, a HfZrLaSiON film which is an insulating film containing hafnium, zirconium, and lanthanum (La) is used. In the present third embodiment, a description will be given to an example in which, as the gate insulating film of each of the n-channel MISFETs (the n-channel core transistor Q1, the n-channel I/O transistor Q3, and the n-channel resistor element R1), an insulating film containing hafnium, zirconium, and a rare earth element (group III element other than actinium or lanthanoid) is used.

The structure of the semiconductor device in the present third embodiment is substantially the same as in FIG. 2 showing the structure of the semiconductor device in the foregoing first embodiment, and therefore the depiction thereof is omitted. What is different is that, as the gate insulating film of each of the n-channel core transistor Q1, the n-channel I/O transistor Q3, and the n-channel resistor element R1, instead of the HfZrSiON film HK1, a HfZrXSiON (where X is a rare earth element (group III element other than actinium or lanthanoid)) film is used. Thus, according to the present third embodiment, by causing the HfSiON film to contain Zr (zirconium), in the same manner as in the foregoing first embodiment, the fixed charges and the trap levels in the film can be reduced. This allows a significant improvement in PBTI, and consequently allows an improvement in the reliability of each of the n-channel core transistor Q1, the n-channel I/O transistor Q3, and the n-channel resistor element R1. In addition, since the fixed charges and the trap levels can be reduced, it is also possible to suppress fluctuations in threshold voltage and a reduction in current driving capability.

Moreover, in the present third embodiment, the HfSiON film is caused to contain not only Zr (zirconium), but also a rare earth element. When contained in an insulating film containing hafnium, a rare earth element achieves the effect of reducing the threshold voltages of the n-channel MISFETs (which are the n-channel core transistor Q1, the n-channel I/O transistor Q3, and the n-channel resistor element R1 herein), similarly to lanthanum (La) described in the foregoing second embodiment. Therefore, in the present third embodiment, by forming the gate insulating film such that the HfSiON film contains not only Zr (zirconium), but also a rare earth element, not only the above-mentioned effect achieved by zirconium (Zr), but also the effect of reducing the threshold voltage of the transistor, which is achieved by a rare earth element, can be obtained.

Specifically, a rare earth element mentioned in the present third embodiment indicates any of Sc, Y, La, Ce, Pr, Nd, Pm, Sm, Eu, Gd, Tb, Dy, Ho, Er, Tm, Yb, and Lu.

The semiconductor device in the present third embodiment is thus structured, and a manufacturing method thereof is substantially the same as in the foregoing second embodiment. In the foregoing second embodiment, as the cap film CAP2, a lanthanum film or a lanthanum oxide film is used. However, the present third embodiment is different only in that, as the cap film CAP2, a film containing a rare earth element (any of Sc, Y, La, Ce, Pr, Nd, Pm, Sm, Eu, Gd, Tb, Dy, Ho, Er, Tm, Yb, and Lu) is used. The other manufacturing steps are the same as the manufacturing steps in the foregoing second embodiment, and therefore the description thereof is omitted. In this manner, the semiconductor device in the present third embodiment can be manufactured.

### Fourth Embodiment

In the foregoing first embodiment, the description has been given to the example in which, as the gate insulating film of each of the p-channel core transistor Q2, the p-channel I/O transistor Q4, and the p-channel resistor element R2, a HfSiON film which is an insulating film containing hafnium is used. In the present fourth embodiment, a description will be given to an example in which, as the gate insulating film of each of the p-channel core transistor Q2, the p-channel I/O transistor Q4, and the p-channel resistor element R2, a HfAlSiON film which is an insulating film containing hafnium and aluminum (Al) is used.

The structure of the semiconductor device in the present fourth embodiment is substantially the same as in FIG. 2 showing the structure of the semiconductor device in the foregoing first embodiment, and therefore the depiction thereof is omitted. What is different is that, as the gate insulating film of each of the p-channel core transistor Q2, the p-channel I/O transistor Q4, and the p-channel resistor element R2, instead of the HfSiON film HK2, the HfAlSiON film is used.

In the present fourth embodiment, the HfSiON film is caused to contain aluminum (Al). When contained in an insulating film containing hafnium, aluminum (Al) achieves the effect of reducing the threshold voltages of the p-channel MISFETs (which are the p-channel core transistor Q2, the p-channel I/O transistor Q4, and the p-channel resistor element R2 herein). Therefore, in the present fourth embodiment, by forming the gate insulating film such that the HfSiON film contains aluminum (Al), the effect of reducing the threshold voltage of the transistor, which is achieved by aluminum (Al), can also be obtained.

The semiconductor device in the present fourth embodiment is thus structured and, hereinbelow, a manufacturing method thereof will be described with reference to the drawings. Initially, in the manufacturing steps in FIGS. 3 to 5, the manufacturing method is the same as in the foregoing first embodiment.

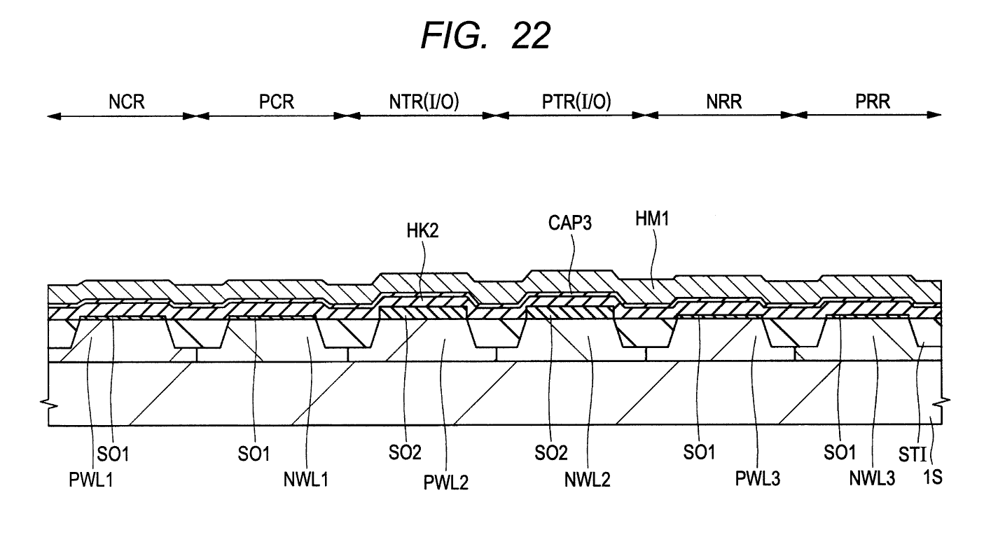

Subsequently, as shown in FIG. 22, over the semiconductor substrate 1S formed with the silicon oxide films SO1 and SO2, the HfSiON film HK2 is formed and, over the HfSiON film HK2, a cap film CAP3 containing aluminum is formed. Then, over the cap film CAP3, the hard mask film HM1 is formed. The HfSiON film HK2 can be formed by using, e.g., a sputtering method, a CVD (Chemical Vapor Deposition) method, or an ALD (Atomic Layer Deposition) method. Note that, instead of the HfSiON film HK2, another hafnium-based insulating film such as a HfSiO film, a HfON film, or a HfO film can also be used. The cap film CAP3 is a film containing aluminum, formed of, e.g., an aluminum film or an aluminum oxide film, and can be formed by, e.g., a sputtering method. The hard mask film HM1 is formed of, e.g., a titanium nitride film, and can be formed by using, e.g., a sputtering method.

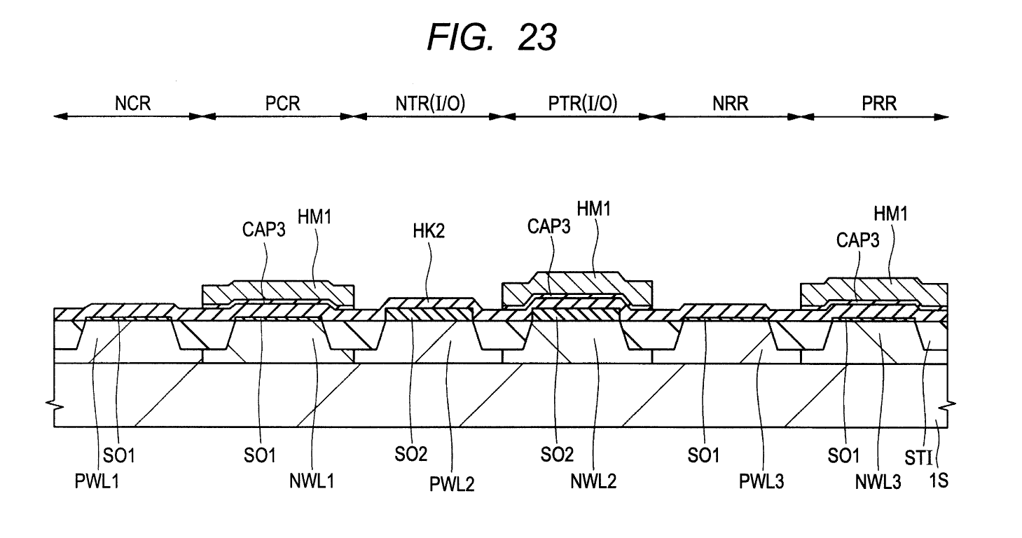

Then, as shown in FIG. 23, by using a photolithographic technique and an etching technique, the hard mask film HM1 is patterned. The patterning of the hard mask film HM1 is performed so as to remove the hard mask film HM1 formed in the n-channel core transistor formation region NCR, the n-channel I/O transistor formation region NTR(I/O), and the n-channel resistor element formation region NRR. As a result, the hard mask film HM1 formed in the p-channel core transistor formation region PCR, the p-channel I/O transistor formation region PTR(I/O), and the p-channel resistor element formation region PRR remains. Thereafter, by etching using the patterned hard mask film HM1 as a mask, the exposed cap film CAP3 is removed. That is, the cap film CAP3 exposed in the n-channel core transistor formation region NCR, the n-channel I/O transistor formation region NTR(I/O), and the n-channel resistor element formation region NRR is removed.

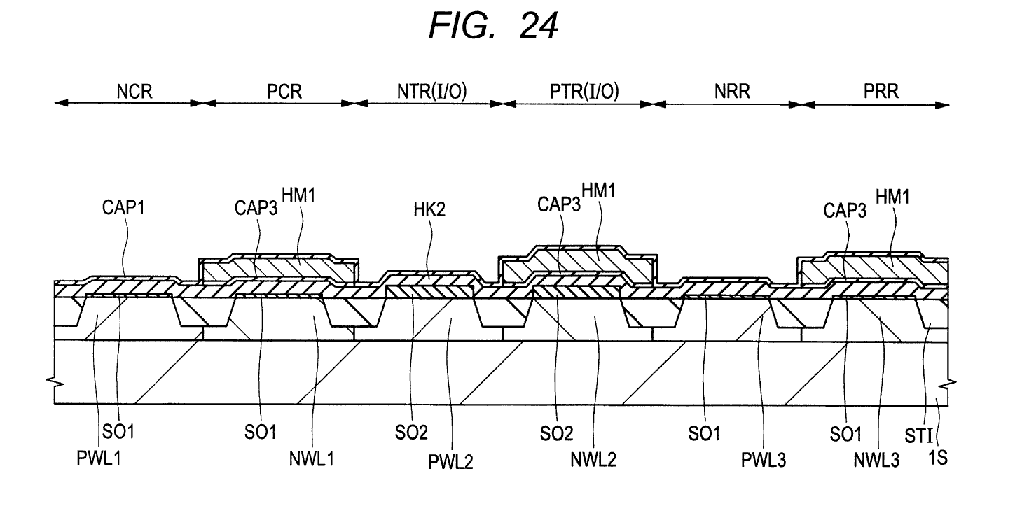

Next, as shown in FIG. 24, over the patterned hard mask film HM1, the cap film CAP1 is formed. The cap film CAP1 is formed of, e.g., a Zr (zirconium) film or a ZrO (zirconium oxide) film, and can be formed by using, e.g., a sputtering method. In this manner, in the n-channel core transistor formation region NCR, the n-channel I/O transistor formation region NTR(I/O), and the n-channel resistor element formation region NRR, the cap film CAP1 is formed directly over the HfSiON film HK2. On the other hand, in the p-channel core transistor formation region PCR, the p-channel I/O transistor formation region PTR(I/O), and the p-channel resistor element formation region PRR, the cap film CAP1 is formed over the hard mask film HM1.

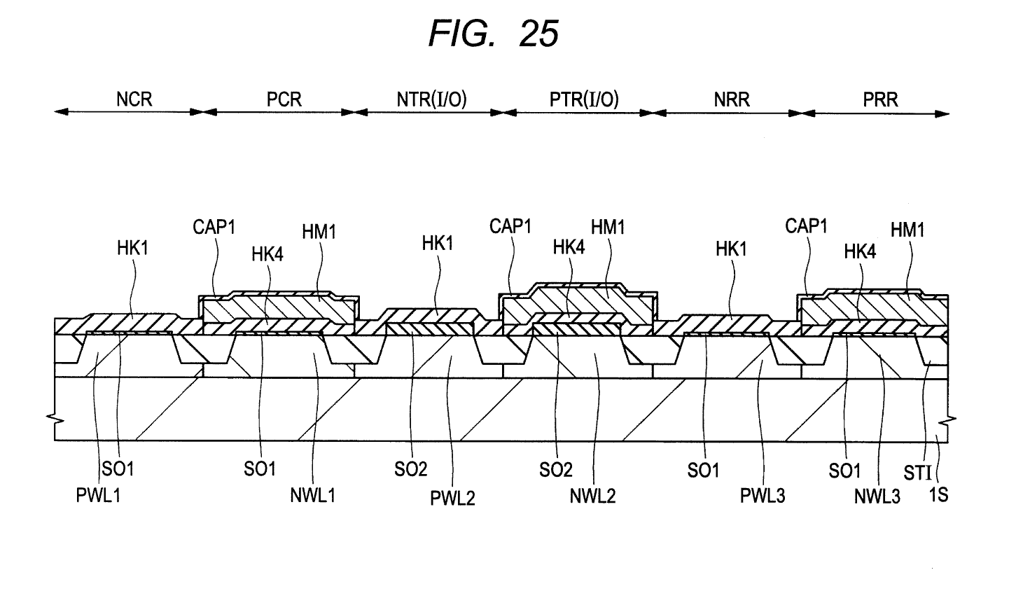

Subsequently, as shown in FIG. 25, a heat treatment is performed to the semiconductor substrate 1S. In the n-channel core transistor formation region NCR, the n-channel I/O transistor formation region NTR(I/O), and the n-channel resistor element formation region NRR, the cap film CAP1 is formed directly over the HfSiON film HK2 so that zirconium (Zr) contained in the cap film CAP1 is diffused into the HfSiON film HK2 by the heat treatment mentioned above. As a result, the HfZrSiON film HK1 is formed. On the other hand, in the p-channel core transistor formation region PCR, the p-channel I/O transistor formation region PTR(I/O), and the p-channel resistor element formation region PRR, the cap film CAP1 is formed over the hard mask film HM1 so that zirconium contained in the cap film CAP1 is not diffused into the HfSiON film HK2. By contrast, in the p-channel core transistor formation region PCR, the p-channel I/O transistor formation region PTR(I/O), and the p-channel resistor element formation region PRR, the cap film CAP3 is formed in the layer under the hard mask film HM1 so that aluminum contained in the cap film CAP3 is diffused into the HfSiON film HK2. As a result, a HfAlSiON film HK4 is formed.

In this manner, in the n-channel core transistor formation region NCR, the n-channel I/O transistor formation region NTR(I/O), and the n-channel resistor element formation region NRR, the HfZrSiON film HK1 is formed. On the other hand, in the p-channel core transistor formation region PCR, the p-channel I/O transistor formation region PTR(I/O), and the p-channel resistor element formation region PRR, the HfAlSiON film HK4 is formed. Here, in terms of improving the balance between the current driving capabilities, the physical film thickness of the HfZrSiON film HK1 is preferably adjusted to be larger than the physical film thickness of the HfAlSiON film HK4.

Thereafter, a resist film (not shown) is coated over the semiconductor substrate 1S, and the coated resist film is subjected to an exposure/development treatment so as to be patterned. The patterning of the resist film is performed such that the resist film remains in the n-channel core transistor formation region NCR, the n-channel I/O transistor formation region NTR(I/O), and the n-channel resistor element formation region NRR. In other words, the patterning of the resist film is performed such that the resist film does not remain in the p-channel core transistor formation region PCR, the p-channel I/O transistor formation region PTR(I/O), and the p-channel resistor element formation region PRR. Then, by etching using the patterned resist film as a mask, the cap film CAP1 formed over the hard mask film HM1 is removed.

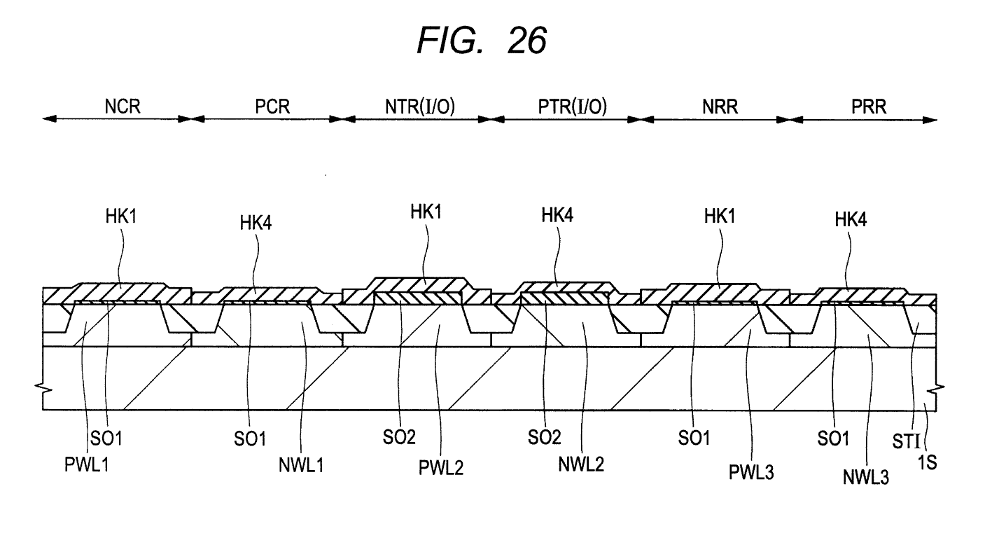

Next, as shown in FIG. 26, the remaining hard mask film HM1 is removed using, e.g., an etching technique. In this manner, in the n-channel core transistor formation region NCR, the n-channel I/O transistor formation region NTR(I/O), and the n-channel resistor element formation region NRR, the HfZrSiON film HK1 can be formed and, in the p-channel core transistor formation region PCR, the p-channel I/O transistor formation region PTR(I/O), and the p-channel resistor element formation region PRR, the HfAlSiON film HK4 can be formed.

The subsequent steps are the same as in the foregoing first embodiment so that the description thereof is omitted (see FIGS. 12 to 18). Thus, the semiconductor device in the present fourth embodiment can be manufactured.

### Fifth Embodiment

In the present fifth embodiment, a description will be given to an example in which the foregoing second embodiment and the foregoing fourth embodiment are combined. Specifically, as the gate insulating film of each of the n-channel core transistor Q1, the n-channel I/O transistor Q3, and the re-channel resistor element R1, a HfZrLaSiON film which is an insulating film containing hafnium, zirconium, and lanthanum (La) is used. In addition, as the gate insulating film of each of the p-channel core transistor Q2, the p-channel I/O transistor Q4, and the p-channel resistor element R2, a HfAlSiON film which is an insulating film containing hafnium and aluminum (Al) is used.

The structure of the semiconductor device in the present fifth embodiment is substantially the same as in FIG. 2 showing the structure of the semiconductor device in the foregoing first embodiment, and therefore the depiction thereof is omitted. What is different is that, as the gate insulating film of each of the n-channel core transistor Q1, the n-channel I/O transistor Q3, and the n-channel resistor element R1, instead of the HfZrSiON film HK1, the HfZrLaSiON film is used. Thus, according to the present fifth embodiment, by causing the HfSiON film to contain Zr (zirconium), in the same manner as in the foregoing first embodiment, the fixed charges and the trap levels in the film can be reduced. This allows a significant improvement in PBTI, and consequently allows an improvement in the reliability of each of the re-channel core transistor Q1, the n-channel I/O transistor Q3, and the n-channel resistor element R1. In addition, since the fixed charges and the trap levels can be reduced, it is also possible to suppress fluctuations in threshold voltage and a reduction in current driving capability.

Moreover, in the present fifth embodiment, the HfSiON film is caused to contain not only Zr (zirconium), but also lanthanum (La). When contained in an insulating film containing hafnium, lanthanum (La) achieves the effect of reducing the threshold voltages of the n-channel MISFETs (which are the n-channel core transistor Q1, the n-channel I/O transistor Q3, and the n-channel resistor element R1 herein). Therefore, in the present fifth embodiment, by forming the gate insulating film such that the HfSiON film contains not only Zr (zirconium), but also lanthanum (La), not only the above-mentioned effect achieved by zirconium (Zr), but also the effect of reducing the threshold voltage of the transistor, which is achieved by lanthanum (La), can be obtained.

In addition, in the present fifth embodiment, as the gate insulating film of each of the p-channel core transistor Q2, the p-channel I/O transistor Q4, and the p-channel resistor element R2, instead of the HfSiON film HK2, the HfAlSiON film is used.

That is, in the present fifth embodiment also, in each of the p-channel MISFETs, the HfSiON film is caused to contain aluminum (Al). When contained in an insulating film containing hafnium, aluminum (Al) achieves the effect of reducing the threshold voltages of the p-channel MISFETs (which are the p-channel core transistor Q2, the p-channel I/O transistor Q4, and the p-channel resistor element R2 herein). Therefore, in the present fifth embodiment, in each of the p-channel MISFETs, by forming the gate insulating film such that the HfSiON film contains aluminum (Al), the effect of reducing the threshold voltage of the transistor, which is achieved by aluminum (Al), can also be obtained.

The semiconductor device in the present fifth embodiment is thus structured and, hereinbelow, a manufacturing method thereof will be described with reference to the drawings. Initially, in the manufacturing steps in FIGS. 3 to 5, the manufacturing method is the same as in the foregoing first embodiment. Thereafter, the manufacturing steps of the foregoing fourth embodiment shown in FIGS. 22 to 24 are performed.

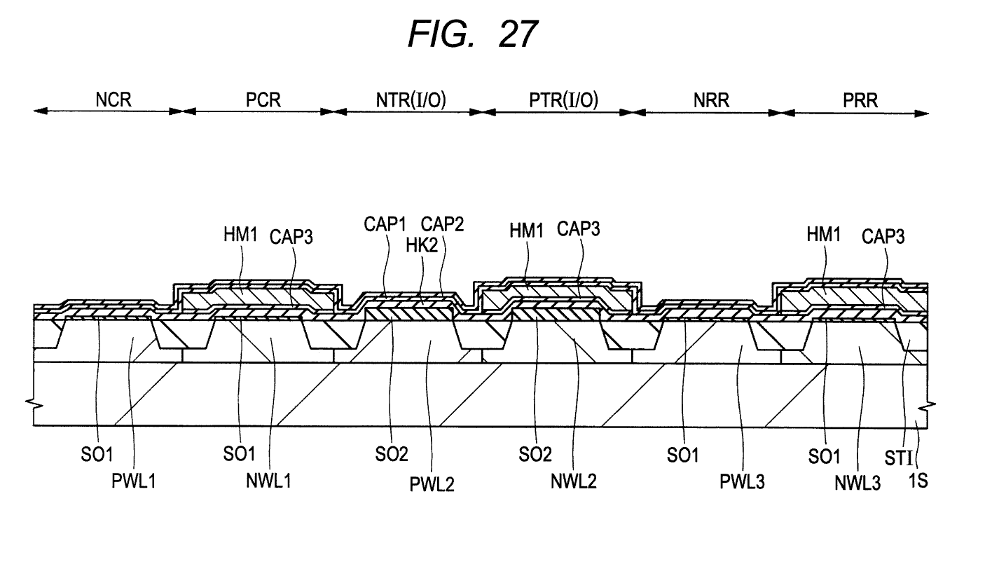

Subsequently, as shown in FIG. 27, over the semiconductor substrate 1S, the cap film CAP2 is formed. Specifically, over the cap film CAP1 formed over the semiconductor substrate 1S, the cap film CAP2 is formed. The cap film CAP2 is formed of a lanthanum (La) film or a lanthanum oxide film, and can be formed by, e.g., a sputtering method.

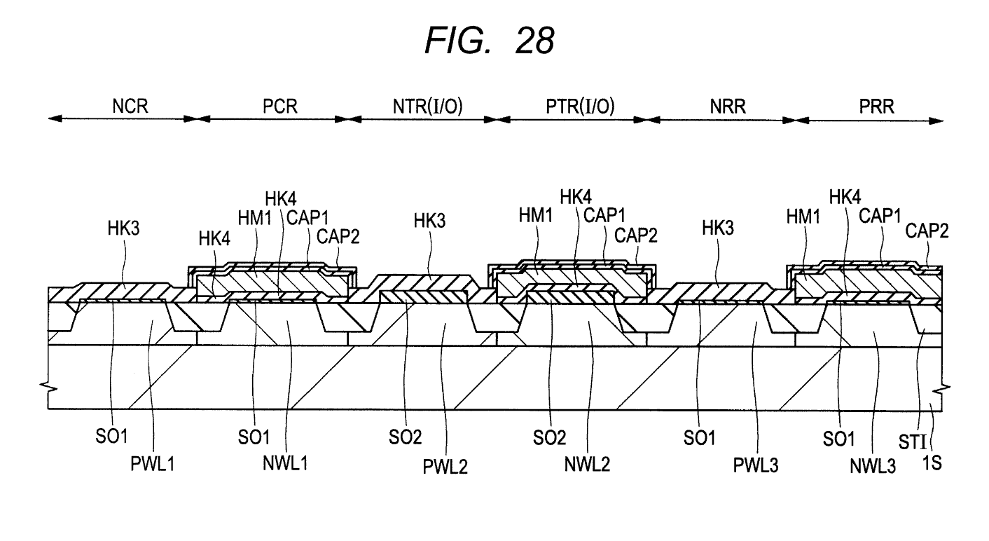

Thereafter, as shown in FIG. 28, a heat treatment is performed to the semiconductor substrate 1S. In the n-channel core transistor formation region NCR, the n-channel I/O transistor formation region NTR(I/O), and the n-channel resistor element formation region NRR, the cap films CAP1 and CAP2 are formed directly over the HfSiON film HK2 so that, by the heat treatment mentioned above, zirconium (Zr) contained in the cap film CAP1 is diffused into the HfSiON film HK2, and lanthanum (La) contained in the cap film CAP2 is diffused into the HfSiON film HK2. As a result, the HfZrLaSiON film HK3 is formed. On the other hand, in the p-channel core transistor formation region PCR, the p-channel I/O transistor formation region PTR(I/O), and the p-channel resistor element formation region PRR, the cap films CAP1 and CAP2 are formed over the hard mask film HM1 so that zirconium (Zr) contained in the cap film CAP1 and lanthanum (La) contained in the cap film CAP2 are not diffused into the HfSiON film HK2. By contrast, in the p-channel core transistor formation region PCR, the p-channel I/O transistor formation region PTR(I/O), and the p-channel resistor element formation region PRR, the cap film CAP3 is formed in the layer under the hard mask film HM1 so that aluminum contained in the cap film CAP3 is diffused into the HfSiON film HK2. As a result, the HfAlSiON film HK4 is formed.

Thus, in the n-channel core transistor formation region NCR, the n-channel I/O transistor formation region NTR(I/O), and the n-channel resistor element formation region NRR, the HfZrLaSiON film HK3 is formed. On the other hand, in the p-channel core transistor formation region PCR, the p-channel I/O transistor formation region PTR(I/O), and the p-channel resistor element formation region PRR, the HfAlSiON film HK4 is formed. Here, in terms of improving the balance between the current driving capabilities, the physical film thickness of the HfZrLaSiON film HK3 is preferably adjusted to be larger than the physical film thickness of the HfAlSiON film HK4.

Thereafter, a resist film (not shown) is coated over the semiconductor substrate 1S, and the coated resist film is subjected to an exposure/development treatment so as to be patterned. The patterning of the resist film is performed such that the resist film remains in the n-channel core transistor formation region NCR, the n-channel I/O transistor formation region NTR(I/O), and the n-channel resistor element formation region NRR. In other words, the patterning of the resist film is performed such that the resist film does not remain in the p-channel core transistor formation region PCR, the p-channel I/O transistor formation region PTR(I/O), and the p-channel resistor element formation region PRR. Then, by etching using the patterned resist film as a mask, the cap films CAP1 and CAP2 formed over the hard mask film HM1 are removed.

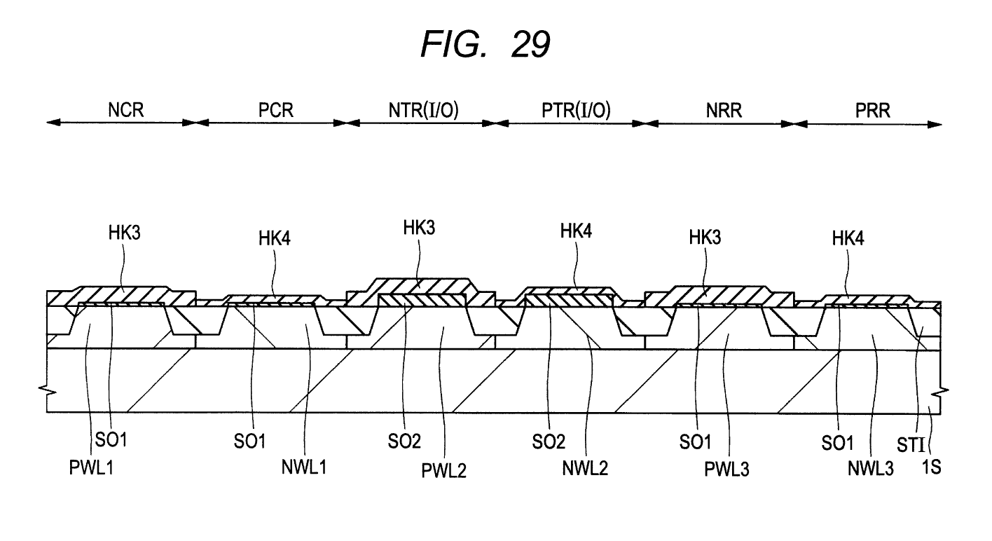

Next, as shown in FIG. 29, the remaining hard mask film HM1 is removed using, e.g., an etching technique. In this manner, in the n-channel core transistor formation region NCR, the n-channel I/O transistor formation region NTR(I/O), and the n-channel resistor element formation region NRR, the HfZrLaSiON film HK3 can be formed and, in the p-channel core transistor formation region PCR, the p-channel I/O transistor formation region PTR(I/O), and the p-channel resistor element formation region PRR, the HfAlSiON film HK4 can be formed.

The subsequent steps are the same as in the foregoing first embodiment so that the description thereof is omitted (see FIGS. 12 to 18). Thus, the semiconductor device in the present fifth embodiment can be manufactured. Note that, in the present fifth embodiment, the example is shown in which, over the cap film CAP1 containing zirconium, the cap film CAP2 containing lanthanum is formed, but the present fifth embodiment is not limited thereto. For example, it may also be possible to form the cap film CAP2 containing lanthanum first, and then form the cap film CAP1 containing zirconium over the cap film CAP2.

### Sixth Embodiment

In the foregoing first embodiment, the description has been given to the example in which, as the gate insulating film of each of the n-channel core transistor Q1, the re-channel I/O transistor Q3, and the n-channel resistor element R1, the HfZrSiON film which is an insulating film containing hafnium and zirconium is used. At this time, in the manufacturing method of the semiconductor device in the foregoing first embodiment, a gate first process in which the gate electrodes are formed first is used. However, in the present sixth embodiment, a description will be given to a method of manufacturing a semiconductor device having the same structure as in the foregoing first embodiment using a gate last process in which the gate electrodes are formed last. The gate last process which will be described in the present sixth embodiment is called a damascene gate process.

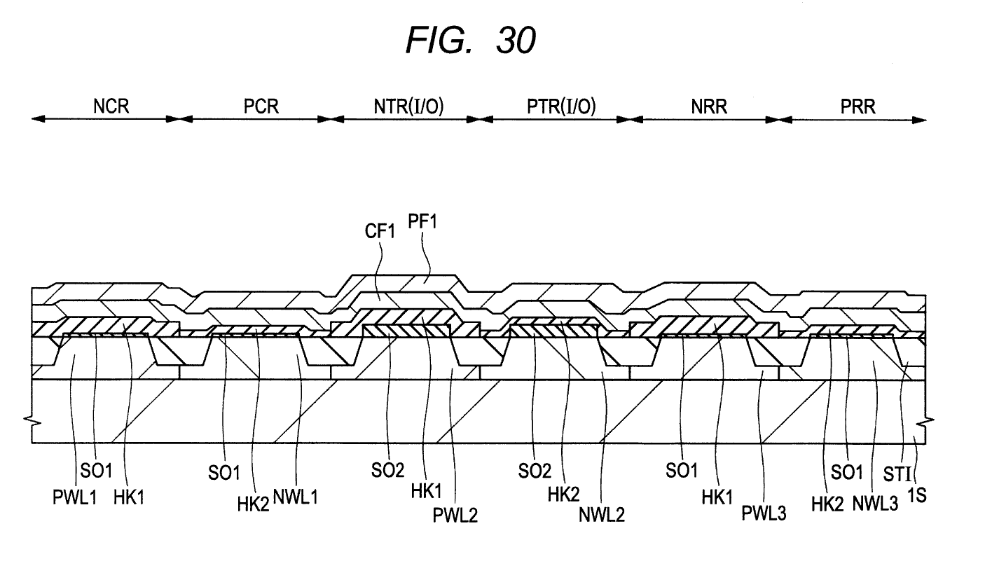

Hereinbelow, a manufacturing method of the semiconductor device in the present sixth embodiment will be described with reference to the drawings. Initially, in the steps in FIGS. 3 to 11, the manufacturing method is the same as in the foregoing first embodiment. Subsequently, as shown in FIG. 30, over the semiconductor substrate 1S formed with the HfZrSiON film HK1 or the HfSiON film HK2, the conductor film CF1 containing a metal is formed. The conductor film CF1 is formed of, e.g., a titanium nitride film, and can be formed using, e.g., a sputtering method. Then, over the conductor film CF1, the polysilicon film PF1 is formed.

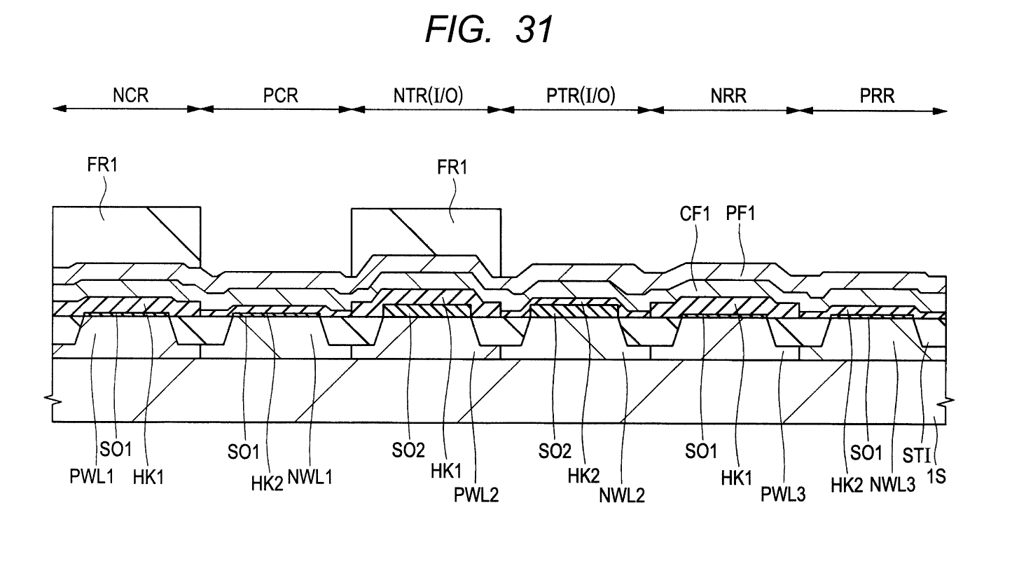

Next, as shown in FIG. 31, a resist film FR1 is coated over the polysilicon film PF1, and the coated resist film FR1 is subjected to an exposure/development treatment so as to be patterned. The patterning of the resist film FR1 is performed such that the resist film FR1 remains only in the n-channel core transistor formation region NCR and the n-channel I/O transistor formation region NTR(I/O). In other words, the resist film FR1 formed in the p-channel core transistor formation region PCR, the p-channel I/O transistor formation region PTR(I/O), the n-channel resistor element formation region NRR, and the p-channel resistor element formation region PRR is removed.

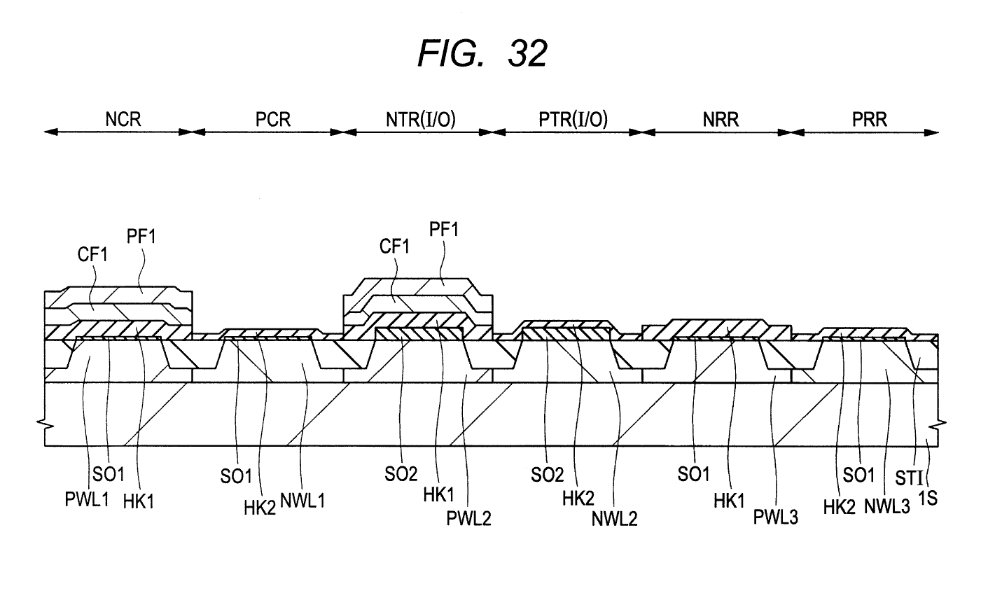

Then, as shown in FIG. 32, by etching using the patterned resist film FR1 as a mask, the polysilicon film PF1 and the conductor film CF1 which are formed in the p-channel core transistor formation region PCR, the p-channel I/O transistor formation region PTR(I/O), the n-channel resistor element formation region NRR, and the p-channel resistor element formation region PRR are removed. As a result, the polysilicon film PF1 and the conductor film CF1 remain only in the re-channel core transistor formation region NCR and the n-channel I/O transistor formation region NTR(I/O). Thereafter, the patterned resist film FR1 is removed.

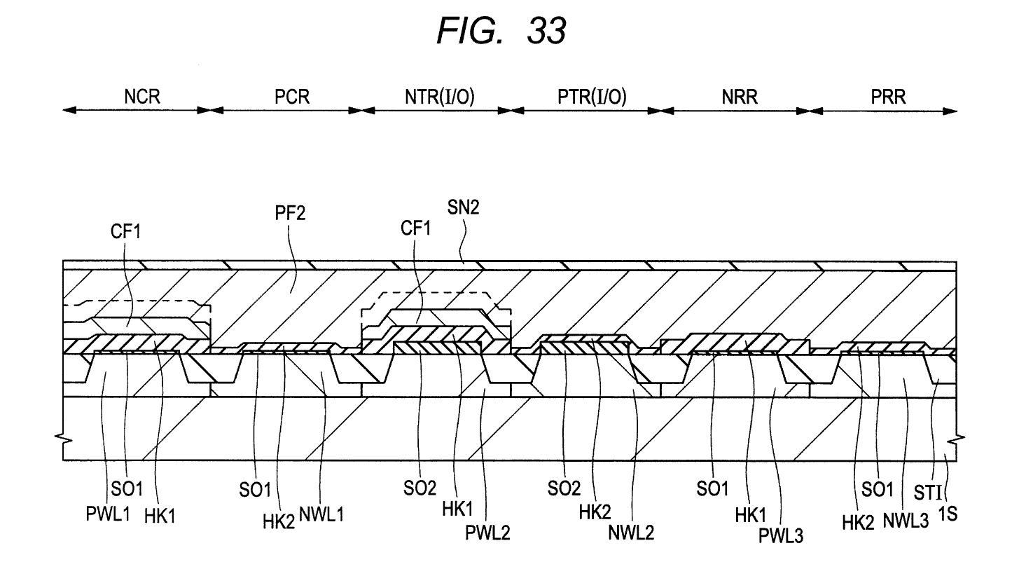

Subsequently, as shown in FIG. 33, a polysilicon film PF2 is formed over the entire main surface of the semiconductor substrate 1S and, over the polysilicon film PF2, a silicon nitride film SN2 is formed. At this time, in the n-channel core transistor formation region NCR and the n-channel I/O transistor formation region NTR(I/O), the polysilicon films PF1 and PF2 are integrated with each other so that the integrated film is assumed to be the polysilicon film PF2.

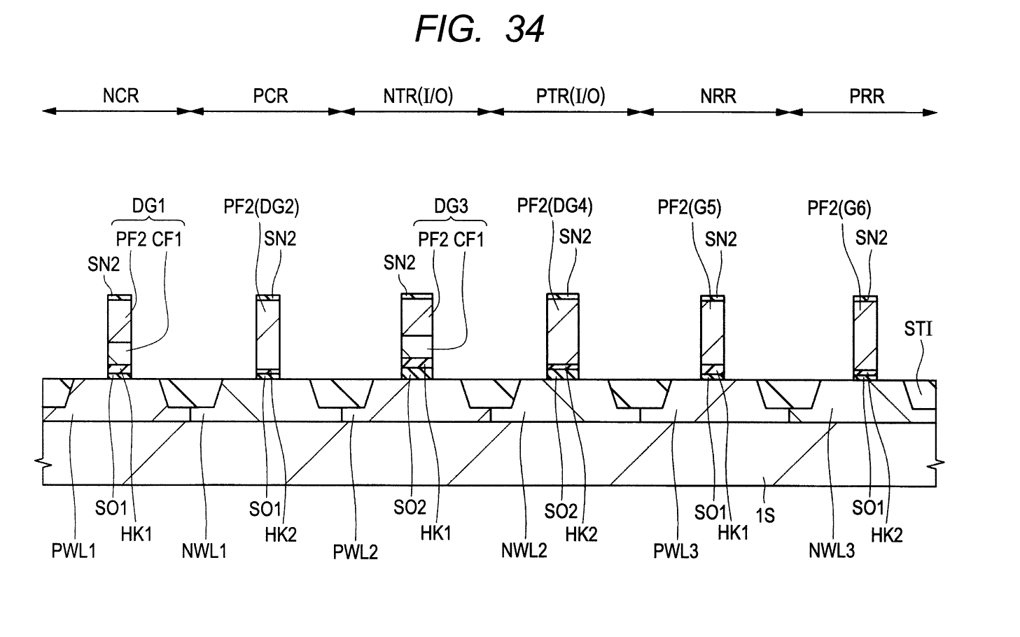

Next, as shown in FIG. 34, by using a photolithographic technique and an etching technique, the polysilicon film PF2 and the conductor film CF1 are patterned to form dummy gate electrodes DG1 to DG4 and the gate electrodes G5 and G6. Specifically, in the n-channel core transistor formation region NCR and the n-channel I/O transistor formation region NTR(I/O), the polysilicon film PF2 and the conductor film CF1 are patterned to form the dummy gate electrodes DG1 and DG3 each formed of the laminate film of the conductor film CF1 and the polysilicon film PF2. On the other hand, in the p-channel core transistor formation region PCR and the p-channel I/O transistor formation region PTR(I/O), the polysilicon film PF2 is patterned to form the dummy gate electrodes DG2 and DG4 each formed of the polysilicon film PF2. Also, in the re-channel resistor element formation region NRR and the p-channel resistor element formation region PRR, the polysilicon film PF2 is patterned to form the gate electrodes G5 and G6 each formed of the polysilicon film PF2. Note that, over the dummy gate electrodes DG1 to DG4 and the gate electrodes G5 and G6, the silicon nitride film SN2 is formed.

Thereafter, in the n-channel core transistor formation region NCR, using the dummy gate electrode DG1 as a mask, the HfZrSiON film HK1 and the silicon oxide film SO1 are processed to form the gate insulating film including the silicon oxide film SO1 and the HfZrSiON film HK1. Likewise, in the p-channel core transistor formation region PCR, using the dummy gate electrode DG2 as a mask, the HfSiON film HK2 and the silicon oxide film SO1 are processed to form the gate insulating film including the silicon oxide film SO1 and the HfSiON film HK2. Also in the n-channel I/O transistor formation region NTR(I/O), using the dummy gate electrode DG3 as a mask, the HfZrSiON film HK1 and the silicon oxide film SO2 are processed to form the gate insulating film including the silicon oxide film SO2 and the HfZrSiON film HK1. Likewise, in the p-channel I/O transistor formation region PTR(I/O), using the dummy gate electrode DG4 as a mask, the HfSiON film HK2 and the silicon oxide film SO2 are processed to form the gate insulating film including the silicon oxide film SO2 and the HfSiON film HK2. Also, in the n-channel resistor element formation region NRR, using the gate electrode G5 as a mask, the HfZrSiON film HK1 and the silicon oxide film SO1 are processed to form the gate insulating film including the silicon oxide film SO1 and the HfZrSiON film HK1. Likewise, in the p-channel resistor element formation region PRR, using the gate electrode G6 as a mask, the HfSiON film HK2 and the silicon oxide film SO1 are processed to form the gate insulating film including the silicon oxide film SO1 and the HfSiON film HK2.

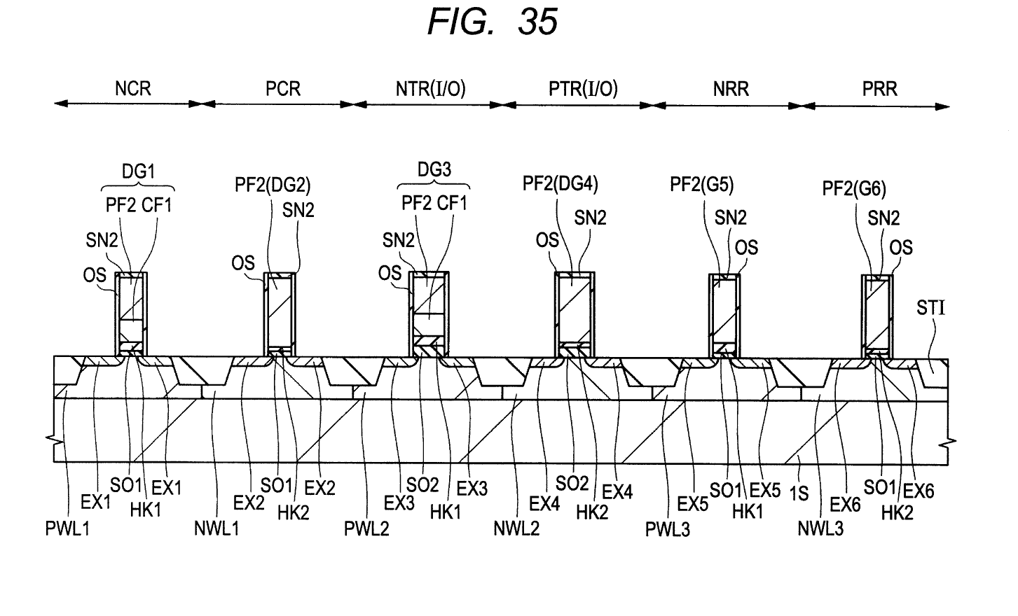

Next, as shown in FIG. 35, over the side walls of the dummy gate electrodes DG1 to DG4 and the gate electrodes G5 and G6, the offset spacers OS are formed. The offset spacers OS are formed of, e.g., a silicon oxide film, and can be formed by, e.g., forming a silicon oxide film over the semiconductor substrate 1S by a CVD method, and then anisotropically etching the silicon oxide film.

Then, by using a photolithographic technique and an ion implantation method, the shallow n-type impurity diffusion regions EX1, EX3, and EX5 are formed in alignment with respect to the dummy gate electrodes DG1 and DG3 and the gate electrode G5. The shallow n-type impurity diffusion regions EX1, EX3, and EX5 are semiconductor regions into which an n-type impurity such as phosphorus or arsenic has been introduced. Likewise, by using a photolithographic technique and an ion implantation method, the shallow p-type impurity diffusion regions EX2, EX4, and EX6 are formed in alignment with respect to the dummy gate electrodes DG2 and DG4 and the gate electrode G6. The shallow p-type impurity diffusion regions EX2, EX4, and EX6 are semiconductor regions into which a p-type impurity such as boron has been introduced.

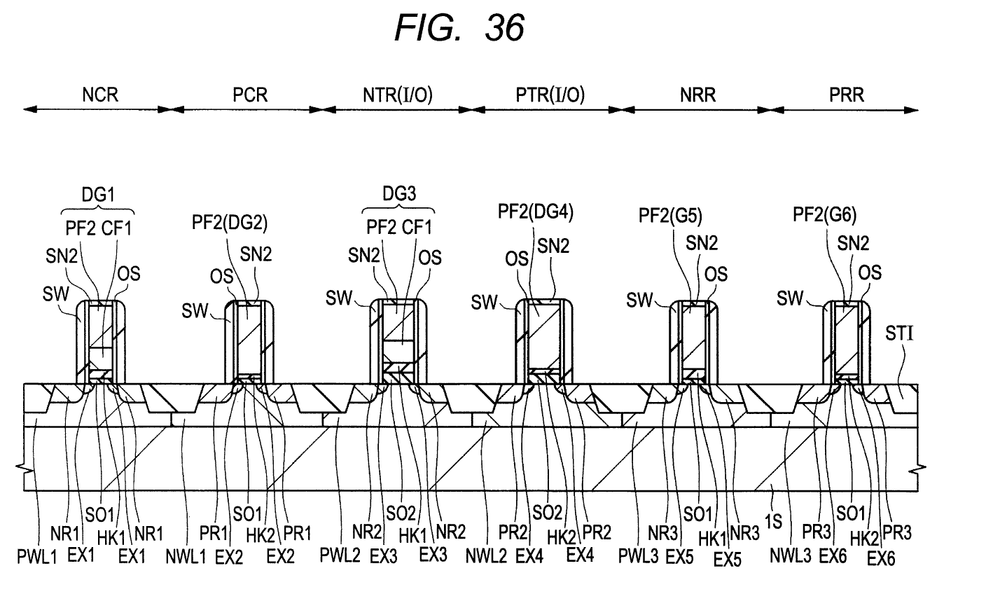

Next, as shown in FIG. 36, over the semiconductor substrate 1S, a silicon oxide film is formed. The silicon oxide film can be formed using, e.g., a CVD method. Then, by anisotropically etching the silicon oxide film, the sidewalls SW are formed over the side walls of the dummy gate electrodes DG1 to DG4 and the gate electrodes G5 and G6. The sidewalls SW are formed of a single-layered film of silicon oxide, but it is not limited thereto. For example, the sidewalls SW formed of a laminate film of a silicon nitride film and a silicon oxide film may also be formed.

Subsequently, by using a photolithographic technique and an ion implantation method, the deep n-type impurity diffusion regions NR1, NR2, and NR3 in alignment with the sidewalls SW are respectively formed in the n-channel core transistor formation region NCR, the n-channel I/O transistor formation region NTR(I/O), and the n-channel resistor element formation region NRR. The deep n-type impurity diffusion regions NR1, NR2, and NR3 are semiconductor regions into which an n-type impurity such as phosphorus or arsenic has been introduced. Likewise, by using a photolithographic technique and an ion implantation method, the deep p-type impurity diffusion regions PR1, PR2, and PR3 in alignment with the sidewalls SW are respectively formed in the p-channel core transistor formation region PCR, the p-channel I/O transistor formation region PTR(I/O), and the p-channel resistor element formation region PRR. The deep p-type impurity diffusion regions PR1, PR2, and PR3 are semiconductor regions into which a p-type impurity such as boron has been introduced.

In this manner, the deep n-type impurity diffusion regions NR1, NR2, and NR3 and the deep p-type impurity diffusion regions PR1, PR2, and PR3 are formed, and then a heat treatment at about 1000° C. is performed, thereby activating the introduced impurities.

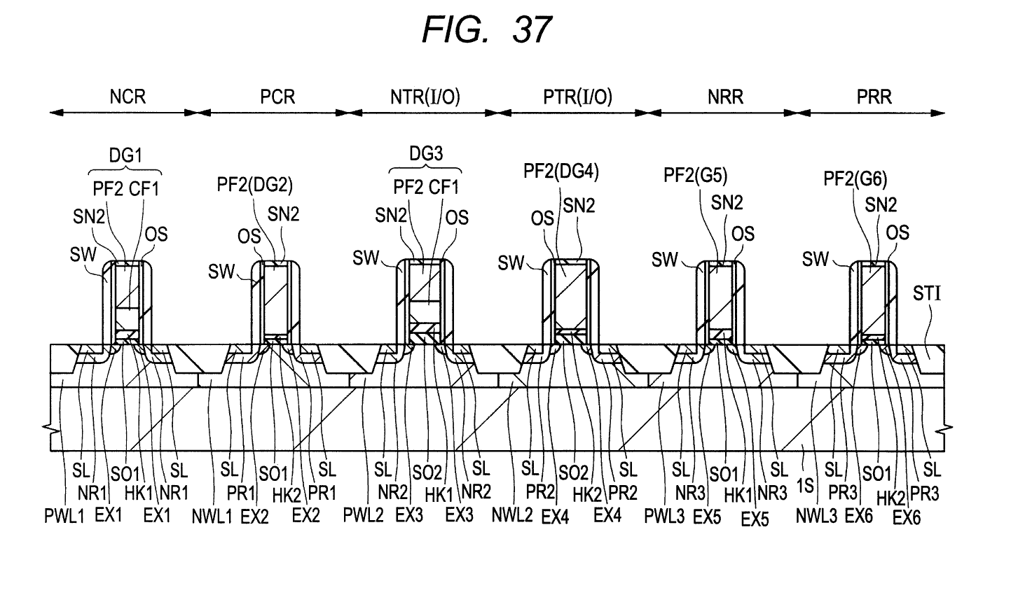

Thereafter, as shown in FIG. 37, over the semiconductor substrate 1S, a nickel platinum film (not shown) is formed. At this time, since the silicon nitride film SN2 is formed over the upper surfaces of the dummy gate electrodes DG1 to DG4 and the gate electrodes G5 and G6, the nickel platinum film is kept from direct contact with the dummy gate electrodes DG1 to DG4 and the gate electrodes G5 and G6. On the other hand, the nickel platinum film comes in direct contact with the deep n-type impurity diffusion regions NR1, NR2, and NR3 and the deep p-type impurity diffusion regions PR1, PR2, and PR3.

The nickel platinum film can be formed using, e.g., a sputtering method. Then, after the nickel platinum film is formed, a heat treatment is performed to result in a reaction between silicon and the nickel platinum film at the surfaces of the deep n-type impurity diffusion regions NR1, NR2, and NR3 so that the silicide films SL formed of a nickel platinum silicide film are formed. This also allows reductions in the resistances of the deep n-type impurity diffusion regions NR1, NR2, and NR3. Also, by the heat treatment mentioned above, at the surfaces of the deep p-type impurity diffusion regions PR1, PR2, and PR3 also, a reaction occurs between silicon and the nickel platinum film to form the silicide films SL formed of a nickel platinum silicide film. This also allows reductions in the resistances of the deep p-type impurity diffusion regions PR1, PR2, and PR3. Note that, as described above, over the upper surfaces of the dummy gate electrodes DG1 to DG4 and the gate electrodes G5 and G6, the silicon nitride film SN2 is formed, and therefore the silicide films SL are not formed over the upper surfaces of the dummy gate electrodes DG1 to DG4 and the gate electrodes G5 and G6.

Then, the unreacted nickel platinum film is removed from over the semiconductor substrate 1S. Note that, in the present sixth embodiment, the silicide films SL formed of the nickel platinum silicide film are formed but, instead of the nickel platinum silicide film, for example, a nickel silicide film, a titanium silicide film, a cobalt silicide film, a platinum silicide film, or the like may also be used to form the silicide films SL.

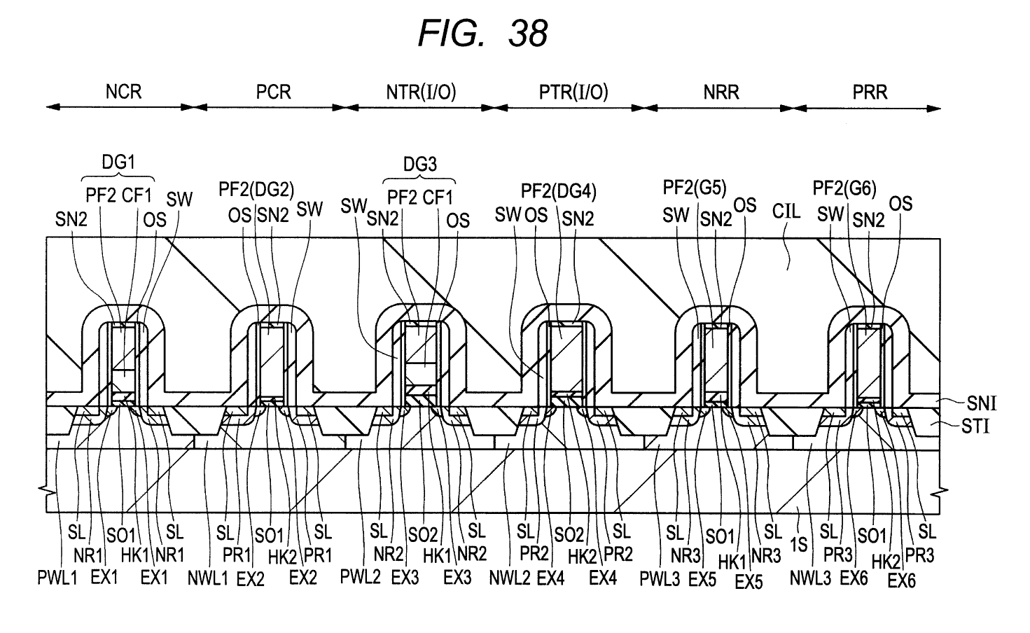

Next, as shown in FIG. 38, over the semiconductor substrate 1S formed with the dummy gate electrodes DG1 to DG4 and the gate electrodes G5 and G6, the silicon nitride film SN1 is formed and, over the silicon nitride film SN1, the contact interlayer insulating film CIL is formed. The contact interlayer insulating film CIL1 is formed of a laminate film of, e.g., an ozone TEOS film formed by a thermal CVD method using ozone and TEOS (tetra ethyl ortho silicate) as raw materials and a plasma TEOS film formed by a plasma CVD method using TEOS provided over the ozone TEOS film as a raw material.

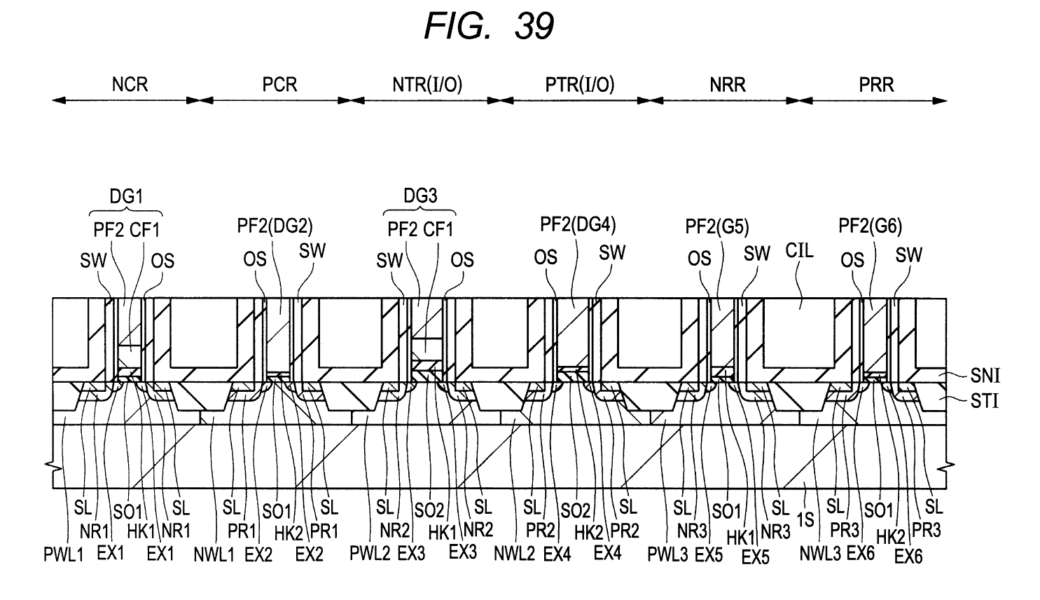

Subsequently, as shown in FIG. 39, the surface of the contact interlayer insulating film CIL is polished by, e.g., a CMP (Chemical Mechanical Polishing) method, and the surfaces of the silicon nitride films SN1 and SN2 are also polished. As a result, the upper surfaces of the dummy gate electrodes DG1 to DG4 and the gate electrodes G5 and G6 are exposed.

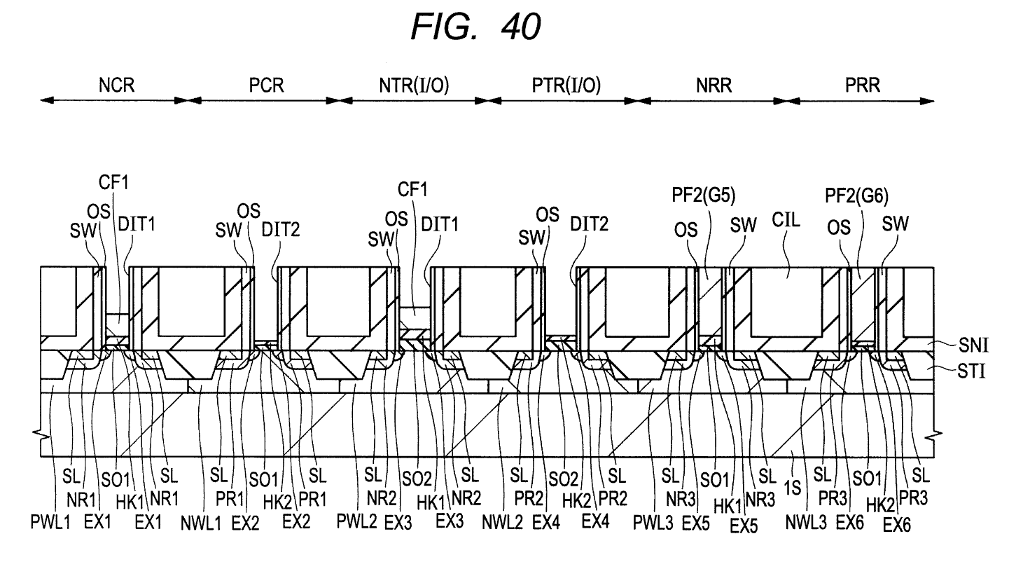

Thereafter, as shown in FIG. 40, using a photolithographic technique and an etching technique, the polysilicon film PF2 forming parts of the dummy gate electrodes DG1 and DG3 is removed to form trenches DIT1. At the bottom portions of the trenches DIT1, the conductor film CF1 is exposed. Likewise, the polysilicon film PF2 forming the dummy gate electrodes DG2 and DG4 is removed to form trenches DIT2. At the bottom portions of the trenches DIT2, the HfSiON film HK2 is exposed. Note that the polysilicon film PF2 forming the gate electrodes G5 and G6 is left.

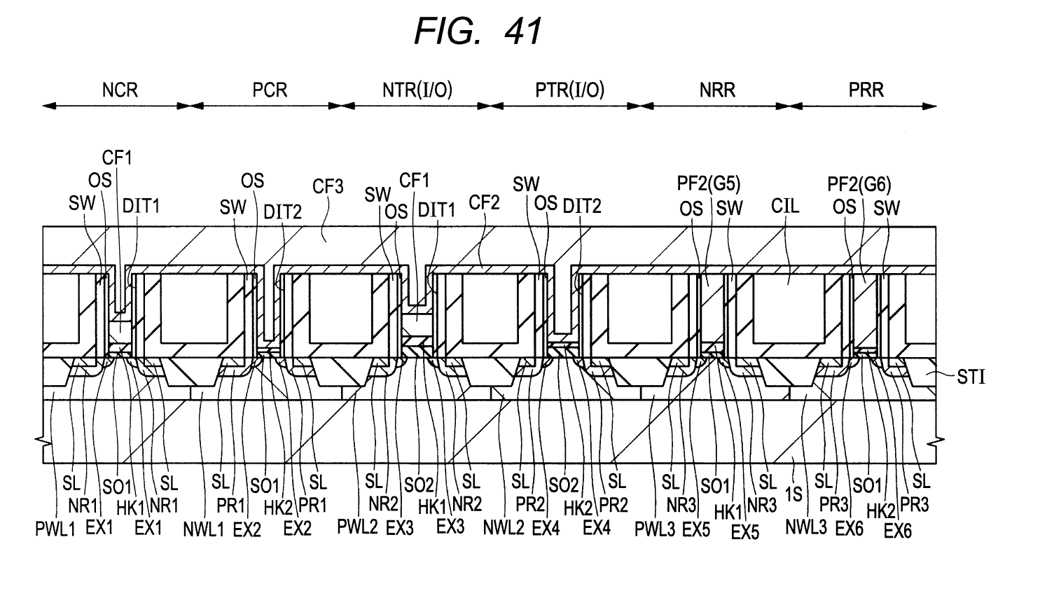

Next, as shown in FIG. 41, over the entire main surface of the semiconductor substrate 1S, a conductor film CF2 for adjusting the work functions of the p-channel core transistor and the p-channel I/O transistor is formed. The conductor film CF2 is formed over the inner surfaces of the trenches DIT1 and DIT2 so as not to completely fill up the trenches DIT1 and DIT2. Thereafter, over the conductor film CF2, a conductor film CF3 is formed so as to completely fill up the insides of the trenches DIT1 and DIT2. The conductor film CF3 is formed of, e.g., a conductor film containing aluminum, and can be formed by, e.g., a sputtering method.

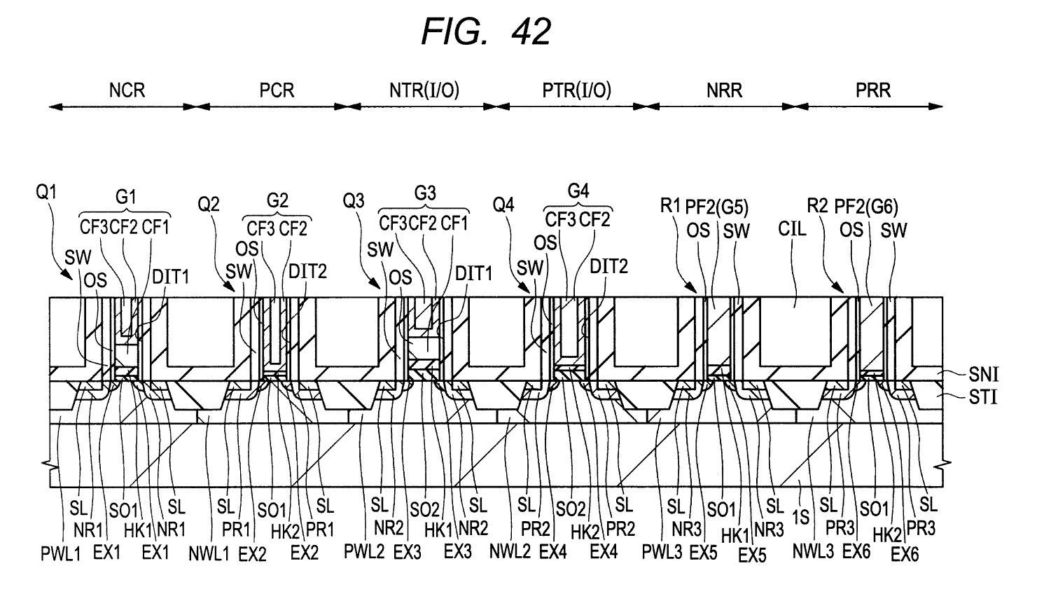

Subsequently, as shown in FIG. 42, the unneeded conductor films CF2 and CF3 formed over the contact interlayer insulating film CIL are removed by, e.g., a CMP method to leave the conductor films CF2 and CF3 only in the trenches DIT1 and DIT2. As a result, in the n-channel core transistor formation region NCR, the gate electrode G1 including the conductor films CF1, CF2, and CF3 is formed while, in the p-channel core transistor formation region PCR, the gate electrode G2 including the conductor films CF2 and CF3 is formed. Likewise, in the n-channel I/O transistor formation region NTR(I/O), the gate electrode G3 including the conductor films CF1, CF2, and CF3 is formed while, in the p-channel I/O transistor formation region PTR(I/O), the gate electrode G4 including the conductor films CF2 and CF3 is formed.

In this manner, over, e.g., the semiconductor substrate 1S, there can be formed the n-channel core transistor Q1, the p-channel core transistor Q2, the n-channel I/O transistor Q3, the p-channel I/O transistor Q4, the n-channel resistor element R1, and the p-channel resistor element R2. The subsequent wiring step is the same as in the foregoing first embodiment and, through the wiring step, the semiconductor device in the present sixth embodiment can be eventually manufactured.

### Seventh Embodiment

In the foregoing second embodiment, the description has been given to the example in which, as the gate insulating film of each of the n-channel core transistor Q1, the re-channel I/O transistor Q3, and the n-channel resistor element R1, a HfZrLaSiON film which is an insulating film containing hafnium, zirconium, and lanthanum (La) is used. At this time, in the manufacturing method of the semiconductor device in the foregoing second embodiment, the gate first process in which the gate electrodes are formed first is used. However, in the present seventh embodiment, a description will be given to a method of manufacturing a semiconductor device having the same structure as in the foregoing second embodiment using the gate last process in which the gate electrodes are formed last.

Initially, in FIGS. 3 to 8, the manufacturing method is the same as in the foregoing first embodiment. Then, the steps in FIGS. 19 to 21 described in the foregoing second embodiment are performed. Thereafter, the steps shown in FIGS. 30 to 42 and described in the foregoing sixth embodiment are performed and, through the wiring step, the semiconductor device in the present seventh embodiment can be eventually manufactured.

### Eighth Embodiment

In the foregoing third embodiment, the description has been given to the example in which, as the gate insulating film of each of the n-channel MISFETs (the n-channel core transistor Q1, the n-channel I/O transistor Q3, and the re-channel resistor element R1), an insulating film containing hafnium, zirconium, and a rare earth element (group III element other than actinium or lanthanoid) is used. At this time, in the manufacturing method of the semiconductor device in the foregoing third embodiment, the gate first process in which the gate electrodes are formed first is used. However, in the present eighth embodiment, a description will be given to a method of manufacturing a semiconductor device having the same structure as in the foregoing third embodiment using the gate last process in which the gate electrodes are formed last.

Initially, in FIGS. 3 to 8, the manufacturing method is the same as in the foregoing first embodiment. Then, the steps in FIGS. 19 to 21 described in the foregoing second embodiment are performed. At this time, in the foregoing second embodiment, as the cap film CAP2, a lanthanum film or a lanthanum oxide film is used. However, the present eight embodiment is different only in that, as the cap film CAP2, a film containing a rare earth element (any of Sc, Y, La, Ce, Pr, Nd, Pm, Sm, Eu, Gd, Tb, Dy, Ho, Er, Tm, Yb, and Lu) is used. Thereafter, the steps shown in FIGS. 30 to 42 and described in the foregoing sixth embodiment are performed and, through the wiring step, the semiconductor device in the present eighth embodiment can be eventually manufactured.

### Ninth Embodiment

In the foregoing fourth embodiment, the description has been given to the example in which, as the gate insulating film of each of the p-channel core transistor Q2, the p-channel I/O transistor Q4, and the p-channel resistor element R2, the HfAlSiON film which is an insulating film containing hafnium and aluminum (Al) is used. At this time, in the manufacturing method of the semiconductor device in the foregoing fourth embodiment, the gate first process in which the gate electrodes are formed first is used. However, in the present ninth embodiment, a description will be given to a method of manufacturing a semiconductor device having the same structure as in the foregoing fourth embodiment using the gate last process in which the gate electrodes are formed last.

Initially, in the manufacturing steps in FIGS. 3 to 5, the manufacturing method is the same as in the foregoing first embodiment. Then, the steps in FIGS. 22 to 26 described in the foregoing fourth embodiment are performed. Thereafter, the steps shown in FIGS. 30 to 42 and described in the foregoing sixth embodiment are performed and, through the wiring step, the semiconductor device in the present ninth embodiment can be eventually manufactured.

### Tenth Embodiment

In the foregoing fifth embodiment, the description has been given to the example in which the foregoing second embodiment and the foregoing fourth embodiment are combined. At this time, in the manufacturing method of the semiconductor device in the foregoing fifth embodiment, the gate first process in which the gate electrodes are formed first is used. However, in the present tenth embodiment, a description will be given to a method of manufacturing a semiconductor device having the same structure as in the foregoing fifth embodiment using the gate last process in which the gate electrodes are formed last.

Initially, in the manufacturing steps in FIGS. 3 to 5, the manufacturing method is the same as in the foregoing first embodiment. Thereafter, the steps of the foregoing fourth embodiment shown in FIGS. 22 to 24 are performed. Then, the steps of the foregoing fifth embodiment shown in FIGS. 27 to 29 are performed. Thereafter, the steps shown in FIGS. 30 to 42 and described in the foregoing sixth embodiment are performed and, through the wiring step, the semiconductor device in the present tenth embodiment can be eventually manufactured.

### Eleventh Embodiment

In the present eleventh embodiment, a description will be given to an example of the method of manufacturing the semiconductor device using the gate last process in which the gate electrodes are formed last, which is different from the example of the foregoing sixth embodiment.

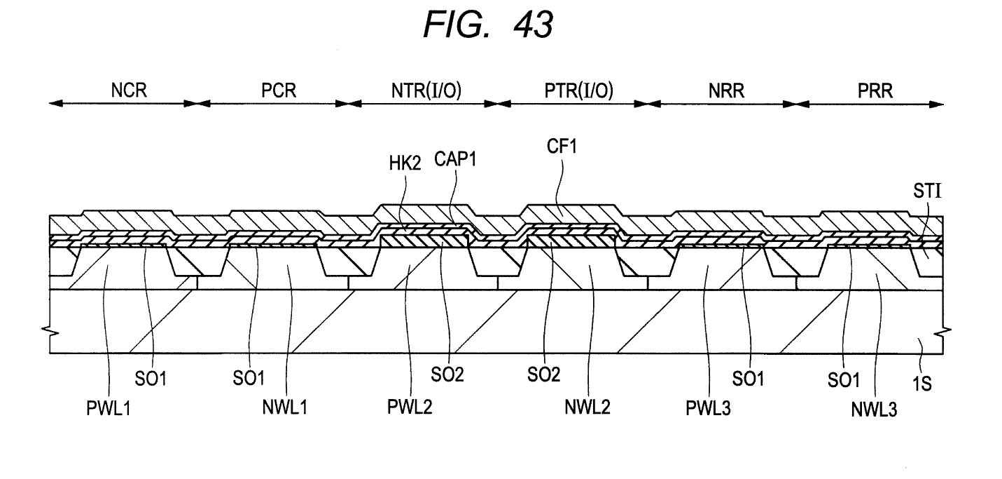

Hereinbelow, the manufacturing method of the semiconductor device in the present eleventh embodiment will be described with reference to the drawings. Initially, in FIGS. 3 to 5, the manufacturing method is the same as in the foregoing first embodiment. Thereafter, as shown in FIG. 43, over the semiconductor substrate 1S formed with the silicon oxide films SO1 and SO2, the HfSiON film HK2 is formed. The HfSiON film HK2 can be formed by using, e.g., a sputtering method, a CVD (Chemical Vapor Deposition) method, or an ALD (Atomic Layer Deposition) method. Note that, instead of the HfSiON film HK2, another hafnium-based insulating film such as a HfSiO film, a HfON film, or a HfO film can also be used.

Then, over the HfSiON film HK2, the cap film CAP1 is formed. The cap film CAP1 is formed of, e.g., a Zr (zirconium) film or a ZrO (zirconium oxide) film, and can be formed by using, e.g., a sputtering method. Subsequently, over the semiconductor substrate 1S formed with the cap film CAP1, the conductor film CF1 containing a metal is formed. The conductor film CF1 is formed of, e.g., a titanium nitride film, and can be formed by using, e.g., a sputtering method.

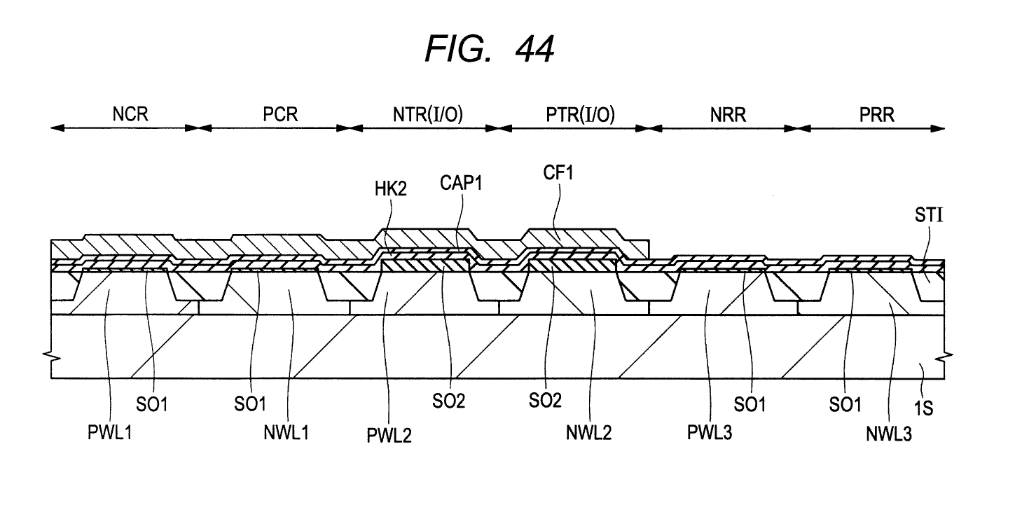

Thereafter, as shown in FIG. 44, using a photolithographic technique and an etching technique, the conductive film CF1 formed in the n-channel resistor element formation region NRR and the p-channel resistor element formation region PRR is removed.

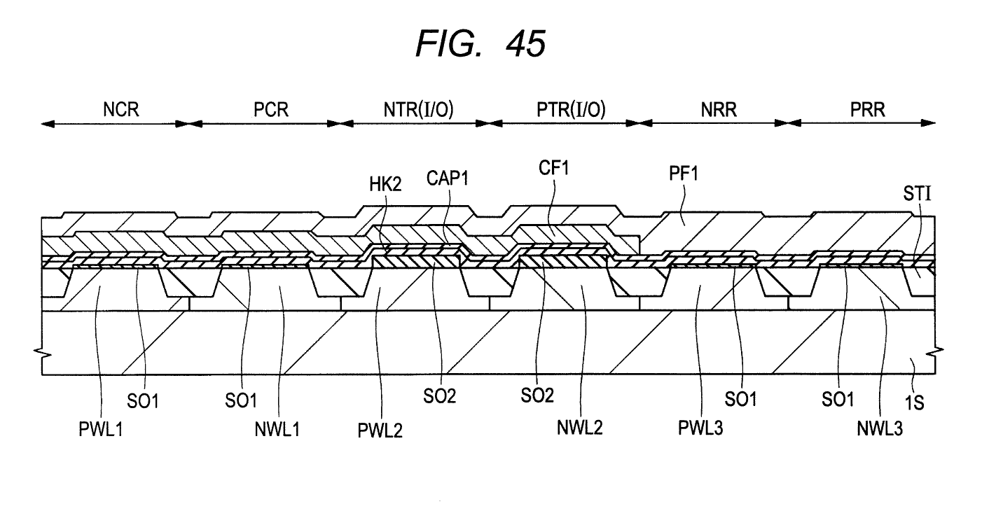

Next, as shown in FIG. 45, over the entire main surface of the semiconductor substrate 1S, the polysilicon film PF1 is formed. Then, over the formed polysilicon film PF1, a resist film (not shown) is coated. Thereafter, the coated resist film is subjected to an exposure/development treatment so as to be patterned. The patterning of the resist film is performed such that the resist film remains only in the n-channel core transistor formation region NCR, the n-channel I/O transistor formation region NTR(I/O), and the n-channel resistor element formation region NRR. In other words, the resist film formed in the p-channel core transistor formation region PCR, the p-channel I/O transistor formation region PTR(I/O), and the p-channel resistor element formation region PRR is removed.

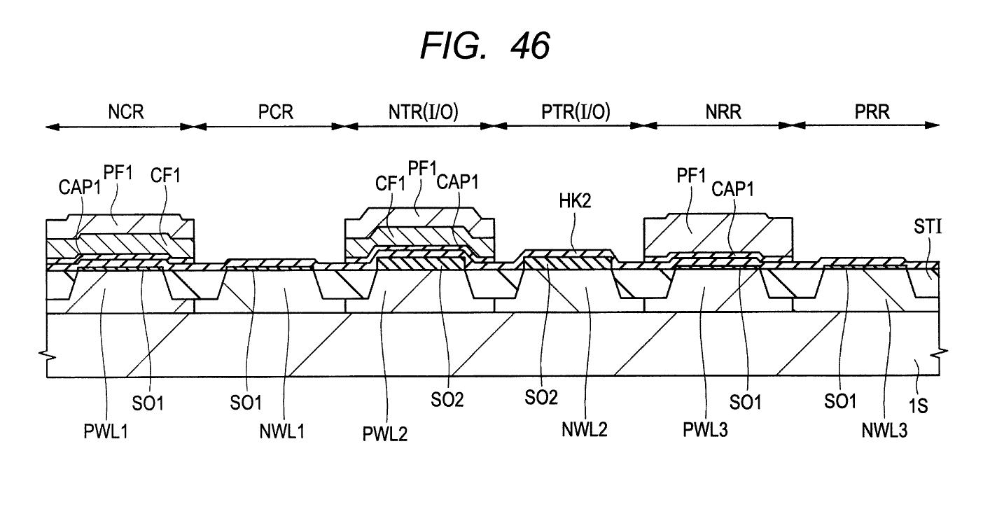

Then, as shown in FIG. 46, by etching using the patterned resist film as a mask, the polysilicon film PF1, the conductor film CF1, and the cap film CAP1 which are formed in the p-channel core transistor formation region PCR, the p-channel I/O transistor formation region PTR(I/O), and the p-channel resistor element formation region PRR are removed. As a result, the polysilicon film PF1, the conductor film CF1, and the cap film CAP1 remain in the n-channel core transistor formation region NCR and the n-channel I/O transistor formation region NTR(I/O). Likewise, the polysilicon film PF1 and the cap film CAP1 remain in the n-channel resistor element formation region NRR. Thereafter, the patterned resist film is removed.

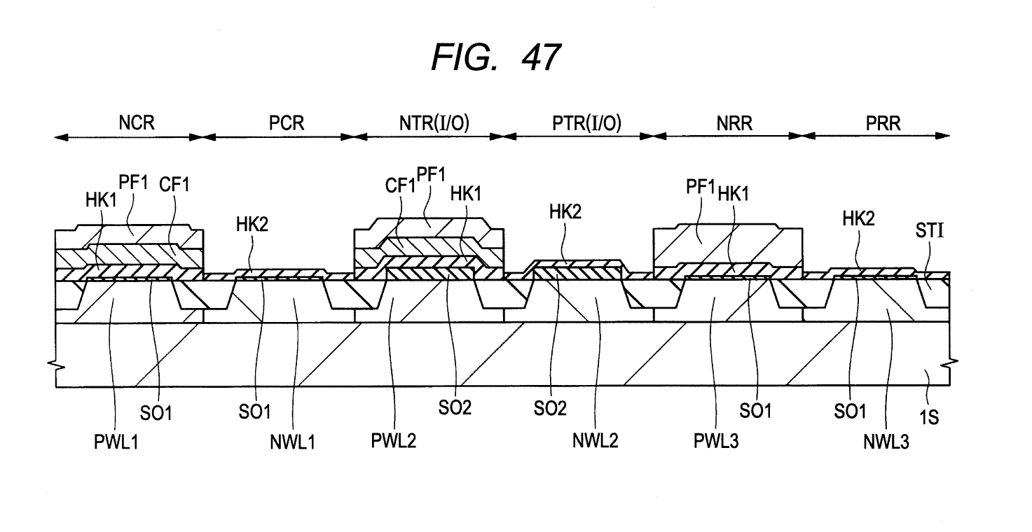

Subsequently, as shown in FIG. 47, a heat treatment is performed to the semiconductor substrate 1S. In the n-channel core transistor formation region NCR, the n-channel I/O transistor formation region NTR(I/O), and the n-channel resistor element formation region NRR, the cap film CAP1 is formed directly over the HfSiON film HK2 so that zirconium (Zr) contained in the cap film CAP1 is diffused into the HfSiON film HK2 by the heat treatment mentioned above. As a result, the HfZrSiON film HK1 is formed. On the other hand, in the p-channel core transistor formation region PCR, the p-channel I/O transistor formation region PTR(I/O), and the p-channel resistor element formation region PRR, the cap film CAP1 has been removed so that the exposed HfSiON film HK2 maintains the current state. In this manner, in the n-channel core transistor formation region NCR, the n-channel I/O transistor formation region NTR(I/O), and the n-channel resistor element formation region NRR, the HfZrSiON film HK1 is formed. On the other hand, in the p-channel core transistor formation region PCR, the p-channel I/O transistor formation region PTR(I/O), and the p-channel resistor element formation region PRR, the HfSiON film HK2 remains without any alteration. Here, the HfZrSiON film HK1 contains zirconium, and accordingly has a physical film thickness larger than that of the HfSiON film HK2 which does not contain zirconium.

Thereafter, steps which are substantially the same as the steps shown in FIGS. 33 to 42 and described in the foregoing sixth embodiment are performed and, through the wiring step, the semiconductor device according to the present eleventh embodiment can be eventually manufactured.

While the invention achieved by the present inventors has been specifically described heretofore based on the embodiments thereof, the present invention is not limited to the foregoing embodiments. It will be appreciated that various changes and modifications can be made in the invention within the scope not departing from the gist thereof.

The present invention can be used widely in a manufacturing industry for manufacturing semiconductor devices.

What is claimed is:

1. A semiconductor device, comprising:
an n-channel MISFET formed in an n-channel MISFET formation region of a semiconductor substrate; and
a p-channel MISFET formed in a p-channel MISFET formation region of the semiconductor substrate,
wherein the n-channel MISFET has:
(a) a first insulating film formed over the semiconductor substrate, and containing hafnium and zirconium;
(b) a first gate electrode formed over the first insulating film;
(c) a first source region formed in the semiconductor substrate; and
(d) a first drain region formed in the semiconductor substrate,
wherein the p-channel MISFET has:
(e) a second insulating film formed over the semiconductor substrate, and containing hafnium;
(f) a second gate electrode formed over the second insulating film;
(g) a second source region formed in the semiconductor substrate; and
(h) a second drain region formed in the semiconductor substrate,
wherein a physical film thickness of the first insulating film is larger than a physical film thickness of the second insulating film, and
wherein a concentration of the zirconium contained in the first insulating film is higher than a concentration of the zirconium contained in the second insulating film.

2. A semiconductor device according to claim 1,
wherein the first insulating film is formed of any of a HfZrSiON film, a HfZrON film, and a HfZrO film, and
wherein the second insulating film is formed of any of a HfSiON film, a HfON film, and a HfO film.

3. A semiconductor device according to claim 2,
wherein, between the semiconductor substrate and the first insulating film, a first interface layer is formed, and
wherein, between the semiconductor substrate and the second insulating film, a second interface layer is formed.

4. A semiconductor device according to claim 3,
wherein each of the first interface layer and the second interface layer is formed of a silicon oxide film.

5. A semiconductor device according to claim 1,
wherein the first gate electrode is formed of a first conductor film containing a metal, and a second conductor film formed over the first conductor film, and
wherein the second gate electrode is formed of the first conductor film containing the metal and the second conductor film formed over the first conductor film.

6. A semiconductor device according to claim 5,
wherein the first conductor film is formed of a titanium nitride film, and
wherein the second conductor film is formed of a polysilicon film.

7. A semiconductor device according to claim 5,
wherein the first conductor film is formed of a titanium nitride film, and
wherein the second conductor film is formed of an aluminum film.

8. A semiconductor device according to claim 1,
wherein the first insulating film further contains La.

9. A semiconductor device according to claim 1,
wherein the first insulating film further contains a rare earth element.

10. A semiconductor device according to claim 9,
wherein the first insulating film further contains any of elements of Sc, Y, La, Ce, Pr, Nd, Pm, Sm, Eu, Gd, Tb, Dy, Ho, Er, Tm, Yb, and Lu.

11. A semiconductor device according to claim 1,
wherein the second insulating film further contains Al.

12. A semiconductor device according to claim 1,
wherein the first insulating film further contains La, and
wherein the second insulating film further contains Al.

13. A method of manufacturing a semiconductor device comprising an n-channel MISFET formed in an n-channel MISFET formation region of a semiconductor substrate, and a p-channel MISFET formed in a p-channel MISFET formation region of the semiconductor substrate, the method comprising the steps of:
(a) forming a second insulating film containing hafnium over the semiconductor substrate;
(b) after the step (a), forming a hard mask film over the second insulating film;
(c) after the step (b), patterning the hard mask film to remove the hard mask film formed in the n-channel MISFET formation region;
(d) after the step (c), forming a first cap film containing zirconium over the second insulating film formed in the n-channel MISFET formation region and over the hard mask film formed in the p-channel MISFET formation region;
(e) after the step (d), performing a heating treatment to the semiconductor substrate to diffuse the zirconium contained in the first cap film into the second insulating film in the n-channel MISFET formation region, and thereby form a first insulating film containing hafnium and zirconium in the re-channel MISFET formation region;
(f) after the step (e), removing the first cap film and the hard mask film which are formed in the p-channel MISFET formation region;
(g) after the step (f), forming a conductor film over the first insulating film formed in the n-channel MISFET formation region and over the second insulating film formed in the p-channel MISFET formation region;
(h) after the step (g), patterning the conductor film to form a first gate electrode in the n-channel MISFET formation region, and form a second gate electrode in the p-channel MISFET formation region; and
(i) after the step (h), introducing an n-type impurity into the semiconductor substrate in the n-channel MISFET formation region to form a first source region and a first drain region, while introducing a p-type impurity into the semiconductor substrate in the p-channel MISFET formation region to form a second source region and second drain region,
wherein a physical film thickness of the first insulating film is larger than a physical film thickness of the second insulating film, and
wherein a concentration of the zirconium contained in the first insulating film is higher than a concentration of the zirconium contained in the second insulating film.

14. A method of manufacturing the semiconductor device according to claim 13,
wherein the first insulating film is formed of any of a HfZrSiON film, a HfZrON film, and a HfZrO film, and
wherein the second insulating film is formed of any of a HfSiON film, a HfON film, and a HfO film.

15. A method of manufacturing the semiconductor device according to claim 13, further comprising the step of:
prior to the step (a), forming an interface layer over the semiconductor substrate,
wherein the step (a) includes forming the second insulating film over the interface layer.

16. A method of manufacturing the semiconductor device according to claim 15,
wherein the interface layer is formed of a silicon oxide film.

17. A method of manufacturing the semiconductor device according to claim 13,
wherein the step (g) includes forming a first conductor film containing a metal, and then forming a second conductor film over the first conductor film to form the conductor film including the first conductor film and the second conductor film.

18. A method of manufacturing the semiconductor device according to claim 17,
wherein the step (g) includes forming the first conductor film of a titanium nitride film, and forming the second conductor film of a polysilicon film.

19. A method of manufacturing the semiconductor device according to claim 13, further comprising the step of:
(j) after the step (d) and prior to the step (e), forming a second cap film containing lanthanum over the first cap film,
wherein the step (e) includes performing a heating treatment to the semiconductor substrate after the step (j) to diffuse the zirconium contained in the first cap film and the lanthanum contained in the second cap film into the second insulating film in the n-channel MISFET formation region, and thereby form the first insulating film containing hafnium, zirconium, and lanthanum in the n-channel MISFET formation region.

20. A method of manufacturing the semiconductor device according to claim 19, further comprising the step of:
(k) after the step (a) and prior to the step (b), forming a third cap film containing aluminum over the second insulating film,
wherein the step (b) includes forming the hard mask film over the third cap film after the step (k),
wherein the step (c) includes patterning the hard mask film and the third cap film to remove the hard mask film and the third cap film which are formed in the n-channel MISFET formation region, and
wherein the step (e) includes performing a heating treatment to the semiconductor substrate to diffuse the zirconium contained in the first cap film and the lanthanum contained in the second cap film into the second insulating film in the n-channel MISFET formation region, and thereby form the first insulating film containing hafnium, zirconium, and lanthanum in the n-channel MISFET formation region and to diffuse aluminum contained in the third cap film into the second insulating film in the p-channel MISFET formation region, and thereby form the second insulating film containing hafnium and aluminum in the p-channel MISFET formation region.

21. A method of manufacturing a semiconductor device comprising an n-channel MISFET formed in an n-channel MISFET formation region of a semiconductor substrate, and a p-channel MISFET formed in a p-channel MISFET formation region of the semiconductor substrate, the method comprising the steps of:
(a) forming a second insulating film containing hafnium over the semiconductor substrate;
(b) after the step (a), forming a hard mask film over the second insulating film;
(c) after the step (b), patterning the hard mask film to remove the hard mask film formed in the n-channel MISFET formation region;
(d) after the step (c), forming a first cap film containing zirconium over the second insulating film formed in the n-channel MISFET formation region and over the hard mask film formed in the p-channel MISFET formation region;
(e) after the step (d), performing a heating treatment to the semiconductor substrate to diffuse the zirconium contained in the first cap film into the second insulating film in the n-channel MISFET formation region, and thereby form a first insulating film containing hafnium and zirconium in the re-channel MISFET formation region;
(f) after the step (e), removing the first cap film and the hard mask film which are formed in the p-channel MISFET formation region;
(g) after the step (f), forming a first conductor film containing a metal over the first insulating film formed in the n-channel MISFET formation region and over the second insulating film formed in the p-channel MISFET formation region;
(h) after the step (g), patterning the first conductor film to remove the first conductor film formed in the p-channel MISFET formation region;
(i) after the step (h), forming a second conductor film over the first conductor film formed in the n-channel MISFET formation region and over the second insulating film formed in the p-channel MISFET formation region;
(j) after the step (i), patterning the first conductor film and the second conductor film to form a first dummy gate electrode in the n-channel MISFET formation region, and form a second dummy gate electrode in the p-channel MISFET formation region;
(k) after the step (j), introducing an n-type impurity into the semiconductor substrate in the n-channel MISFET formation region to form a first source region and a first drain region, while introducing a p-type impurity into the semiconductor substrate in the p-channel MISFET formation region to form a second source region and a second drain region;
(l) after the step (k), forming, over the semiconductor substrate, an interlayer insulating film covering the first dummy gate electrode and the second dummy gate electrode;
(m) after the step (l), polishing a surface of the interlayer insulating film to expose an upper surface of the first dummy gate electrode and an upper surface of the second dummy gate electrode;
(n) after the step (m), removing the second conductor film forming a part of the first dummy gate electrode to form a first trench in the interlayer insulating film, while removing the second conductor film forming the second dummy gate electrode to form a second trench in the interlayer insulating film;
(o) after the step (n), forming a third conductor film containing a metal over the interlayer insulating film including an inside of the first trench and an inside of the second trench, and forming a fourth conductor film containing a metal over the third conductor film to fill the inside of the first trench and the inside of the second trench with the third conductor film and the fourth conductor film; and
(p) after the step (o), removing the unneeded third conductor film and the unneeded fourth conductor film which are formed over the interlayer insulating film to form a first gate electrode in the first trench, and form a second gate electrode in the second trench,
wherein a physical film thickness of the first insulating film is larger than a physical film thickness of the second insulating film, and
wherein a concentration of the zirconium contained in the first insulating film is higher than a concentration of the zirconium contained in the second insulating film.

22. A method of manufacturing the semiconductor device according to claim 21,
wherein the first insulating film is formed of any of a HfZrSiON film, a HfZrON film, and a HfZrO film, and
wherein the second insulating film is formed of any of a HfSiON film, a HfON film, and a HfO film.

23. A method of manufacturing the semiconductor device according to claim 21, further comprising the step of:
prior to the step (a), forming an interface layer over the semiconductor substrate,
wherein the step (a) includes forming the second insulating film over the interface layer.

24. A method of manufacturing the semiconductor device according to claim 23,
wherein the interface layer is formed of a silicon oxide film.

25. A method of manufacturing the semiconductor device according to claim 21,
wherein the step (g) includes forming the first conductor film of a titanium nitride film,
wherein the step (i) includes forming the second conductor film of a polysilicon film, and
wherein the step (o) includes forming the fourth conductor film of an aluminum film.

26. A method of manufacturing the semiconductor device according to claim 21, further comprising the step of:
(q) after the step (d) and prior to the step (e), forming a second cap film containing lanthanum over the first cap film,
wherein the step (e) includes performing a heating treatment to the semiconductor substrate after the step (q) to diffuse the zirconium contained in the first cap film and the lanthanum contained in the second cap film into the second insulating film in the n-channel MISFET formation region, and thereby form the first insulating film containing hafnium, zirconium, and lanthanum in the n-channel MISFET formation region.

27. A method of manufacturing the semiconductor device according to claim 26, further comprising the step of:
(r) after the step (a) and prior to the step (b), forming a third cap film containing aluminum over the second insulating film,
wherein the step (b) includes forming the hard mask film over the third cap film after the step (r),
wherein the step (c) includes patterning the hard mask film and the third cap film to remove the hard mask film and the third cap film which are formed in the n-channel MISFET formation region, and
wherein the step (e) includes performing a heating treatment to the semiconductor substrate to diffuse the zirconium contained in the first cap film and the lanthanum contained in the second cap film into the second insulating film in the n-channel MISFET formation region, and thereby form the first insulating film containing hafnium, zirconium, and lanthanum in the n-channel MISFET formation region and to diffuse aluminum contained in the third cap film into the second insulating film in the p-channel MISFET formation region, and thereby form the second insulating film containing hafnium and aluminum in the p-channel MISFET formation region.

28. A method of manufacturing a semiconductor device comprising an n-channel MISFET formed in an n-channel MISFET formation region of a semiconductor substrate, and a p-channel MISFET formed in a p-channel MISFET formation region of the semiconductor substrate, the method comprising the steps of:
(a) forming a second insulating film containing hafnium over the semiconductor substrate;
(b) after the step (a), forming a first cap film containing zirconium over the second insulating film;
(c) after the step (b), forming a first conductor film containing a metal over the first cap film;
(d) after the step (c), removing the first conductor film and the first cap film which are formed in the p-channel MISFET formation region;
(e) after the step (d), performing a heating treatment to the semiconductor substrate to diffuse the zirconium contained in the first cap film into the second insulating film in the n-channel MISFET formation region, and thereby form a first insulating film containing hafnium and zirconium in the re-channel MISFET formation region;
(f) after the step (e), forming a second conductor film over the first conductor film formed in the n-channel MISFET formation region and over the second insulating film formed in the p-channel MISFET formation region;
(g) after the step (f), patterning the first conductor film and the second conductor film to form a first dummy gate electrode in the n-channel MISFET formation region, and form a second dummy gate electrode in the p-channel MISFET formation region;
(h) after the step (g), introducing an n-type impurity into the semiconductor substrate in the n-channel MISFET formation region to form a first source region and a first drain region, while introducing a p-type impurity into the semiconductor substrate in the p-channel MISFET formation region to form a second source region and a second drain region;
(i) after the step (h), forming, over the semiconductor substrate, an interlayer insulating film covering the first dummy gate electrode and the second dummy gate electrode;
(j) after the step (i), polishing a surface of the interlayer insulating film to expose an upper surface of the first dummy gate electrode and an upper surface of the second dummy gate electrode;
(k) after the step (j), removing the second conductor film forming a part of the first dummy gate electrode to form a first trench in the interlayer insulating film, while removing the second conductor film forming the second dummy gate electrode to form a second trench in the interlayer insulating film;
(l) after the step (k), forming a third conductor film containing a metal over the interlayer insulating film including an inside of the first trench and an inside of the second trench, and forming a fourth conductor film containing a metal over the third conductor film to fill the inside of the first trench and the inside of the second trench with the third conductor film and the fourth conductor film; and
(m) after the step (l), removing the unneeded third conductor film and the unneeded fourth conductor film which are formed over the interlayer insulating film to form a first gate electrode in the first trench, and form a second gate electrode in the second trench,
wherein a physical film thickness of the first insulating film is larger than a physical film thickness of the second insulating film, and
wherein a concentration of the zirconium contained in the first insulating film is higher than a concentration of the zirconium contained in the second insulating film.
